(19) United States
(12) Patent Application Publication
(10) Pub. No.: US 2026/0349336 A1
(43) Pub. Date: Nov. 5, 2026

(54) PATTERNED MATERIALS AND METHODS OF MAKING AND USE THEREOF

(71) Applicant: BOARD OF REGENTS, THE UNIVERSITY OF TEXAS SYSTEM, Austin, TX (US)

(72) Inventors: Chih-Hao CHANG, Austin, TX (US); Kun-Chieh CHIEN, Austin, TX (US)

(21) Appl. No.: 19/487,119

(22) PCT Filed: May 24, 2024
(86) PCT No.: PCT/US2024/030942

§ 371 Date: Nov. 24, 2025

Related U.S. Application Data
(60) Provisional application No. 63/469,125, filed on May 26, 2023.

(51) Int. Cl. G03F 7/004; G02B 1/118; G03F 7/00; G03F 7/09; G03F 7/115

(52) U.S. Cl. CPC G03F 7/0043; G02B 1/118; G03F 7/0005; G03F 7/094; G03F 7/115

(57) ABSTRACT

Disclosed herein are patterned materials and methods of making and use thereof. For example, disclosed herein are patterned materials comprising a first plurality of nanostructures patterned on a first surface of a substrate and optionally further comprising a second plurality of nanostructures patterned on a second surface of the substrate, the second surface being opposite and spaced apart from the first surface. In some examples, the first plurality of nanostructures and/or the second plurality of nanostructures have an average aspect ratio of 0.5 or more. In some examples, the patterned material exhibits improved anti-glare (anti-reflection) properties, anti-dust properties, anti-fog properties, anti-scratch properties, self-cleaning properties, or a combination thereof. Also disclosed herein are methods of making and methods of use of any of the patterned materials described herein. Also disclosed herein are articles of manufacture and/or a devices comprising any of the patterned materials disclosed herein.

### CROSS-REFERENCE TO RELATED APPLICATIONS

This application claims the benefit of priority to U.S. Provisional Application No. 63/469,125 filed May 26, 2023, which is hereby incorporated herein by reference in its entirety.

### STATEMENT OF GOVERNMENT SUPPORT

This invention was made with government support under Grant No. W911NF-22-1-0124 awarded by the Army Research Office. The government has certain rights in the invention.

### BACKGROUND

Nanostructures on a surface can impart functionality to the surface. However, not every material can be patterned easily on its surface. Hard transparent ceramics, for example, are difficult to pattern. Patterning of such materials can lead to improved properties and/or their use in broader applications. Patterned transparent ceramics and improved methods for making said patterned materials are needed. The compositions, devices, methods, and systems discussed herein address these and other needs.

### SUMMARY

In accordance with the purposes of the disclosed compositions, devices, methods, and systems as embodied and broadly described herein, the disclosed subject matter relates to patterned materials and methods of making and use thereof.

For example, disclosed herein are patterned materials comprising a first plurality of nanostructures patterned on a first surface of a substrate. In some examples, the first plurality of nanostructures have a first average aspect ratio of 0.5 or more. In some examples, the first plurality of nanostructures comprise a first plurality of pillars extending from the first surface of the substrate. In some examples, the first plurality of nanostructures are arranged in a first ordered array, such that the first plurality of nanostructures are periodic. In some examples, the first plurality of nanostructures and the substrate comprise a transparent ceramic material comprising alumina (aluminum oxide, Al₂O₃) (e.g., an alumina-based transparent ceramic material). In some examples, the first plurality of nanostructures are substantially uniform over a surface area of 10 square micrometers (μm²) or more on the first surface of the substrate. In some examples, the first plurality of nanostructures are integrally formed with the first surface of the substrate. In some examples, the first plurality of pillars have a first average characteristic dimension (e.g., diameter) and a first average height, and the first average characteristic dimension varies along at least a portion of the first average height (e.g., at least a portion of each of the first plurality of pillars are tapered).

In some examples, the substrate has a second surface, the second surface being opposite and spaced apart from the first surface (e.g., the first surface is a top surface and the second surface is a bottom surface), and the patterned material further comprises a second plurality of nanostructures patterned on the second surface of the substrate. In some examples, the second plurality of nanostructures have a second average aspect ratio of 0.5 or more. In some examples, the second plurality of nanostructures comprise a second plurality of pillars extending from the second surface of the substrate. In some examples, the second plurality of nanostructures are arranged in a second ordered array, such that the second plurality of nanostructures are periodic. In some examples, the second plurality of nanostructures comprise the alumina-based transparent ceramic material. In some examples, the second plurality of nanostructures are substantially uniform over a surface area of 10 square micrometers (μm²) or more on the second surface of the substrate. In some examples, the second plurality of nanostructures are integrally formed with the second surface of the substrate. In some examples, the second plurality of pillars have a second average characteristic dimension (e.g., diameter) and a second average height, and the second average characteristic dimension varies along at least a portion of the second average height (e.g., at least a portion of each of the second plurality of pillars are tapered). In some examples, the second plurality of nanostructures are the same as the first plurality of nanostructures.

In some examples, the patterned material exhibits improved anti-glare (anti-reflection) properties, anti-dust properties, anti-fog properties, anti-scratch properties, self-cleaning properties, or a combination thereof, for example relative to the substrate in the absence of the patterning.

Also disclosed herein are methods of making any of the patterned materials described herein.

For example, the methods can comprise patterning a photoresist layer of a first layered stack, thereby making a second layered stack where the photoresist layer is patterned; wherein the first layered stack comprises the photoresist layer, an antireflection layer, a polysilicon layer, and a substrate having a first surface, the polysilicon layer being disposed on the first surface of the substrate, the antireflection layer being disposed on the polysilicon layer such that the polysilicon layer is sandwiched between the antireflection layer and the first surface of the substrate, and the photoresist layer being disposed on the antireflection layer such that the antireflection layer is sandwiched between the photoresist layer and the polysilicon layer; patterning the antireflection layer of the second layered stack to transfer the pattern of the photoresist layer to the antireflection layer, thereby making a third layered stack where the photoresist layer and the antireflection layer are patterned; patterning the polysilicon layer of the third layered stack to transfer the pattern of the antireflection layer to the polysilicon layer, thereby making a fourth layered stack where the photoresist layer, the antireflection layer, and the polysilicon layer are patterned; and etching the fourth layered stack to transfer the pattern of the polysilicon layer to the substrate and remove the photoresist layer, the antireflection layer, and the polysilicon layer, thereby making the patterned material.

In some examples, the method comprises patterning a photoresist layer of a first precursor layered stack, thereby making a first intermediate layered stack where the photoresist layer is patterned; wherein the first precursor layered stack comprises the photoresist layer, a polysilicon layer, and a substrate having a first surface, the polysilicon layer being disposed on the first surface of the substrate, the photoresist layer being disposed on the polysilicon layer such that the polysilicon layer is sandwiched between the photoresist layer and the first surface of the substrate; patterning the polysilicon layer of the first intermediate layered stack to transfer the pattern of the photoresist layer to the polysilicon layer, thereby making a second intermediate layered stack where the photoresist layer and the polysilicon layer are patterned; and etching the second intermediate layered stack to transfer the pattern of the polysilicon layer to the substrate and remove the photoresist layer and the polysilicon layer, thereby making the patterned material.

In some examples, the substrate has a second surface, the second surface being opposite and spaced apart from the first surface (e.g., the first surface is a top surface and the second surface is a bottom surface), and the method further comprises patterning the second surface.

In some examples, the method comprises: patterning a photoresist layer of a fifth layered stack thereby making a sixth layered stack where the photoresist layer is patterned; wherein the fifth layered stack comprises the photoresist layer, an antireflection layer, a polysilicon layer, and the substrate having the second surface, the polysilicon layer being disposed on the second surface of the substrate, the antireflection layer being disposed on the polysilicon layer such that the polysilicon layer is sandwiched between the antireflection layer and the second surface of the substrate, and the photoresist layer being disposed on the antireflection layer such that the antireflection layer is sandwiched between the photoresist layer and the polysilicon layer; patterning the antireflection layer of the sixth layered stack, to transfer the pattern of the photoresist layer to the antireflection layer, thereby making a seventh layered stack where the photoresist layer and the antireflection layer are patterned; patterning the polysilicon layer of the seventh layered stack to transfer the pattern of the antireflection layer to the polysilicon layer, thereby making an eighth layered stack where the photoresist layer, the antireflection layer, and the polysilicon layer are patterned; and etching the eighth layered stack to transfer the pattern of the polysilicon layer to the substrate and remove the photoresist layer, the antireflection layer, and the polysilicon layer, thereby making the patterned material (e.g., wherein the first surface and the second surface are patterned).

In some examples, the method comprises: patterning a photoresist layer of a second precursor layered stack thereby making a third intermediate layered stack where the photoresist layer is patterned; wherein the second precursor layered stack comprises the photoresist layer, a polysilicon layer, and the substrate having the second surface, the polysilicon layer being disposed on the second surface of the substrate, the photoresist layer being disposed on the polysilicon layer such that the polysilicon layer is sandwiched between the photoresist layer and the second surface of the substrate; patterning the polysilicon layer of the third intermediate layered stack, to transfer the pattern of the photoresist layer to the polysilicon layer, thereby making a fourth intermediate layered stack where the photoresist layer and the polysilicon layer are patterned; and etching the fourth intermediate layered stack to transfer the pattern of the polysilicon layer to the substrate and remove the photoresist layer and the polysilicon layer, thereby making the patterned material.

In some examples, patterning the photoresist layer comprises using interference lithography.

In some examples, patterning the antireflection layer comprises using inductively coupled plasma reactive ion etching (ICP-RIE), such as O₂ inductively coupled plasma reactive ion etching (ICP-RIE).

In some examples, patterning the polysilicon layer comprises using ICP-RIE with low RF power, such as HBr ICP-RIE with low RF power. In some examples, the low RF power used to pattern the polysilicon layer enhances etch selectivity.

In some examples, etching the fourth layered stack, the eighth layered stack, the second intermediate layered stack, the fourth intermediate layered stack, or a combination thereof independently comprises using ICP-RIE, such as HBr/BCl₃ ICP-RIE.

Also disclosed herein are methods of use of any of the patterned materials disclosed herein.

Also disclosed herein are articles of manufacture and/or a devices comprising any of the patterned materials disclosed herein.

Additional advantages of the disclosed compositions, devices, systems, and methods will be set forth in part in the description which follows, and in part will be obvious from the description. The advantages of the disclosed compositions, devices, systems, and methods will be realized and attained by means of the elements and combinations particularly pointed out in the appended claims. It is to be understood that both the foregoing general description and the following detailed description are exemplary and explanatory only and are not restrictive of the disclosed compositions, devices, systems, and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1. Fabrication processes of proposed technique.

FIG. 2A-FIG. 2C. The sapphire sample after the BCl₃/HBr ICP-RIE process for 18 min (FIG. 2A). SEM images of tapered sapphire nanostructures with an etch time of (FIG. 2B) 18 min and (FIG. 2C) 23 min.

FIG. 3. Broadband transmittance of planar sapphire (blue line) and sapphire with 350 nm height of nanostructures (red line).

FIG. 4A. Raw optical emission spectroscopy signals at different timestamps.

FIG. 4B. Key wavelength analysis by principal component analysis.

FIG. 4C. Optical emission spectroscopy signals at 395.6 nm.

FIG. 4D. Optical emission spectroscopy signals at 826.3 nm.

FIG. 5. Multilayer etching mask fabrication process.

FIG. 6. Etch selectivity.

FIG. 7. Image of sapphire substrate after 4 cycles of poly-Si LPCVD.

FIG. 8. Image of substrate after 80 minutes of etching using HBr ICP-RIE with 20 W RF power.

FIG. 9. Image of substrate.

FIG. 10. Image of nanostructures.

FIG. 11. Image of nanostructures.

FIG. 12. Image of nanostructures.

FIG. 13. Optical characterization of nanostructures shown in FIG. 12.

FIG. 14. Photographs illustrating the anti-glare properties of the patterned sapphire vs. planar sapphire.

FIG. 15. Photographs illustrating the anti-glare properties of the patterned sapphire vs. planar sapphire.

FIG. 16. Photographs illustrating the anti-glare properties of the patterned sapphire vs. planar sapphire.

FIG. 17. Photographs illustrating the anti-glare properties of the patterned sapphire vs. planar sapphire.

FIG. 18. Fabrication processes of proposed technique.

FIG. 19. Image of patterned photoresist and antireflection coating layers.

FIG. 20. Image of high aspect ratio polysilicon pillars.

FIG. 21. Image of sapphire nanostructures.

FIG. 22. Image of sapphire nanostructures.

FIG. 23. Optical characterization of sapphire samples.

FIG. 24. Photographs illustrating the anti-glare properties of the double-sided patterned sapphire vs. planar sapphire.

FIG. 25. Photographs illustrating the anti-glare properties of the double-sided patterned sapphire vs. planar sapphire.

FIG. 26. Photographs illustrating the anti-fog properties of the double-sided patterned sapphire vs. planar sapphire.

FIG. 27. Photographs illustrating the anti-fog properties of the double-sided patterned sapphire vs. planar sapphire.

FIG. 28. Schematic illustration of anti-glare effect due to surface structures.

FIG. 29. Schematic illustration of Wenzel state wetting (left) and Cassie-Baxter State (right).

FIG. 30. Transmittance of TE and TM measured at 1330 nm for different incidence angles.

FIG. 31. Non-polarized transmittance measured at 1330 nm for different incidence angles.

FIG. 32. Time evolution of transmission at 600 nm for anti-fogging.

FIG. 33. Time evolution of transmission at 1000 nm for anti-fogging.

FIG. 34. Water contact angle on planar surface after silane coating.

FIG. 35. Water contact angle on nanotextured surface after silane coating.

FIG. 36. Photographs over time of water droplet introduced onto the patterned surface with a low impact at a 200 oblique angle.

FIG. 37. Photographs over time of water droplet introduced onto the surface with a high impact at a 50° oblique angle (V=1 m/s).

FIG. 38. Nanoindentation result of sapphire nanopillar structures.

FIG. 39. Nanostructured sapphire surface after pencil hardness testing.

FIG. 40. SEM image of nanostructured sapphire surface after pencil hardness testing at 7.5N loading at 450 angle with 2B pencil lead.

FIG. 41. Planar sapphire sample (left) and nanostructured sapphire sample (right) after anti-dust experiment using a lunar dust simulant.

FIG. 42A. Topographic map the nanostructured sapphire surface by confocal microscopy after the anti-dust experiment.

FIG. 42B. Topographic map of the planar sapphire surface by confocal microscopy after the anti-dust experiment

### DETAILED DESCRIPTION

The compositions, devices, methods, and systems described herein may be understood more readily by reference to the following detailed description of specific aspects of the disclosed subject matter and the Examples included therein.

Before the present compositions, devices, methods, and systems are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

“Exemplary” means “an example of” and is not intended to convey an indication of a preferred or ideal embodiment. “Such as” is not used in a restrictive sense, but for explanatory purposes.

Values can be expressed herein as an “average” value. “Average” generally refers to the statistical mean value.

By “substantially” is meant within 5%, e.g., within 4%, 3%, 2%, or 1%.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

As used herein the term “plurality” means 2 or more (e.g., 3 or more; 4 or more; 5 or more; 10 or more; 15 or more; 20 or more; 25 or more; 30 or more; 40 or more; 50 or more; 75 or more; 100 or more; 150 or more; 200 or more; 250 or more; 300 or more; 400 or more; 500 or more; 750 or more; 1000 or more; 1500 or more; 2000 or more; 2500 or more; 3000 or more; 4000 or more; or 5000 or more).

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

### Patterned Materials

Disclosed herein are patterned materials and methods of making and use thereof.

For example, disclosed herein are patterned materials comprising a first plurality of nanostructures patterned on a first surface of a substrate.

The first plurality of nanostructures and the substrate comprise a transparent ceramic material comprising alumina (aluminum oxide, Al₂O₃) (e.g., an alumina-based transparent ceramic material). Examples of alumina-based transparent ceramic materials include, but are not limited to, sapphire (single-crystal aluminum oxide), aluminum oxynitride spinel (Al₂₃O₂₇N₅, abbreviated as AlON), yttrium aluminum garnet (YAG), magnesium aluminate spinel (MgAl₂O₄), alumina-based glass, derivatives thereof, and combinations thereof. In some examples, the alumina-based transparent ceramic material comprises sapphire.

In some examples, the alumina-based transparent ceramic material has a Mohs hardness of 7 or more (e.g., 7.5 or more, 8 or more, 8.5 or more, or 9 or more).

The first plurality of nanostructures can, for example, comprise a first plurality of pillars extending from the first surface of the substrate. In some examples, the first plurality of nanostructures are integrally formed with the first surface of the substrate.

In some examples, the first plurality of pillars have a first average characteristic dimension (e.g., diameter) and a first average height. The term “height” as used herein refers to the dimension of the first plurality of pillars in a plane perpendicular to the first surface of the substrate. “Average height” and “mean height” are used interchangeably herein, and generally refer to the statistical mean height. The term “characteristic dimension,” as used herein refers to the largest straight line distance between two points in the plane of the cross-sectional shape of the pillar, e.g. in a plane parallel to the first surface of the substrate. “Average characteristic dimension” and “mean characteristic dimension” are used interchangeably herein, and generally refer to the statistical mean characteristic dimension. For example, for a pillar with a cross-sectional shape that is substantially circular, the average characteristic dimension can refer to the average diameter.

In some examples, the first plurality of pillars have a first average height of 200 nanometers (nm) or more (e.g., 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, 900 nm or more, 950 nm or more, 1 micrometer (micron, μm) or more, 1.1 μm or more, 1.2 μm or more, 1.3 μm or more, 1.4 μm or more, 1.5 μm or more, 1.6 μm or more, 1.7 μm or more, or 1.8 μm or more). In some examples, the first plurality of pillars have a first average height of 2 micrometers (microns, μm) or less (e.g., 1.9 μm or less, 1.8 μm or less, 1.7 μm or less, 1.6 μm or less, 1.5 μm or less, 1.4 μm or less, 1.3 μm or less, 1.2 μm or less, 1.1 μm or less, 1 μm or less, 950 nanometers (nm) or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, or 250 nm or less). The first average height of the first plurality of pillars can range from any of the minimum values described above to any of the maximum values described above. For example, the first plurality of pillars can have a first average height of from 200 nanometers (nm) to 2 micrometers (microns, μm) (e.g., from 200 nm to 1 μm, from 1 μm to 2 μm, from 200 nm to 650 nm, from 650 nm to 1.1 μm, from 1.1 μm to 1.5 μm, from 1.5 μm to 2 μm, from 250 nm to 2 μm, from 300 nm to 2 μm, from 350 nm to 2 μm, from 400 nm to 2 μm, from 450 nm to 2 μm, from 500 nm to 2 μm, from 550 nm to 2 μm, from 600 nm to 2 μm, from 650 nm to 2 μm, from 700 nm to 2 μm, from 750 nm to 2 μm, from 800 nm to 2 μm, from 850 nm to 2 μm, from 900 nm to 2 μm, from 950 nm to 2 μm, from 1.1 μm to 2 μm, from 1.2 μm to 2 μm, from 1.3 μm to 2 μm, from 1.4 μm to 2 μm, from 1.6 μm to 2 μm, from 250 nm to 1.8 μm, or from 375 nm to 550 nm). The average height can be determined, for example, using electron microscopy (e.g., scanning electron microscopy (SEM), scanning transmission electron microscopy (STEM), etc.).

In some examples, the first average characteristic dimension varies along at least a portion of the first average height (e.g., at least a portion of each of the first plurality of pillars are tapered). In some examples, the first average characteristic dimension of the first plurality of pillars at the first surface of the substrate (e.g., the base of the first plurality of pillars) is 50 nm or more (e.g., 75 nm or more, 100 nm or more, 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, 900 nm or more, 950 nm or more, 1 micrometer (micron, km) or more, 1.1 μm or more, 1.2 μm or more, 1.3 μm or more, 1.4 μm or more, 1.5 μm or more, 1.6 μm or more, 1.7 μm or more, or 1.8 μm or more). In some examples, the first average characteristic dimension of the first plurality of pillars at the first surface of the substrate (e.g., the base of the first plurality of pillars) is 2 micrometers (microns, μm) or less (e.g., 1.9 μm or less, 1.8 μm or less, 1.7 μm or less, 1.6 μm or less, 1.5 μm or less, 1.4 μm or less, 1.3 μm or less, 1.2 μm or less, 1.1 μm or less, 1 μm or less, 950 nanometers (nm) or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, 150 nm or less, 125 nm or less, or 100 nm or less). The first average characteristic dimension of the first plurality of pillars at the first surface of the substrate (e.g., the base of the first plurality of pillars) can range from any of the minimum values described above to any of the maximum values described above. For example, the first average characteristic dimension of the first plurality of pillars at the first surface of the substrate (e.g., the base of the first plurality of pillars) can be from 50 nm to 2 μm (e.g., from 50 nm to 1 μm, from 1 μm to 2 μm, from 50 nm to 500 nm, from 500 nm to 1 μm, from 1 μm to 1.5 μm, from 1.5 μm to 2 μm, from 50 nm to 1.8 μm, from 50 nm to 1.6 μm, from 50 nm to 1.4 μm, from 50 nm to 1.2 μm, from 50 nm to 800 nm, from 50 nm to 600 nm, from 50 nm to 400 nm, from 50 nm to 200 nm, from 100 nm to 2 μm, from 200 nm to 2 μm, from 400 nm to 2 μm, from 600 nm to 2 μm, from 800 nm to 2 μm, from 1.2 μm to 2 μm, from 1.4 μm to 2 μm, from 1.6 μm to 2 μm, from 100 nm to 1.8 μm, from 100 nm to 1 μm, or from 200 nm to 300 nm). The average characteristic dimension can be determined, for example, using electron microscopy (e.g., scanning electron microscopy (SEM), scanning transmission electron microscopy (STEM), etc.).

In some examples, the first plurality of pillars can have a first average height of from 200 nanometers (nm) to 2 micrometers (microns, μm) and the first average characteristic dimension of the first plurality of pillars at the first surface of the substrate (e.g., the base of the first plurality of pillars) can be from 50 nm to 2 μm.

In some examples, first plurality of nanostructures can be described by their average aspect ratio, which, as used herein, is the first average height divided by the first average characteristic of the pillar at the base of the pillar. The first plurality of nanostructures can, for example, have a first average aspect ratio of 0.5 or more (e.g., 1 or more, 1.5 or more, 2 or more, 2.5 or more, 3 or more, 3.5 or more, 4 or more, 4.5 or more, 5 or more, 5.5 or more, 6 or more, 6.5 or more, 7 or more, 7.5 or more, 8 or more, 8.5 or more, 9 or more, 9.5 or more, 10 or more, 11 or more, 12 or more, 13 or more, 14 or more, 15 or more, 16 or more, 17 or more, or 18 or more). In some examples, the first plurality of nanostructures can have a first average aspect ratio of 20 or less (e.g., 19 or less, 18 or less, 17 or less, 16 or less, 15 or less, 14 or less, 13 or less, 12 or less, 11 or less, 10 or less, 9.5 or less, 9 or less, 8.5 or less, 8 or less, 7.5 or less, 7 or less, 6.5 or less, 6 or less, 5.5 or less, 5 or less, 4.5 or less, 4 or less, 3.5 or less, 3 or less, 2.5 or less, 2 or less, or 1.5 or less). The first average aspect ratio can range from any of the minimum values described above to any of the maximum values described above. For example, the first average aspect ratio can be from 0.5 to 20 (e.g., from 0.5 to 10, from 10 to 20, from 0.5 to 4, from 4 to 8, from 8 to 12, from 12 to 16, from 16 to 20, from 1 to 20, from 2 to 20, from 3 to 20, from 4 to 20, from 5 to 20, from 6 to 20, from 7 to 20, from 8 to 20, from 9 to 20, from 11 to 20, from 12 to 20, from 13 to 20, from 14 to 20, or from 15 to 20). In some examples, the first plurality of nanostructures have a first average aspect ratio of 1 or more, 1.5 or more or 2 or more.

In some examples, the first plurality of pillars can have a first average aspect ratio of 0.5 or more and a first average height of from 200 nanometers (nm) to 2 micrometers (microns, μm).

In some examples, the first plurality of nanostructures can have a first average aspect ratio of 0.5 or more and the first average characteristic dimension of the first plurality of pillars at the first surface of the substrate (e.g., the base of the first plurality of pillars) can be from 50 nm to 2 μm.

In some examples, the first plurality of nanostructures can have a first average aspect ratio of 0.5 or more, the first plurality of pillars can have a first average height of from 200 nanometers (nm) to 2 micrometers (microns, μm) and the first average characteristic dimension of the first plurality of pillars at the first surface of the substrate (e.g., the base of the first plurality of pillars) can be from 50 nm to 2 μm.

The first plurality of pillars can have a cross-sectional shape in a plane substantially parallel to the first surface of the substrate, wherein the cross-sectional shape can be any shape, such as a regular shape, an irregular shape, an isotropic shape, or an anisotropic shape. In some examples, the cross-sectional shape of the first plurality of pillars can be substantially circular, ovate, ovoid, elliptic, triangular, rectangular, polygonal, etc. In some examples, the cross-sectional shape of the first plurality of pillars can vary along the height of the pillar.

The first plurality of pillars can have any shape, such as, for example, a polyhedron (e.g., a platonic solid, a prism, a pyramid), a cylinder, a hemicylinder, an elliptical cylinder, a hemi-elliptical cylinder, a cone, a semicone, etc. In some examples, the shape of the first plurality of pillars can vary along the height of the pillar.

In some examples, the first plurality of nanostructures are arranged in a first ordered array, such that the first plurality of nanostructures are periodic. For example, the first ordered array can comprise a two dimensional ordered array. In some examples, the first ordered array has a first periodicity of 10 nanometers (nm) or more (e.g., 15 nm or more, 20 nm or more, 25 nm or more, 30 nm or more, 35 nm or more, 40 nm or more, 45 nm or more, 50 nm or more, 60 nm or more, 70 nm or more, 80 nm or more, 90 nm or more, 100 nm or more, 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, or 900 nm or more). In some examples, the first ordered array can have a fired periodicity of 1000 nm or less (e.g., 950 nm or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, 150 nm or less, 125 nm or less, 100 nm or less, 90 nm or less, 80 nm or less, 70 nm or less, 60 nm or less, 50 nm or less, 45 nm or less, 40 nm or less, 35 nm or less, 30 nm or less, 25 nm or less, or 20 nm or less). The first periodicity of the first ordered array can range from any of the minimum values described above to any of the maximum values described above. For example, the first ordered array can have a first periodicity of from 10 nanometers (nm) to 1 micrometer (μm) (e.g., from 10 to 500 nm, from 500 to 1000 nm, from 10 to 200 nm, from 200 to 400 nm, from 400 to 600 nm, from 600 to 800 nm, from 800 to 1000 nm, from 10 to 900 nm, from 10 to 800 nm, from 10 to 700 nm, from 10 to 600 nm, from 10 to 500 nm, from 10 to 400 nm, from 10 to 300 nm, from 10 to 200 nm, from 10 to 100 nm, from 10 to 50 nm, from 50 to 1000 nm, from 100 to 1000 nm, from 200 to 1000 nm, from 300 to 1000 nm, from 400 to 1000 nm, from 500 to 1000 nm, from 600 to 1000 nm, from 700 to 1000 nm, from 25 to 900 nm, from 50 to 800 nm, or from 100 to 600 nm). In some examples, the first ordered array has a first periodicity of 300 nm or less, 250 nm or less, or 200 nm or less.

In some examples, the first plurality of pillars can have a first average aspect ratio of 0.5 or more and the first ordered array can have a first periodicity of from 10 nanometers (nm) to 1 micrometer (μm).

In some examples, the first plurality of pillars have a first average height of from 200 nanometers (nm) to 2 micrometers (microns, μm) and the first ordered array can have a first periodicity of from 10 nanometers (nm) to 1 micrometer (μm).

In some examples, the first average characteristic dimension of the first plurality of pillars at the first surface of the substrate (e.g., the base of the first plurality of pillars) can be from 50 nm to 2 μm and the first ordered array can have a first periodicity of from 10 nanometers (nm) to 1 micrometer (μm).

In some examples, the first plurality of pillars can have a first average height of from 200 nanometers (nm) to 2 micrometers (microns, μm), the first average characteristic dimension of the first plurality of pillars at the first surface of the substrate (e.g., the base of the first plurality of pillars) can be from 50 nm to 2 μm, and the first ordered array can have a first periodicity of from 10 nanometers (nm) to 1 micrometer (μm).

In some examples, the first plurality of pillars can have a first average aspect ratio of 0.5 or more and a first average height of from 200 nanometers (nm) to 2 micrometers (microns, μm) the first ordered array can have a first periodicity of from 10 nanometers (nm) to 1 micrometer (μm).

In some examples, the first plurality of nanostructures can have a first average aspect ratio of 0.5 or more, the first average characteristic dimension of the first plurality of pillars at the first surface of the substrate (e.g., the base of the first plurality of pillars) can be from 50 nm to 2 μm, and the first ordered array can have a first periodicity of from 10 nanometers (nm) to 1 micrometer (μm).

In some examples, the first plurality of nanostructures can have a first average aspect ratio of 0.5 or more, the first plurality of pillars can have a first average height of from 200 nanometers (nm) to 2 micrometers (microns, μm), the first average characteristic dimension of the first plurality of pillars at the first surface of the substrate (e.g., the base of the first plurality of pillars) can be from 50 nm to 2 μm, and the first ordered array can have a first periodicity of from 10 nanometers (nm) to 1 micrometer (μm).

The first plurality of nanostructures can be substantially uniform over a surface area of 10 square micrometers (μm²) or more on the first surface of the substrate (e.g., 15 μm² or more; m² or more; 25 μm² or more; 30 μm² or more; 35 μm² or more; 40 μm² or more; 45 μm² or more; 50 μm² or more; 60 μm² or more; 70 μm² or more; 80 μm² or more; 90 μm² or more; 100 μm² or more; 125 μm² or more; 200 μm² or more; 225 μm² or more; 250 μm² or more; 300 μm² or more; 350 μm² or more; 400 μm² or more; 450 μm² or more; 500 μm² or more; 600 μm² or more; 700 μm² or more; 800 μm² or more; 900 μm² or more; 1000 μm² or more; 1250 μm² or more; 1500 μm² or more; 1750 μm² or more; 2000 μm² or more; 2250 μm² or more; 2500 μm² or more; 3000 μm² or more; 3500 μm² or more; 4000 μm² or more; 4500 μm² or more; 5000 μm² or more; 6000 μm² or more; 7000 μm² or more; 8000 μm² or more; 9000 μm² or more; 10,000 μm² or more; 15,000 μm² or more; 20,000 μm² or more; 25,000 μm² or more; 30,000 μm² or more; 35,000 μm² or more; 40,000 μm² or more; 45,000 μm² or more; 50,000 μm² or more; 60,000 μm² or more; 70,000 μm² or more; 80,000 μm² or more; 90,000 μm² or more; 100,000 μm² or more; 125,000 μm² or more; 200,000 μm² or more; 225,000 μm² or more; 250,000 μm² or more; 300,000 μm² or more; 350,000 μm² or more; 400,000 μm² or more; 450,000 μm² or more; 500,000 μm² or more; 600,000 μm² or more; 700,000 μm² or more; 800,000 μm² or more; or 900,000 μm² or more). In some examples, the first plurality of nanostructures can be substantially uniform over a surface area of 1 square millimeters (mm²) or more on the first surface of the substrate (e.g., 2 mm² or more; 3 mm² or more; 4 mm² or more; 5 mm² or more; 10 mm² or more; 15 mm² or more; 20 mm² or more; 25 mm² or more; 30 mm² or more; 35 mm² or more; 40 mm² or more; 45 mm² or more; 50 mm² or more; 60 mm² or more; 70 mm² or more; 80 mm² or more; 90 mm² or more; 100 mm² or more; 125 mm² or more; 200 mm² or more; 225 mm² or more; 250 mm² or more; 300 mm² or more; 350 mm² or more; 400 mm² or more; 450 mm² or more; 500 mm² or more; 600 mm² or more; 700 mm² or more; 800 mm² or more; 900 mm² or more; 1000 mm² or more; 1250 mm² or more; 1500 mm² or more; 1750 mm² or more; 2000 mm² or more; 2250 mm² or more; 2500 mm² or more; 3000 mm² or more; 3500 mm² or more; 4000 mm² or more; 4500 mm² or more; 5000 mm² or more; 6000 mm² or more; 7000 mm² or more; 8000 mm² or more; 9000 mm² or more; 10,000 mm² or more; 15,000 mm² or more; 20,000 mm² or more; 25,000 mm² or more; 30,000 mm² or more; 35,000 mm² or more; 40,000 mm² or more; 45,000 mm² or more; 50,000 mm² or more; 60,000 mm² or more; 70,000 mm² or more; 80,000 mm² or more; 90,000 mm² or more; 100,000 mm² or more; 125,000 mm² or more; 200,000 mm² or more; 225,000 mm² or more; 250,000 mm² or more; 300,000 mm² or more; 350,000 mm² or more; 400,000 mm² or more; 450,000 mm² or more; 500,000 mm² or more; 600,000 mm² or more; 700,000 mm² or more; 800,000 mm² or more; or 900,000 mm² or more).

As used herein, “substantially uniform” generally describes a population of nanostructures wherein the nanostructures are the same or nearly the same in terms of average height, average characteristic dimension, and periodicity. As used herein, a substantially uniform distribution refers to nanostructures in which 80% of the distribution or more (e.g., 85% of the distribution, 90% of the distribution, or 95% of the distribution) lies within 25% of the median value for height, average characteristic dimension, and periodicity (e.g., within 20%, within 15%, within 10%, or within 5%).

In some examples, the substrate has a second surface, the second surface being opposite and spaced apart from the first surface (e.g., the first surface is a top surface and the second surface is a bottom surface), and the patterned material further comprises a second plurality of nanostructures patterned on the second surface of the substrate. The second plurality of nanostructures can be the same or different than the first plurality of nanostructures. In some examples, the second plurality of nanostructures are the same as the first plurality of nanostructures.

The second plurality of nanostructures can, for example, comprise a second plurality of pillars extending from the second surface of the substrate. In some examples, the second plurality of nanostructures are integrally formed with the second surface of the substrate.

In some examples, the second plurality of pillars have a second average characteristic dimension (e.g., diameter) and a second average height. The term “height” as used herein refers to the dimension of the second plurality of pillars in a plane perpendicular to the second surface of the substrate. “Average height” and “mean height” are used interchangeably herein, and generally refer to the statistical mean height. The term “characteristic dimension,” as used herein refers to the largest straight line distance between two points in the plane of the cross-sectional shape of the pillar, e.g. in a plane parallel to the second surface of the substrate. “Average characteristic dimension” and “mean characteristic dimension” are used interchangeably herein, and generally refer to the statistical mean characteristic dimension. For example, for a pillar with a cross-sectional shape that is substantially circular, the average characteristic dimension can refer to the average diameter.

In some examples, the second plurality of pillars have a second average height of 200 nanometers (nm) or more (e.g., 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, 900 nm or more, 950 nm or more, 1 micrometer (micron, μm) or more, 1.1 μm or more, 1.2 μm or more, 1.3 μm or more, 1.4 μm or more, 1.5 μm or more, 1.6 μm or more, 1.7 μm or more, or 1.8 μm or more). In some examples, the second plurality of pillars have a second average height of 2 micrometers (microns, μm) or less (e.g., 1.9 μm or less, 1.8 μm or less, 1.7 μm or less, 1.6 μm or less, 1.5 μm or less, 1.4 μm or less, 1.3 μm or less, 1.2 μm or less, 1.1 μm or less, 1 μm or less, 950 nanometers (nm) or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, or 250 nm or less). The second average height of the second plurality of pillars can range from any of the minimum values described above to any of the maximum values described above. For example, the second plurality of pillars can have a second average height of from 200 nanometers (nm) to 2 micrometers (microns, μm) (e.g., from 200 nm to 1 μm, from 1 μm to 2 μm, from 200 nm to 650 nm, from 650 nm to 1.1 μm, from 1.1 μm to 1.5 μm, from 1.5 μm to 2 μm, from 250 nm to 2 μm, from 300 nm to 2 μm, from 350 nm to 2 μm, from 400 nm to 2 μm, from 450 nm to 2 μm, from 500 nm to 2 μm, from 550 nm to 2 μm, from 600 nm to 2 μm, from 650 nm to 2 μm, from 700 nm to 2 μm, from 750 nm to 2 μm, from 800 nm to 2 μm, from 850 nm to 2 μm, from 900 nm to 2 μm, from 950 nm to 2 μm, from 1.1 μm to 2 μm, from 1.2 μm to 2 μm, from 1.3 μm to 2 μm, from 1.4 μm to 2 μm, from 1.6 μm to 2 μm, from 250 nm to 1.8 μm, or from 375 nm to 550 nm). The average height can be determined, for example, using electron microscopy (e.g., scanning electron microscopy (SEM), scanning transmission electron microscopy (STEM), etc.).

In some examples, the second average characteristic dimension varies along at least a portion of the second average height (e.g., at least a portion of each of the second plurality of pillars are tapered). In some examples, the second average characteristic dimension of the second plurality of pillars at the second surface of the substrate (e.g., the base of the second plurality of pillars) is 50 nm or more (e.g., 75 nm or more, 100 nm or more, 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, 900 nm or more, 950 nm or more, 1 micrometer (micron, μm) or more, 1.1 μm or more, 1.2 μm or more, 1.3 μm or more, 1.4 μm or more, 1.5 μm or more, 1.6 μm or more, 1.7 μm or more, or 1.8 μm or more). In some examples, the second average characteristic dimension of the second plurality of pillars at the second surface of the substrate (e.g., the base of the second plurality of pillars) is 2 micrometers (microns, μm) or less (e.g., 1.9 μm or less, 1.8 μm or less, 1.7 μm or less, 1.6 μm or less, 1.5 μm or less, 1.4 μm or less, 1.3 μm or less, 1.2 μm or less, 1.1 μm or less, 1 μm or less, 950 nanometers (nm) or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, 150 nm or less, 125 nm or less, or 100 nm or less). The second average characteristic dimension of the second plurality of pillars at the second surface of the substrate (e.g., the base of the second plurality of pillars) can range from any of the minimum values described above to any of the maximum values described above. For example, the second average characteristic dimension of the second plurality of pillars at the second surface of the substrate (e.g., the base of the second plurality of pillars) can be from 50 nm to 2 μm (e.g., from 50 nm to 1 μm, from 1 μm to 2 μm, from 50 nm to 500 nm, from 500 nm to 1 μm, from 1 μm to 1.5 μm, from 1.5 μm to 2 μm, from 50 nm to 1.8 μm, from 50 nm to 1.6 μm, from 50 nm to 1.4 μm, from 50 nm to 1.2 μm, from 50 nm to 800 nm, from 50 nm to 600 nm, from 50 nm to 400 nm, from 50 nm to 200 nm, from 100 nm to 2 μm, from 200 nm to 2 μm, from 400 nm to 2 μm, from 600 nm to 2 μm, from 800 nm to 2 μm, from 1.2 μm to 2 μm, from 1.4 μm to 2 μm, from 1.6 μm to 2 μm, from 100 nm to 1.8 μm, from 100 nm to 1 μm, or from 200 nm to 300 nm). The average characteristic dimension can be determined, for example, using electron microscopy (e.g., scanning electron microscopy (SEM), scanning transmission electron microscopy (STEM), etc.).

In some examples, the second plurality of pillars can have a second average height of from 200 nanometers (nm) to 2 micrometers (microns, μm) and the second average characteristic dimension of the second plurality of pillars at the second surface of the substrate (e.g., the base of the second plurality of pillars) can be from 50 nm to 2 μm.

In some examples, second plurality of nanostructures can be described by their average aspect ratio, which, as used herein, is the second average height divided by the second average characteristic of the pillar at the base of the pillar. The second plurality of nanostructures can, for example, have a second average aspect ratio of 0.5 or more (e.g., 1 or more, 1.5 or more, 2 or more, 2.5 or more, 3 or more, 3.5 or more, 4 or more, 4.5 or more, 5 or more, 5.5 or more, 6 or more, 6.5 or more, 7 or more, 7.5 or more, 8 or more, 8.5 or more, 9 or more, 9.5 or more, 10 or more, 11 or more, 12 or more, 13 or more, 14 or more, 15 or more, 16 or more, 17 or more, or 18 or more). In some examples, the second plurality of nanostructures can have a second average aspect ratio of 20 or less (e.g., 19 or less, 18 or less, 17 or less, 16 or less, 15 or less, 14 or less, 13 or less, 12 or less, 11 or less, 10 or less, 9.5 or less, 9 or less, 8.5 or less, 8 or less, 7.5 or less, 7 or less, 6.5 or less, 6 or less, 5.5 or less, 5 or less, 4.5 or less, 4 or less, 3.5 or less, 3 or less, 2.5 or less, 2 or less, or 1.5 or less). The second average aspect ratio can range from any of the minimum values described above to any of the maximum values described above. For example, the second average aspect ratio can be from 0.5 to 20 (e.g., from 0.5 to 10, from 10 to 20, from 0.5 to 4, from 4 to 8, from 8 to 12, from 12 to 16, from 16 to 20, from 1 to 20, from 2 to 20, from 3 to 20, from 4 to 20, from 5 to 20, from 6 to 20, from 7 to 20, from 8 to 20, from 9 to 20, from 11 to 20, from 12 to 20, from 13 to 20, from 14 to 20, or from 15 to 20). In some examples, the second plurality of nanostructures have a second average aspect ratio of 1 or more, 1.5 or more or 2 or more.

In some examples, the second plurality of pillars can have a second average aspect ratio of 0.5 or more and a second average height of from 200 nanometers (nm) to 2 micrometers (microns, μm).

In some examples, the second plurality of nanostructures can have a second average aspect ratio of 0.5 or more and the second average characteristic dimension of the second plurality of pillars at the second surface of the substrate (e.g., the base of the second plurality of pillars) can be from 50 nm to 2 μm.

In some examples, the second plurality of nanostructures can have a second average aspect ratio of 0.5 or more, the second plurality of pillars can have a second average height of from 200 nanometers (nm) to 2 micrometers (microns, μm) and the second average characteristic dimension of the second plurality of pillars at the second surface of the substrate (e.g., the base of the second plurality of pillars) can be from 50 nm to 2 μm.

The second plurality of pillars can have a cross-sectional shape in a plane substantially parallel to the second surface of the substrate, wherein the cross-sectional shape can be any shape, such as a regular shape, an irregular shape, an isotropic shape, or an anisotropic shape. In some examples, the cross-sectional shape of the second plurality of pillars can be substantially circular, ovate, ovoid, elliptic, triangular, rectangular, polygonal, etc. In some examples, the cross-sectional shape of the second plurality of pillars can vary along the height of the pillar.

The second plurality of pillars can have any shape, such as, for example, a polyhedron (e.g., a platonic solid, a prism, a pyramid), a cylinder, a hemicylinder, an elliptical cylinder, a hemi-elliptical cylinder, a cone, a semicone, etc. In some examples, the shape of the second plurality of pillars can vary along the height of the pillar.

In some examples, the second plurality of nanostructures are arranged in a second ordered array, such that the second plurality of nanostructures are periodic. For example, the second ordered array can comprise a two dimensional ordered array. In some examples, the second ordered array has a second periodicity of 10 nanometers (nm) or more (e.g., 15 nm or more, 20 nm or more, 25 nm or more, 30 nm or more, 35 nm or more, 40 nm or more, 45 nm or more, 50 nm or more, 60 nm or more, 70 nm or more, 80 nm or more, 90 nm or more, 100 nm or more, 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, or 900 nm or more). In some examples, the second ordered array can have a fired periodicity of 1000 nm or less (e.g., 950 nm or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, 150 nm or less, 125 nm or less, 100 nm or less, 90 nm or less, 80 nm or less, 70 nm or less, 60 nm or less, 50 nm or less, 45 nm or less, 40 nm or less, 35 nm or less, 30 nm or less, 25 nm or less, or 20 nm or less). The second periodicity of the second ordered array can range from any of the minimum values described above to any of the maximum values described above. For example, the second ordered array can have a second periodicity of from 10 nanometers (nm) to 1 micrometer (μm) (e.g., from 10 to 500 nm, from 500 to 1000 nm, from 10 to 200 nm, from 200 to 400 nm, from 400 to 600 nm, from 600 to 800 nm, from 800 to 1000 nm, from 10 to 900 nm, from 10 to 800 nm, from 10 to 700 nm, from 10 to 600 nm, from 10 to 500 nm, from 10 to 400 nm, from 10 to 300 nm, from 10 to 200 nm, from 10 to 100 nm, from 10 to 50 nm, from 50 to 1000 nm, from 100 to 1000 nm, from 200 to 1000 nm, from 300 to 1000 nm, from 400 to 1000 nm, from 500 to 1000 nm, from 600 to 1000 nm, from 700 to 1000 nm, from 25 to 900 nm, from 50 to 800 nm, or from 100 to 600 nm). In some examples, the second ordered array has a second periodicity of 300 nm or less, 250 nm or less, or 200 nm or less.

In some examples, the second plurality of pillars can have a second average aspect ratio of 0.5 or more and the second ordered array can have a second periodicity of from 10 nanometers (nm) to 1 micrometer (μm).

In some examples, the second plurality of pillars have a second average height of from 200 nanometers (nm) to 2 micrometers (microns, μm) and the second ordered array can have a second periodicity of from 10 nanometers (nm) to 1 micrometer (μm).

In some examples, the second average characteristic dimension of the second plurality of pillars at the second surface of the substrate (e.g., the base of the second plurality of pillars) can be from 50 nm to 2 μm and the second ordered array can have a second periodicity of from 10 nanometers (nm) to 1 micrometer (μm).

In some examples, the second plurality of pillars can have a second average height of from 200 nanometers (nm) to 2 micrometers (microns, μm), the second average characteristic dimension of the second plurality of pillars at the second surface of the substrate (e.g., the base of the second plurality of pillars) can be from 50 nm to 2 μm, and the second ordered array can have a second periodicity of from 10 nanometers (nm) to 1 micrometer (μm).

In some examples, the second plurality of pillars can have a second average aspect ratio of 0.5 or more and a second average height of from 200 nanometers (nm) to 2 micrometers (microns, μm) the second ordered array can have a second periodicity of from 10 nanometers (nm) to 1 micrometer (μm).

In some examples, the second plurality of nanostructures can have a second average aspect ratio of 0.5 or more, the second average characteristic dimension of the second plurality of pillars at the second surface of the substrate (e.g., the base of the second plurality of pillars) can be from 50 nm to 2 μm, and the second ordered array can have a second periodicity of from 10 nanometers (nm) to 1 micrometer (μm).

In some examples, the second plurality of nanostructures can have a second average aspect ratio of 0.5 or more, the second plurality of pillars can have a second average height of from 200 nanometers (nm) to 2 micrometers (microns, μm), the second average characteristic dimension of the second plurality of pillars at the second surface of the substrate (e.g., the base of the second plurality of pillars) can be from 50 nm to 2 μm, and the second ordered array can have a second periodicity of from 10 nanometers (nm) to 1 micrometer (μm).

The second plurality of nanostructures can be substantially uniform over a surface area of 10 square micrometers (m²) or more on the second surface of the substrate (e.g., 15 μm² or more; 20 μm² or more; 25 μm² or more; 30 μm² or more; 35 μm² or more; 40 μm² or more; 45 μm² or more; 50 μm² or more; 60 μm² or more; 70 μm² or more; 80 μm² or more; 90 μm² or more; 100 μm² or more; 125 μm² or more; 200 μm² or more; 225 μm² or more; 250 μm² or more; 300 μm² or more; 350 μm² or more; 400 μm² or more; 450 μm² or more; 500 μm² or more; 600 μm² or more; 700 μm² or more; 800 μm² or more; 900 μm² or more; 1000 μm² or more; 1250 μm² or more; 1500 μm² or more; 1750 μm² or more; 2000 μm² or more; 2250 μm² or more; 2500 μm² or more; 3000 μm² or more; 3500 μm² or more; 4000 μm² or more; 4500 μm² or more; 5000 μm² or more; 6000 μm² or more; 7000 μm² or more; 8000 μm² or more; 9000 μm² or more; 10,000 μm² or more; 15,000 μm² or more; 20,000 μm² or more; 25,000 μm² or more; 30,000 μm² or more; 35,000 μm² or more; 40,000 μm² or more; 45,000 μm² or more; 50,000 μm² or more; 60,000 μm² or more; 70,000 μm² or more; 80,000 μm² or more; 90,000 μm² or more; 100,000 μm² or more; 125,000 μm² or more; 200,000 μm² or more; 225,000 μm² or more; 250,000 μm² or more; 300,000 μm² or more; 350,000 μm² or more; 400,000 μm² or more; 450,000 μm² or more; 500,000 μm² or more; 600,000 μm² or more; 700,000 μm² or more; 800,000 μm² or more; or 900,000 μm² or more). In some examples, the second plurality of nanostructures can be substantially uniform over a surface area of 1 square millimeters (mm²) or more on the second surface of the substrate (e.g., 2 mm² or more; 3 mm² or more; 4 mm² or more; 5 mm² or more; 10 mm² or more; 15 mm² or more; 20 mm² or more; 25 mm² or more; 30 mm² or more; 35 mm² or more; 40 mm² or more; 45 mm² or more; 50 mm² or more; 60 mm² or more; 70 mm² or more; 80 mm² or more; 90 mm² or more; 100 mm² or more; 125 mm² or more; 200 mm² or more; 225 mm² or more; 250 mm² or more; 300 mm² or more; 350 mm² or more; 400 mm² or more; 450 mm² or more; 500 mm² or more; 600 mm² or more; 700 mm² or more; 800 mm² or more; 900 mm² or more; 1000 mm² or more; 1250 mm² or more; 1500 mm² or more; 1750 mm² or more; 2000 mm² or more; 2250 mm² or more; 2500 mm² or more; 3000 mm² or more; 3500 mm² or more; 4000 mm² or more; 4500 mm² or more; 5000 mm² or more; 6000 mm² or more; 7000 mm² or more; 8000 mm² or more; 9000 mm² or more; 10,000 mm² or more; 15,000 mm² or more; 20,000 mm² or more; 25,000 mm² or more; 30,000 mm² or more; 35,000 mm² or more; 40,000 mm² or more; 45,000 mm² or more; 50,000 mm² or more; 60,000 mm² or more; 70,000 mm² or more; 80,000 mm² or more; 90,000 mm² or more; 100,000 mm² or more; 125,000 mm² or more; 200,000 mm² or more; 225,000 mm² or more; 250,000 mm² or more; 300,000 mm² or more; 350,000 mm² or more; 400,000 mm² or more; 450,000 mm² or more; 500,000 mm² or more; 600,000 mm² or more; 700,000 mm² or more; 800,000 mm² or more; or 900,000 mm² or more).

The patterned material can, for example, exhibit improved properties for example relative to the substrate in the absence of the patterning. In some examples, the patterned material exhibits improved anti-glare (anti-reflection) properties, anti-dust properties, anti-fog properties, anti-scratch properties, self-cleaning properties, or a combination thereof, for example relative to the substrate in the absence of the patterning.

In some examples, the patterned material exhibits improved anti-reflection properties. In some examples, the patterned material exhibits reduced reflectance and/or enhanced transmittance at one or more wavelengths, for example relative to the substrate in the absence of the patterning.

In some examples, the patterned material exhibits a transmittance of 90% or more (e.g., 91% or more, 92% or more, 93% or more, 94% or more, 95% or more, 96% or more, 97% or more, 98% or more, or 99% or more) at one or more wavelengths of 300 nm or more (e.g., 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, 900 nm or more, 950 nm or more, 1000 nm or more, 1100 nm or more, 1200 nm or more, 1300 nm or more, 1400 nm or more, 1500 nm or more, 1750 nm or more, 2000 nm or more, 2250 nm or more, 2500 nm or more, 2750 nm or more, 3000 nm or more, 3250 nm or more, 3500 nm or more, 3750 nm or more, 4000 nm or more, 4250 nm or more, or 4500 nm or more). In some examples, the patterned material exhibits a transmittance of 90% or more (e.g., 91% or more, 92% or more, 93% or more, 94% or more, 95% or more, 96% or more, 97% or more, 98% or more, or 99% or more) at one or more wavelengths of 5000 nm or less (e.g., 4750 nm or less, 4500 nm or less, 4250 nm or less, 4000 nm or less, 3750 nm or less, 3500 nm or less, 3250 nm or less, 3000 nm or less, 2750 nm or less, 2500 nm or less, 2250 nm or less, 2000 nm or less, 1750 nm or less, 1500 nm or less, 1400 nm or less, 1300 nm or less, 1200 nm or less, 1100 nm or less, 1000 nm or less, 950 nm or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, or 350 nm or less). In some examples, the wavelength(s) at which the patterned material exhibits a transmittance of 90% or more can range from any of the minimum values described above to any of the maximum values described above. For example, the patterned material can exhibits a transmittance of 90% or more (e.g., 91% or more, 92% or more, 93% or more, 94% or more, 95% or more, 96% or more, 97% or more, 98% or more, or 99% or more) at one or more wavelengths of from 300 nm to 5000 nm (e.g., from 300 nm to 2500 nm, from 2500 nm to 5000 nm, from 300 to 700 nm, from 700 to 5000 nm, from 700 nm to 1500 nm, from 1500 nm to 5000 nm, or from 600 nm to 1500 nm). In some examples, the patterned material exhibits a transmittance of 90% or more (e.g., 91% or more, 92% or more, 93% or more, 94% or more, 95% or more, 96% or more, 97% or more, 98% or more, or 99% or more) over the wavelength range of from 600 nm to 1500 nm

In some examples, the transmittance is at an incidence angle of 0° or more (e.g., 5° or more, 100 or more, 150 or more, 200 or more, 250 or more, 300 or more, 350 or more, 400 or more, 450 or more, 500 or more, 550 or more, 600 or more, 650 or more, 700 or more, 750 or more, or 800 or more). In some examples, the transmittance is at an incident angle of 900 or less (e.g., 850 or less, 800 or less, 750 or less, 700 or less, 650 or less, 600 or less, 550 or less, 500 or less, 450 or less, 400 or less, 350 or less, 300 or less, 250 or less, 200 or less, 150 or less, or 100 or less). The incident angle can range from any of the minimum values described above to any of the maximum values described above. For example, the transmittance can be at an incidence angle of from 0° to 90° (e.g., from 0° to 45°, from 45° to 90°, from 0° to 30°, from 30° to 60°, from 60° to 90°, from 0° to 75°, from 0° to 60°, from 0° to 15°, from 15° to 90°, from 30° to 90°, from 75° to 90°, from 1° to 85°, or from 5° to 80°).

In some examples, the patterned material exhibits improved anti-fog properties. In some examples, the patterned material exhibits reduced fogging/water condensation, for example relative to the substrate in the absence of the patterning. For example, the patterned material can reduce fogging/water condensation by 90% or more (e.g., 91% or more, 92% or more, 93% or more, 94% or more, 95% or more, 96% or more, 97% or more, 98% or more, or 99% or more) relative to the substrate in the absence of the patterning (e.g., a substantially flat/planar substrate).

In some examples, the patterned material exhibits improved anti-dust properties. In some examples, the patterned material exhibits reduced dust adhesion, for example relative to the substrate in the absence of the patterning. For example, the patterned material can reduce dust adhesion by 90% or more (e.g., 91% or more, 92% or more, 93% or more, 94% or more, 95% or more, 96% or more, 97% or more, 98% or more, or 99% or more) relative to the substrate in the absence of the patterning (e.g., a substantially flat/planar substrate).

In some examples, the patterned material exhibits mechanical robustness, e.g. the first plurality of nanostructures and/or the second plurality of nanostructures can exhibit mechanical robustness. In some examples, the patterned material exhibits enhanced toughness while maintaining high stiffness, hardness, and/or scratch resistance, for example relative to the substrate in the absence of the patterning. For example, the patterned material can have a hardness of 1.8 GPa or more (e.g., 5 GPa or more, 10 GPa or more, 15 GPa or more, 20 GPa or more, 25 GPa or more, or 30 GPa or more) relative to the substrate in the absence of the patterning (e.g., a substantially flat/planar substrate) based on the quasi-static, load-controlled indentation test method. For example, the patterned material can have an indentation modulus of 115 GPa or more (e.g., 150 GPa or more, 200 GPa or more, 250 GPa or more, 300 GPa or more, 350 GPa or more, 400 GPa or more, or 440 GPa or more) relative to the substrate in the absence of the patterning (e.g., a substantially flat/planar substrate) based on Oliver-Pharr method.

### Methods of Making

Also disclosed herein are methods of making any of the patterned materials disclosed herein.

For example, the methods can comprise patterning a photoresist layer of a first layered stack thereby making a second layered stack where the photoresist layer is patterned. The first layered stack can, for example, comprise the photoresist layer, an antireflection layer, a polysilicon layer, and a substrate having a first surface, the polysilicon layer being disposed on the first surface of the substrate, the antireflection layer being disposed on the polysilicon layer such that the polysilicon layer is sandwiched between the antireflection layer and the first surface of the substrate, and the photoresist layer being disposed on the antireflection layer such that the antireflection layer is sandwiched between the photoresist layer and the polysilicon layer. In some examples, the first surface of the substrate is substantially flat or planar.

In some examples, the methods further comprise patterning the antireflection layer of the second layered stack, to transfer the pattern of the photoresist layer to the antireflection layer, thereby making a third layered stack where the photoresist layer and the antireflection layer are patterned. In some examples, the methods further comprise patterning the polysilicon layer of the third layered stack to transfer the pattern of the antireflection layer to the polysilicon layer, thereby making a fourth layered stack where the photoresist layer, the antireflection layer, and the polysilicon layer are patterned. In some examples, the methods further comprise etching the fourth layered stack to transfer the pattern of the polysilicon layer to the substrate and remove the photoresist layer, the antireflection layer, and the polysilicon layer, thereby making the patterned material.

In some examples, the methods can comprise patterning a photoresist layer of a first precursor layered stack thereby making a first intermediate layered stack where the photoresist layer is patterned. The first precursor layered stack can, for example, comprise the photoresist layer, a polysilicon layer, and a substrate having a first surface, the polysilicon layer being disposed on the first surface of the substrate, the photoresist layer being disposed on the polysilicon layer such that the polysilicon layer is sandwiched between the photoresist layer and the first surface of the substrate. In some examples, the first surface of the substrate is substantially flat or planar.

In some examples, the methods further comprise patterning the polysilicon layer of the first intermediate layered stack, to transfer the pattern of the photoresist layer to the polysilicon layer, thereby making a second intermediate layered stack where the photoresist layer and the polysilicon layer are patterned. In some examples, the methods further comprise etching the second intermediate layered stack to transfer the pattern of the polysilicon layer to the substrate and remove the photoresist layer and the polysilicon layer, thereby making the patterned material.

In some examples, the substrate has a second surface, the second surface being opposite and spaced apart from the first surface (e.g., the first surface is a top surface and the second surface is a bottom surface). In some examples, the second surface of the substrate is substantially flat or planar. In some examples, the methods can further comprise patterning the second surface.

For example, the methods can comprise patterning a photoresist layer of a fifth layered stack thereby making a sixth layered stack where the photoresist layer is patterned. The fifth layered stack can, for example, comprise the photoresist layer, an antireflection layer, a polysilicon layer, and the substrate having the second surface, the polysilicon layer being disposed on the second surface of the substrate, the antireflection layer being disposed on the polysilicon layer such that the polysilicon layer is sandwiched between the antireflection layer and the second surface of the substrate, and the photoresist layer being disposed on the antireflection layer such that the antireflection layer is sandwiched between the photoresist layer and the polysilicon layer. In some examples, the methods further comprise patterning the antireflection layer of the sixth layered stack, to transfer the pattern of the photoresist layer to the antireflection layer, thereby making a seventh layered stack where the photoresist layer and the antireflection layer are patterned. In some examples, the methods further comprise patterning the polysilicon layer of the seventh layered stack to transfer the pattern of the antireflection layer to the polysilicon layer, thereby making an eighth layered stack where the photoresist layer, the antireflection layer, and the polysilicon layer are patterned. In some examples, the methods further comprise etching the eighth layered stack to transfer the pattern of the polysilicon layer to the substrate and remove the photoresist layer, the antireflection layer, and the polysilicon layer, thereby making the patterned material.

In some examples, the methods can comprise patterning a photoresist layer of a second precursor layered stack thereby making a third intermediate layered stack where the photoresist layer is patterned. The second precursor layered stack can, for example, comprise the photoresist layer, a polysilicon layer, and the substrate having the second surface, the polysilicon layer being disposed on the second surface of the substrate, the photoresist layer being disposed on the polysilicon layer such that the polysilicon layer is sandwiched between the photoresist layer and the second surface of the substrate. In some examples, the methods further comprise patterning the polysilicon layer of the third intermediate layered stack, to transfer the pattern of the photoresist layer to the polysilicon layer, thereby making a fourth intermediate layered stack where the photoresist layer and the polysilicon layer are patterned. In some examples, the methods further comprise etching the fourth intermediate layered stack to transfer the pattern of the polysilicon layer to the substrate and remove the photoresist layer and the polysilicon layer, thereby making the patterned material.

In some examples, the polysilicon layer in the first layered stack, the fifth layered stack, the first precursor layered stack, the second precursor layered stack, or a combination thereof can independently have an average thickness of 500 nm or more (e.g., 600 nm or more, 700 nm or more, 800 nm or more, 900 nm or more, 1 micrometer (micron, μm) or more, 1.25 μm or more, 1.5 μm or more, 1.75 μm or more, 2 μm or more, 2.25 μm or more, 2.5 μm or more, 2.75 μm or more, 3 μm or more, 3.25 μm or more, 3.5 μm or more, 3.75 μm or more, 4 μm or more, 4.25 μm or more, 4.5 μm or more, 4.75 μm or more, 5 μm or more, 5.5 μm or more, 6 μm or more, 6.5 μm or more, 7 μm or more, 7.5 μm or more, 8 μm or more, 8.5 μm or more, or 9 μm or more). In some examples, the polysilicon layer in the first layered stack, the fifth layered stack, the first precursor layered stack, the second precursor layered stack, or a combination thereof can independently have an average thickness of 10 micrometers (microns, μm) or less (e.g., 9.5 μm or less, 9 μm or less, 8.5 μm or less, 8 μm or less, 7.5 μm or less, 7 μm or less, 6.5 μm or less, 6 μm or less, 5.5 μm or less, 5 μm or less, 4.75 μm or less, 4.5 μm or less, 4.25 μm or less, 4 μm or less, 3.75 μm or less, 3.5 μm or less, 3.25 μm or less, 3 μm or less, 2.75 μm or less, 2.5 μm or less, 2.25 μm or less, 2 μm or less, 1.75 μm or less, 1.5 μm or less, 1.25 μm or less, 1 μm or less, 900 nanometers (nm) or less, 800 nm or less, or 700 nm or less). The average thickness of the polysilicon layer in the first layered stack, the fifth layered stack, the first precursor layered stack, the second precursor layered stack, or a combination thereof can independently range from any of the minimum values described above to any of the maximum values described above. For example, the polysilicon layer in the first layered stack, the fifth layered stack, the first precursor layered stack, the second precursor layered stack, or a combination thereof can independently have an average thickness of from 500 nm to 10 μmicrons (e.g., from 500 nm to 5 μmicrons, from 5 microns to 10 μmicrons, from 500 nm to 1 μmicron, from 1 μmicron to 4 μmicrons, from 4 μmicrons to 7 μmicrons, from 7 μmicrons to 10 μmicrons, from 500 nm to 7 μmicrons, from 500 nm to 4 μmicrons, from 500 nm to 2 μmicrons, from 1 μmicron to 10 μmicrons, from 2 μmicrons to 10 μmicrons, from 4 microns to 10 μmicrons, from 600 nm to 9.5 μmicrons, or from 700 nm to 9 μmicrons).

In some examples, the antireflection layer in the first layered stack, the fifth layered stack, the first precursor layered stack, the second precursor layered stack, or a combination thereof can independently have an average thickness of 50 nm or more (e.g., 55 nm or more, 60 nm or more, 65 nm or more, 70 nm or more, 75 nm or more, 80 nm or more, 85 nm or more, 90 nm or more, 95 nm or more, 100 nm or more, 110 nm or more, 120 nm or more, 130 nm or more, 140 nm or more, 150 nm or more, 160 nm or more, 170 nm or more, or 180 nm or more). In some examples, the antireflection layer in the first layered stack, the fifth layered stack, the first precursor layered stack, the second precursor layered stack, or a combination thereof can independently have an average thickness of 200 nm or less (e.g., 190 nm or less, 180 nm or less, 170 nm or less, 160 nm or less, 150 nm or less, 140 nm or less, 130 nm or less, 120 nm or less, 110 nm or less, 100 nm or less, 95 nm or less, 90 nm or less, 85 nm or less, 80 nm or less, 75 nm or less, 70 nm or less, 65 nm or less, or 60 nm or less). The average thickness of the antireflection layer in the first layered stack, the fifth layered stack, the first precursor layered stack, the second precursor layered stack, or a combination thereof can independently range from any of the minimum values described above to any of the maximum values described above. For example, the antireflection layer in the first layered stack, the fifth layered stack, the first precursor layered stack, the second precursor layered stack, or a combination thereof can independently have an average thickness of from 50 to 200 nm (e.g., from 50 nm to 125 nm, from 125 nm to 200 nm, from 50 nm to 100 nm, from 100 nm to 150 nm, from 150 nm to 200 nm, from 50 nm to 175 nm, from 50 nm to 150 nm, from 50 nm to 75 nm, from 75 nm to 200 nm, from 100 nm to 200 nm, from 175 nm to 200 nm, from 60 nm to 190 nm, or from 75 nm to 175 nm).

In some examples, the polysilicon layer has an average thickness of from 500 nm to 10 microns and the antireflection layer has an average thickness of from 50 to 200 nm in the first layered stack, the fifth layered stack, the first precursor layered stack, the second precursor layered stack, or a combination thereof.

In some examples, the photoresist layer in the first layered stack, the fifth layered stack, the first precursor layered stack, the second precursor layered stack, or a combination thereof can independently have an average thickness of 100 nm or more (e.g., 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, or 900 nm or more). In some examples, the photoresist layer in the first layered stack, the fifth layered stack, the first precursor layered stack, the second precursor layered stack, or a combination thereof can independently have an average thickness of 1000 nm or less (e.g., 950 nm or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, or 150 nm or less). The average thickness of the photoresist layer in the first layered stack, the fifth layered stack, the first precursor layered stack, the second precursor layered stack, or a combination thereof can independently range from any of the minimum values described above to any of the maximum values described above. For example, the photoresist layer in the first layered stack, the fifth layered stack, the first precursor layered stack, the second precursor layered stack, or a combination thereof can independently have an average thickness of from 100 nm to 1000 nm (e.g., from 100 nm to 550 nm, from 500 nm to 1000 nm, from 100 nm to 400 nm, from 400 nm to 700 nm, from 700 nm to 1000 nm, from 100 nm to 900 nm, from 100 nm to 800 nm, from 100 nm to 700 nm, from 100 nm to 600 nm, from 100 nm to 500 nm, from 100 nm to 300 nm, from 100 nm to 200 nm, from 200 nm to 1000 nm, from 300 nm to 1000 nm, from 400 nm to 1000 nm, from 500 nm to 1000 nm, from 600 nm to 1000 nm, from 800 nm to 1000 nm, from 900 nm to 1000 nm, from 150 nm to 950 nm, or from 200 nm to 900 nm).

In some examples, the polysilicon layer has an average thickness of from 500 nm to 10 microns and the photoresist layer has an average thickness of from 100 nm to 1000 nm in the first layered stack, the fifth layered stack, the first precursor layered stack, the second precursor layered stack, or a combination thereof. In some examples, the antireflection layer has an average thickness of from 50 to 200 nm and the photoresist layer has an average thickness of from 100 nm to 1000 nm in the first layered stack, the fifth layered stack, the first precursor layered stack, the second precursor layered stack, or a combination thereof. In some examples, the polysilicon layer has an average thickness of from 500 nm to 10 μmicrons, the antireflection layer has an average thickness of from 50 to 200 nm, and the photoresist layer has an average thickness of from 100 nm to 1000 nm in the first layered stack, the fifth layered stack, the first precursor layered stack, the second precursor layered stack, or a combination thereof.

In some examples, the photoresist layer comprises a photosensitive polymer, for example that records a light intensity pattern. The photoresist layer can comprise any suitable composition, such as those known in the art.

The photoresist layer can be patterned using any suitable method, such as, for example, nanoimprint lithography, electron beam lithography, ion beam lithography, optical projection lithography, optical direct-write lithography, interference lithography, or a combination thereof. In some examples, patterning the photoresist layer comprises using interference lithography. In some examples, patterning the photoresist comprises Llyod's mirror interference lithography with two orthogonal exposures. In some examples, patterning the photoresist further comprises developing the photoresist by exposing the patterned photoresist to a solvent.

In some examples, the antireflection layer comprises a polymer that absorbs light at one or more wavelengths. The antireflection layer can comprise any suitable composition, such as those known in the art.

The antireflection layer can be patterned using any suitable method, such as, for example, ion milling, reactive ion etching (RIE), inductively coupled plasma reactive ion etching (ICP-RIE), or a combination thereof. In some examples, patterning the antireflection layer comprises using inductively coupled plasma reactive ion etching (ICP-RIE). In some examples, patterning the antireflection layer comprises using inductively coupled plasma reactive ion etching (ICP-RIE) with O₂, CF₄, or a combination thereof. In some examples, patterning the antireflection layer comprises using O₂ inductively coupled plasma reactive ion etching (ICP-RIE).

In some examples, patterning the antireflection layer can comprise using O₂ inductively coupled plasma reactive ion etching (ICP-RIE) for an amount of time of 1 minute or more (e.g., 1.25 minutes or more, 1.5 minutes or more, 1.75 minutes or more, 2 minutes or more, 2.25 minutes or more, 2.5 minutes or more, 2.75 minutes or more, 3 minutes or more, 3.25 minutes or more, 3.5 minutes or more, 3.75 minutes or more, 4 minutes or more, 4.25 minutes or more, or 4.5 minutes or more). In some examples, patterning the antireflection layer can comprises using O₂ ICP-RIE for an amount of time of 5 minutes or less (e.g., 4.75 minutes or less, 4.5 minutes or less, 4.25 minutes or less, 4 minutes or less, 3.75 minutes or less, 3.5 minutes or less, 3.25 minutes or less, 3 minutes or less, 2.75 minutes or less, 2.5 minutes or less, 2.25 minutes or less, 2 minutes or less, 1.75 minutes or less, or 1.5 minutes or less). The amount of time for which the antireflection layer is patterned using O₂ ICP-RIE can range from any of the minimum values described above to any of the maximum values described above. For example, patterning the antireflection layer can comprises using O₂ ICP-RIE for an amount of time of from 1 minute to 5 minutes (e.g., from 1 minute to 3 minutes, from 3 to 5 minutes, from 1 to 2 minutes, from 2 to 3 minutes, from 3 to 4 minutes, from 4 to 5 minutes, from 1 to 4 minutes, from 2 to 5 minutes, or from 2 to 4 minutes).

In some examples, patterning the antireflection layer can comprise using O₂ ICP-RIE at an RF power of 10 W or more (e.g., 15 W or more, 20 W or more, 25 W or more, 30 W or more, 35 W or more, 40 W or more, 45 W or more, 50 W or more, 60 W or more, 70 W or more, 80 W or more, 90 W or more, 100 W or more, 125 W or more, 150 W or more, 175 W or more, 200 W or more, 225 W or more, or 250 W or more). In some examples, patterning the antireflection layer can comprise using O₂ ICP-RIE at an RF power of 300 W or less (e.g., 275 W or less, 250 W or less, 225 W or less, 200 W or less, 175 W or less, 150 W or less, 125 W or less, 100 W or less, 90 W or less, 80 W or less, 70 W or less, 60 W or less, 50 W or less, 45 W or less, 40 W or less, 35 W or less, 30 W or less, 25 W or less, or 20 W or less). The RF power at which the antireflection layer is patterned using O₂ ICP-RIE can range from any of the minimum values described above to any of the maximum values described above. For example, patterning the antireflection layer can comprise using O₂ ICP-RIE at a RF power of from 10 to 300 W (e.g., from 10 to 150 W, from 150 to 300 W, from 10 to 100 W, from 100 to 200 W, from 200 to 300 W, from 10 to 250 W, from 10 to 200 W, from 10 to 50 W, from 10 to 25 W, from 25 to 300 W, from 50 to 300 W, from 100 to 300 W, from 250 to 300 W, from 15 to 275 W, or from 25 to 250 W). In some examples, patterning the antireflection layer can comprises using O₂ ICP-RIE for an amount of time of from 1 minute to 5 minutes and at a RF power of from 10 to 300 W.

In some examples, patterning the antireflection layer can comprise using O₂ ICP-RIE at a pressure of 1 μmTorr or more (e.g., 2 μmTorr or more, 3 μmTorr or more, 4 μmTorr or more, 5 μmTorr or more, 10 μmTorr or more, 15 μmTorr or more, 20 μmTorr or more, or 25 μmTorr or more). In some examples, patterning the antireflection layer can comprise using O₂ ICP-RIE at a pressure of 30 μmTorr or less (e.g., 25 μmTorr or less, 20 μmTorr or less, 15 μmTorr or less, 10 μmTorr or less, or 5 μmTorr or less). The pressure at which the antireflection layer is patterned using O₂ ICP-RIE can range from any of the minimum values described above to any of the maximum values described above. For example, patterning the antireflection layer can comprise using O₂ ICP-RIE at a pressure of from 1 to 30 μmTorr (e.g., from 1 to 15 μmTorr, from 15 to 30 μmTorr, from 1 to 10 mTorr, from 10 to 20 μmTorr, from 20 to 30 μmTorr, from 5 to 30 μmTorr, from 10 to 30 μmTorr, from 1 to 25 μmTorr, from 1 to 20 μmTorr, or from 5 to 25 μmTorr).

In some examples, patterning the antireflection layer can comprises using O₂ ICP-RIE for an amount of time of from 1 minute to 5 minutes and at a pressure of from 1 to 30 μmTorr. In some examples, patterning the antireflection layer can comprises using O₂ ICP-RIE for at a RF power of from 10 to 300 W and at a pressure of from 1 to 30 μmTorr. In some examples, patterning the antireflection layer can comprises using O₂ ICP-RIE for an amount of time of from 1 minute to 5 minutes, at a RF power of from 10 to 300 W, and at a pressure of from 1 to 30 μmTorr.

In some examples, patterning the antireflection layer can comprise using O₂ ICP-RIE with an 02 flow rate of 5 sccm or more (e.g., 10 sccm or more, 15 sccm or more, 20 sccm or more, 25 sccm or more, 30 sccm or more, 35 sccm or more, 40 sccm or more, or 45 sccm or more). In some examples, patterning the antireflection layer can comprise using O₂ ICP-RIE with an O₂ flow rate of 50 sccm or less (e.g., 45 sccm or less, 40 sccm or less, 35 sccm or less, 30 sccm or less, 25 sccm or less, 20 sccm or less, 15 sccm or less, or 10 sccm or less). The O₂ flow rate at which the antireflection layer is patterned using O₂ ICP-RIE can range from any of the minimum values described above to any of the maximum values described above. For example, patterning the antireflection layer can comprise using O₂ ICP-RIE with an O₂ flow rate of from 5 to 50 sccm (e.g., from 5 to 25 sccm, from 25 to 50 sccm, from 5 to 10 sccm, from 10 to 20 sccm, from 20 to 30 sccm, from 30 to 40 sccm, from 40 to 50 sccm, from 5 to 40 sccm, from 5 to 30 sccm, from 5 to 20 sccm, from 10 to 50 sccm, from 20 to 50 sccm, from 30 to 50 sccm, from 5 to 45 sccm, from 10 to 40 sccm, or from 15 to 35 sccm).

In some examples, patterning the antireflection layer can comprises using O₂ ICP-RIE for an amount of time of from 1 minute to 5 minutes and with an O₂ flow rate of from 5 to 50 sccm. In some examples, patterning the antireflection layer can comprises using O₂ ICP-RIE at a RF power of from 10 to 300 W and with an O₂ flow rate of from 5 to 50 sccm. In some examples, patterning the antireflection layer can comprises using O₂ ICP-RIE at a pressure of from 1 to 30 mTorr and with an O₂ flow rate of from 5 to 50 sccm.

In some examples, patterning the antireflection layer can comprises using O₂ ICP-RIE for an amount of time of from 1 minute to 5 minutes, at a RF power of from 10 to 300 W, and with an O₂ flow rate of from 5 to 50 sccm. In some examples, patterning the antireflection layer can comprises using O₂ ICP-RIE for an amount of time of from 1 minute to 5 minutes, at a pressure of from 1 to 30 μmTorr, and with an O₂ flow rate of from 5 to 50 sccm. In some examples, patterning the antireflection layer can comprises using O₂ ICP-RIE at a RF power of from 10 to 300 W, at a pressure of from 1 to 30 μmTorr, and with an O₂ flow rate of from 5 to 50 sccm.

In some examples, patterning the antireflection layer can comprises using O₂ ICP-RIE for an amount of time of from 1 minute to 5 minutes, at a RF power of from 10 to 300 W, at a pressure of from 1 to 30 μmTorr, and with an O₂ flow rate of from 5 to 50 sccm.

In some examples, patterning the antireflection layer can comprises using O₂ inductively coupled plasma reactive ion etching (ICP-RIE): for an amount of time of from 1 minute to 5 minutes; at a RF power of from 10 to 300 W; at a pressure of from 1 to 30 μmTorr; with a O₂ flow rate of from 5 to 50 sccm; or a combination thereof. In some examples, patterning the antireflection layer can comprises using O₂ inductively coupled plasma reactive ion etching (ICP-RIE): for an amount of time of from 1 minute to 5 minutes; at a RF power of from 10 to 300 W; at a pressure of from 1 to 30 μmTorr; and with a O₂ flow rate of from 5 to 50 sccm.

The polysilicon layer can be patterned using any suitable method, such as, for example, deep reactive ion etching (DRIE), metal-assisted chemical etching (MacEtch), ICP-RIE, or a combination thereof. In some examples, patterning the polysilicon layer comprises using ICP-RIE, such as ICP-RIE with low RF power. In some examples, patterning the polysilicon layer comprises using ICP-RIE with low RF power and with HBr, Cl₂, BCl₃, or a combination thereof. In some examples, patterning the polysilicon layer comprises using HBr ICP-RIE with low RF power. In some examples, the low RF power used to pattern the polysilicon layer enhances etch selectivity.

In some examples, patterning the polysilicon layer can comprise using HBr ICP-RIE with low RF power for an amount of time of 30 minutes or more (e.g., 35 minutes or more, 40 minutes or more, 45 minutes or more, 50 minutes or more, 55 minutes or more, 60 minutes or more, 65 minutes or more, 70 minutes or more, 75 minutes or more, 80 minutes or more, 85 minutes or more, 90 minutes or more, 95 minutes or more, 100 minutes or more, 105 minutes or more, 110 minutes or more, 115 minutes or more, 120 minutes or more, 125 minutes or more, 130 minutes or more, 135 minutes or more, 140 minutes or more, 145 minutes or more, 150 minutes or more, 155 minutes or more, 160 minutes or more, 165 minutes or more, 170 minutes or more, 175 minutes or more, 180 minutes or more, 185 minutes or more, or 190 minutes or more). In some examples, patterning the polysilicon layer can comprise using HBr ICP-RIE with low RF power for an amount of time of 200 minutes or less (e.g., 195 minutes or less, 190 minutes or less, 185 minutes or less, 180 minutes or less, 175 minutes or less, 170 minutes or less, 165 minutes or less, 160 minutes or less, 155 minutes or less, 150 minutes or less, 145 minutes or less, 140 minutes or less, 135 minutes or less, 130 minutes or less, 125 minutes or less, 120 minutes or less, 115 minutes or less, 110 minutes or less, 105 minutes or less, 100 minutes or less, 95 minutes or less, 90 minutes or less, 85 minutes or less, 80 minutes or less, 75 minutes or less, 70 minutes or less, 65 minutes or less, 60 minutes or less, 55 minutes or less, 50 minutes or less, 45 minutes or less, or 40 minutes or less). The amount of time for which the polysilicon layer is patterned using HBr ICP-RIE with low RF power can range from any of the minimum values described above to any of the maximum values described above. For example, patterning the polysilicon layer can comprise using HBr ICP-RIE with low RF power for an amount of time of from 30 minutes to 200 minutes (e.g., from 30 to 115 minutes, from 115 to 200 minutes, from 30 to 90 minutes, from 90 to 120 minutes, from 120 to 150 minutes, from 150 to 180 minutes, from 180 to 200 minutes, from 30 to 180 minutes, from 30 to 150 minutes, from 30 to 120 minutes, from 30 to 90 minutes, from 30 to 60 minutes, from 45 to 200 minutes, from 60 to 200 minutes, from 90 to 200 minutes, from 120 to 200 minutes, from 150 to 200 minutes, from 35 to 195 minutes, from 40 to 190 minutes, or from 45 to 180 minutes).

In some examples, patterning the polysilicon layer can comprise using HBr ICP-RIE with an RF power of 1 W or more (e.g., 2 W or more, 3 W or more, 4 W or more, 5 W or more, 10 W or more, 15 W or more, 20 W or more, 25 W or more, 30 W or more, 35 W or more, or 40 W or more). In some examples, patterning the polysilicon layer can comprise using HBr ICP-RIE with an RF power of 50 W or less (e.g., 45 W or less, 40 W or less, 35 W or less, 30 W or less, 25 W or less, 20 W or less, 15 W or less, 10 W or less, or 5 W or less). The RF power at which the polysilicon layer is patterned using HBr ICP-RIE can range from any of the minimum values described above to any of the maximum values described above. For example, patterning the polysilicon layer can comprise using HBr ICP-RIE with an RF power of from 1 to 50 W (e.g., from 1 to 25 W, from 25 to 50 W, from 1 to 10 W, from 10 to 20 W, from 20 to 30 W, from 30 to 40 W, from 40 to 50 W, from 1 to 40 W, from 1 to 30 W, from 1 to 20 W, or from 1 to 5 W). In some examples, patterning the polysilicon layer can comprise using HBr ICP-RIE for an amount of time of from 30 minutes to 200 minutes and at an RF power of from 1 to 50 W.

In some examples, patterning the polysilicon layer can comprise using HBr ICP-RIE with low RF power and an ICP power of 100 W or more (e.g., 125 W or more, 150 W or more, 175 W or more, 200 W or more, 225 W or more, 250 W or more, 275 W or more, 300 W or more, 325 W or more, 350 W or more, 375 W or more, 400 W or more, 425 W or more, 450 W or more, 475 W or more, 500 W or more, 525 W or more, or 550 W or more). In some examples, patterning the polysilicon layer can comprise using HBr ICP-RIE with low RF power and an ICP power of 600 W or less (e.g., 575 W or less, 550 W or less, 525 W or less, 500 W or less, 475 W or less, 450 W or less, 425 W or less, 400 W or less, 375 W or less, 350 W or less, 325 W or less, 300 W or less, 275 W or less, 250 W or less, 225 W or less, 200 W or less, 175 W or less, or 150 W or less). The ICP power at which the polysilicon layer is patterned using HBr ICP-RIE with low RF power can range from any of the minimum values described above to any of the maximum values described above. For example, patterning the polysilicon layer can comprise using HBr ICP-RIE with low RF power and an ICP power of from 100 to 600 W (e.g., from 100 to 350 W, from 350 to 600 W, from 100 to 200 W, from 200 to 300 W, from 300 to 400 W, from 400 to 500 W, from 500 to 600 W, from 100 to 500 W, from 100 to 400 W, from 100 to 300 W, from 200 to 600 W, from 300 to 600 W, from 400 to 600 W, from 125 to 575 W, or from 150 to 550 W).

In some examples, patterning the polysilicon layer can comprise using HBr ICP-RIE with a low RF power for an amount of time of from 30 minutes to 200 minutes and an ICP power of from 100 to 600 W. In some examples, patterning the polysilicon layer can comprise using HBr ICP-RIE at an RF power of from 1 to 50 W and an ICP power of from 100 to 600 W. In some examples, patterning the polysilicon layer can comprise using HBr ICP-RIE for an amount of time of from 30 minutes to 200 minutes, at an RF power of from 1 to 50 W, and an ICP power of from 100 to 600 W.

In some examples, patterning the polysilicon layer can comprise using HBr ICP-RIE with low RF power at a pressure of 1 μmTorr or more (e.g., 2 μmTorr or more, 3 μmTorr or more, 4 mTorr or more, 5 μmTorr or more, 10 μmTorr or more, 15 μmTorr or more, 20 μmTorr or more, or 25 mTorr or more). In some examples, patterning the polysilicon layer can comprise using HBr ICP-RIE with low RF power at a pressure of 30 μmTorr or less (e.g., 25 μmTorr or less, 20 μmTorr or less, 15 μmTorr or less, 10 μmTorr or less, or 5 μmTorr or less). The pressure at which the polysilicon layer is patterned using HBr ICP-RIE with low RF power can range from any of the minimum values described above to any of the maximum values described above. For example, patterning the polysilicon layer can comprise using HBr ICP-RIE with low RF power at a pressure of from 1 to 30 μmTorr (e.g., from 1 to 15 μmTorr, from 15 to 30 μmTorr, from 1 to 10 mTorr, from 10 to 20 μmTorr, from 20 to 30 μmTorr, from 5 to 30 μmTorr, from 10 to 30 μmTorr, from 1 to 25 μmTorr, from 1 to 20 μmTorr, or from 5 to 25 μmTorr).

In some examples, patterning the polysilicon layer can comprise using HBr ICP-RIE with a low RF power for an amount of time of from 30 minutes to 200 minutes and at a pressure of from 1 to 30 μmTorr. In some examples, patterning the polysilicon layer can comprise using HBr ICP-RIE at an RF power of from 1 to 50 W and at a pressure of from 1 to 30 μmTorr. In some examples, patterning the polysilicon layer can comprise using HBr ICP-RIE with a low RF power, an ICP power of from 100 to 600 W, and at a pressure of from 1 to 30 μmTorr.

In some examples, patterning the polysilicon layer can comprise using HBr ICP-RIE for an amount of time of from 30 minutes to 200 minutes, with an RF power of from 1 to 50 W, and at a pressure of from 1 to 30 μmTorr. In some examples, patterning the polysilicon layer can comprise using HBr ICP-RIE with a low RF power for an amount of time of from 30 minutes to 200 minutes, an ICP power of from 100 to 600 W, and at a pressure of from 1 to 30 μmTorr. In some examples, patterning the polysilicon layer can comprise using HBr ICP-RIE at an RF power of from 1 to 50 W, an ICP power of from 100 to 600 W, and at a pressure of from 1 to 30 mTorr.

In some examples, patterning the polysilicon layer can comprise using HBr ICP-RIE for an amount of time of from 30 minutes to 200 minutes, at an RF power of from 1 to 50 W, an ICP power of from 100 to 600 W, and at a pressure of from 1 to 30 μmTorr.

In some examples, patterning the polysilicon layer can comprise using HBr ICP-RIE with low RF power and a HBr flow rate of 5 sccm or more (e.g., 10 sccm or more, 15 sccm or more, 20 sccm or more, 25 sccm or more, 30 sccm or more, 35 sccm or more, 40 sccm or more, or 45 sccm or more). In some examples, patterning the polysilicon layer can comprise using HBr ICP-RIE with low RF power and a HBr flow rate of 50 sccm or less (e.g., 45 sccm or less, 40 sccm or less, 35 sccm or less, 30 sccm or less, 25 sccm or less, 20 sccm or less, 15 sccm or less, or 10 sccm or less). The HBr flow rate at which the polysilicon layer is patterned using HBr ICP-RIE with a low RF power can range from any of the minimum values described above to any of the maximum values described above. For example, patterning the polysilicon layer can comprise using HBr ICP-RIE with low RF power and a HBr flow rate of from 5 to 50 sccm (e.g., from 5 to 25 sccm, from 25 to 50 sccm, from 5 to 10 sccm, from 10 to 20 sccm, from 20 to 30 sccm, from 30 to 40 sccm, from 40 to 50 sccm, from 5 to 40 sccm, from 5 to 30 sccm, from 5 to 20 sccm, from 10 to 50 sccm, from 20 to 50 sccm, from 30 to 50 sccm, from 5 to 45 sccm, from 10 to 40 sccm, or from 15 to 35 sccm).

In some examples, patterning the polysilicon layer can comprise using HBr ICP-RIE with a low RF power for an amount of time of from 30 minutes to 200 minutes and a HBr flow rate of from 5 to 50 sccm. In some examples, patterning the polysilicon layer can comprise using HBr ICP-RIE at an RF power of from 1 to 50 W and a HBr flow rate of from 5 to 50 sccm. In some examples, patterning the polysilicon layer can comprise using HBr ICP-RIE with a low RF power, an ICP power of from 100 to 600 W, and a HBr flow rate of from 5 to 50 sccm. In some examples, patterning the polysilicon layer can comprise using HBr ICP-RIE with a low RF power at a pressure of from 1 to 30 μmTorr and a HBr flow rate of from 5 to 50 sccm.

In some examples, patterning the polysilicon layer can comprise using HBr ICP-RIE with for an amount of time of from 30 minutes to 200 minutes, a RF power of from 1 to 50 W, and a HBr flow rate of from 5 to 50 sccm. In some examples, patterning the polysilicon layer can comprise using HBr ICP-RIE with a low RF power for an amount of time of from 30 minutes to 200 minutes, an ICP power of from 100 to 600 W, and a HBr flow rate of from 5 to 50 sccm. In some examples, patterning the polysilicon layer can comprise using HBr ICP-RIE with a low RF power for an amount of time of from 30 minutes to 200 minutes, at a pressure of from 1 to 30 mTorr, and a HBr flow rate of from 5 to 50 sccm. In some examples, patterning the polysilicon layer can comprise using HBr ICP-RIE with a low RF power, an ICP power of from 100 to 600 W, and a HBr flow rate of from 5 to 50 sccm. In some examples, patterning the polysilicon layer can comprise using HBr ICP-RIE at an RF power of from 1 to 50 W, at a pressure of from 1 to 30 μmTorr, and a HBr flow rate of from 5 to 50 sccm. In some examples, patterning the polysilicon layer can comprise using HBr ICP-RIE with a low RF power, an ICP power of from 100 to 600 W, at a pressure of from 1 to 30 μmTorr, and a HBr flow rate of from 5 to 50 sccm.

In some examples, patterning the polysilicon layer can comprise using HBr ICP-RIE for an amount of time of from 30 minutes to 200 minutes, with an RF power of from 1 to 50 W, an ICP power of from 100 to 600 W, and a HBr flow rate of from 5 to 50 sccm. In some examples, patterning the polysilicon layer can comprise using HBr ICP-RIE for an amount of time of from 30 minutes to 200 minutes, with an RF power of from 1 to 50 W, at a pressure of from 1 to 30 mTorr, and a HBr flow rate of from 5 to 50 sccm. In some examples, patterning the polysilicon layer can comprise using HBr ICP-RIE with a low RF power for an amount of time of from 30 minutes to 200 minutes, an ICP power of from 100 to 600 W, at a pressure of from 1 to 30 mTorr, and a HBr flow rate of from 5 to 50 sccm. In some examples, patterning the polysilicon layer can comprise using HBr ICP-RIE at an RF power of from 1 to 50 W, an ICP power of from 100 to 600 W, at a pressure of from 1 to 30 μmTorr, and a HBr flow rate of from 5 to 50 sccm.

In some examples, patterning the polysilicon layer can comprise using HBr ICP-RIE for an amount of time of from 30 minutes to 200 minutes, at an RF power of from 1 to 50 W, an ICP power of from 100 to 600 W, at a pressure of from 1 to 30 μmTorr, and a HBr flow rate of from 5 to 50 sccm.

In some examples, patterning the polysilicon layer comprises using HBr ICP-RIE with low RF power: for an amount of time of 30 minutes to 200 minutes; at a RF power of from 1 to 50 W; at an ICP power of from 100 to 600 W; at a pressure of from 1 to 30 μmTorr; with a HBr flow rate of from 5 to 50 sccm; or a combination thereof. In some examples, patterning the polysilicon layer comprises using HBr ICP-RIE with low RF power: for an amount of time of 30 minutes to 200 minutes; at a RF power of from 1 to 50 W; at an ICP power of from 100 to 600 W; at a pressure of from 1 to 30 μmTorr; and with a HBr flow rate of from 5 to 50 sccm.

The fourth layered stack, the eighth layered stack, the second intermediate layered stack, the fourth intermediate layered stack, or a combination thereof can independently be etched and/or patterned using any suitable method, such as, for example, ion milling, reactive ion etching, ICP-RIE, or a combination thereof. In some examples, etching and/or patterning the fourth layered stack, the eighth layered stack, the second intermediate layered stack, the fourth intermediate layered stack, or a combination thereof can independently comprise using ICP-RIE. In some examples, etching and/or patterning the fourth layered stack, the eighth layered stack, the second intermediate layered stack, the fourth intermediate layered stack, or a combination thereof can independently comprise using ICP-RIE with HBr, BCl₃, Cl₂, or a combination thereof. In some examples, etching and/or patterning the fourth layered stack, the eighth layered stack, the second intermediate layered stack, the fourth intermediate layered stack, or a combination thereof can independently comprise using ICP-RIE with HBr and BCl₃ (e.g., HBr/BCl₃ ICP-RIE).

In some examples, etching the fourth layered stack, the eighth layered stack, the second intermediate layered stack, the fourth intermediate layered stack, or a combination thereof can independently comprise using HBr/BCl₃ ICP-RIE for an amount of time of 10 minutes of more (e.g., 15 minutes or more, 20 minutes or more, 25 minutes or more, 30 minutes or more, 35 minutes or more, 40 minutes or more, 45 minutes or more, 50 minutes or more, 55 minutes or more, 60 minutes or more, 65 minutes or more, 70 minutes or more, 75 minutes or more, 80 minutes or more, 85 minutes or more, 90 minutes or more, 95 minutes or more, 100 minutes or more, 105 minutes or more, or 110 minutes or more). In some examples, etching the fourth layered stack, the eighth layered stack, the second intermediate layered stack, the fourth intermediate layered stack, or a combination thereof can independently comprise using HBr/BCl₃ ICP-RIE for an amount of time of 120 minutes or less (e.g., 115 minutes or less, 110 minutes or less, 105 minutes or less, 100 minutes or less, 95 minutes or less, 90 minutes or less, 85 minutes or less, 80 minutes or less, 75 minutes or less, 70 minutes or less, 65 minutes or less, 60 minutes or less, 55 minutes or less, 50 minutes or less, 45 minutes or less, 40 minutes or less, 35 minutes or less, 30 minutes or less, 25 minutes or less, or 20 minutes or less). The amount of time for which the fourth layered stack, the eighth layered stack, the second intermediate layered stack, the fourth intermediate layered stack, or a combination thereof can independently be etched using HBr/BCl₃ ICP-RIE can range from any of the minimum values described above to any of the maximum values described above. For example, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes (e.g., from 10 to 65 minutes, from 65 to 120 minutes, from 10 to 30 minutes, from 30 to 60 minutes, from 60 to 90 minutes, from 90 to 120 minutes, from 10 to 100 minutes, from 10 to 80 minutes, from 10 to 60 minutes, from 10 to 40 minutes, from 20 to 120 minutes, from 40 to 120 minutes, from 60 to 120 minutes, from 80 to 120 minutes, from 100 to 120 minutes, from 15 to 115 minutes, or from 20 to 110 minutes).

In some examples, etching the fourth layered stack, the eighth layered stack, the second intermediate layered stack, the fourth intermediate layered stack, or a combination thereof can independently comprise using HBr/BCl₃ ICP-RIE at an RF power of 100 W or more (e.g., 125 W or more, 150 W or more, 175 W or more, 200 W or more, 225 W or more, 250 W or more, 275 W or more, 300 W or more, 325 W or more, 350 W or more, 375 W or more, 400 W or more, 425 W or more, or 450 W or more). In some examples, etching the fourth layered stack, the eighth layered stack, the second intermediate layered stack, the fourth intermediate layered stack, or a combination thereof can independently comprise using HBr/BCl₃ ICP-RIE at an RF power of 500 W or less (e.g., 475 W or less, 450 W or less, 425 W or less, 400 W or less, 375 W or less, 350 W or less, 325 W or less, 300 W or less, 275 W or less, 250 W or less, 225 W or less, 200 W or less, 175 W or less, or 150 W or less). The RF power at which the fourth layered stack, the eighth layered stack, the second intermediate layered stack, the fourth intermediate layered stack, or a combination thereof can independently be etched using HBr/BCl₃ ICP-RIE can range from any of the minimum values described above to any of the maximum values described above. For example, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W (e.g., from 100 to 300 W, from 300 to 500 W, from 100 to 200 W, from 200 to 300 W, from 300 to 400 W, from 400 to 500 W, from 100 to 400 W, from 200 to 500 W, or from 200 to 400 W).

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes and at an RF power of from 100 to 500 W.

In some examples, etching the fourth layered stack, the eighth layered stack, the second intermediate layered stack, the fourth intermediate layered stack, or a combination thereof can independently comprise using HBr/BCl₃ ICP-RIE at an ICP power of 100 W or less (e.g., 150 W or more, 200 W or more, 250 W or more, 300 W or more, 350 W or more, 400 W or more, 450 W or more, 500 W or more, 600 W or more, 700 W or more, 800 W or more, 900 W or more, 1000 W or more, 1100 W or more, 1200 W or more, 1300 W or more, 1400 W or more, 1500 W or more, 1600 W or more, 1700 W or more, or 1800 W or more). In some examples, etching the fourth layered stack, the eighth layered stack, the second intermediate layered stack, the fourth intermediate layered stack, or a combination thereof can independently comprise using HBr/BCl₃ ICP-RIE at an ICP power of 2000 W or less (e.g., 1900 W or less, 1800 W or less, 1700 W or less, 1600 W or less, 1500 W or less, 1400 W or less, 1300 W or less, 1200 W or less, 1100 W or less, 1000 W or less, 900 W or less, 800 W or less, 700 W or less, 600 W or less, 500 W or less, 450 W or less, 400 W or less, 350 W or less, 300 W or less, 250 W or less, or 200 W or less). The ICP power at which the fourth layered stack is etch using HBr/BCl₃ ICP-RIE can range from any of the minimum values described above to any of the maximum values described above. For example, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W (e.g., from 100 to 1000 W, from 1000 to 2000 W, from 100 to 500 W, from 500 to 1000 W, from 1000 to 1500 W, from 1500 to 2000 W, from 100 to 1750 W, from 100 to 1500 W, from 100 to 1250 W, from 100 to 750 W, from 100 to 250 W, from 250 to 200 W, from 500 to 2000 W, from 750 to 2000 W, from 1250 to 2000 W, from 1750 to 2000 W, from 150 to 1750 W, or from 200 to 1500 W).

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes and at an ICP power of from 100 to 2000 W. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W and at an ICP power of from 100 to 2000 W. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an RF power of from 100 to 500 W, and at an ICP power of from 100 to 2000 W.

In some examples, etching the fourth layered stack, the eighth layered stack, the second intermediate layered stack, the fourth intermediate layered stack, or a combination thereof can independently comprise using HBr/BCl₃ ICP-RIE at a pressure of 1 μmTorr or more (e.g., 2 mTorr or more, 3 μmTorr or more, 4 μmTorr or more, 5 μmTorr or more, 10 μmTorr or more, 15 mTorr or more, 20 μmTorr or more, or 25 μmTorr or more). In some examples, etching the fourth layered stack, the eighth layered stack, the second intermediate layered stack, the fourth intermediate layered stack, or a combination thereof can independently comprise using HBr/BCl₃ ICP-RIE at a pressure of 30 μmTorr or less (e.g., 25 μmTorr or less, 20 μmTorr or less, 15 mTorr or less, 10 μmTorr or less, or 5 μmTorr or less). The pressure at which the fourth layered stack, the eighth layered stack, the second intermediate layered stack, the fourth intermediate layered stack, or a combination thereof can independently be etched using HBr/BCl₃ ICP-RIE can range from any of the minimum values described above to any of the maximum values described above. For example, etching the fourth layered stack, the eighth layered stack, the second intermediate layered stack, the fourth intermediate layered stack, or a combination thereof can independently comprise using HBr/BCl₃ ICP-RIE at a pressure of from 1 to 30 mTorr (e.g., from 1 to 15 μmTorr, from 15 to 30 μmTorr, from 1 to 10 μmTorr, from 10 to 20 mTorr, from 20 to 30 μmTorr, from 5 to 30 μmTorr, from 10 to 30 μmTorr, from 1 to 25 μmTorr, from 1 to 20 μmTorr, or from 5 to 25 μmTorr).

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes and at a pressure of from 1 to 30 μmTorr. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W and at a pressure of from 1 to 30 mTorr. In some examples, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W and at a pressure of from 1 to 30 μmTorr.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an RF power of from 100 to 500 W, and at a pressure of from 1 to 30 μmTorr. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an ICP power of from 100 to 2000 W, and at a pressure of from 1 to 30 μmTorr. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, at an ICP power of from 100 to 2000 W, and at a pressure of from 1 to 30 μmTorr.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an RF power of from 100 to 500 W, at an ICP power of from 100 to 2000 W, and at a pressure of from 1 to 30 μmTorr.

In some examples, etching the fourth layered stack, the eighth layered stack, the second intermediate layered stack, the fourth intermediate layered stack, or a combination thereof can independently comprise using HBr/BCl₃ ICP-RIE at a HBr flow rate of 5 sccm or more (e.g., 10 sccm or more, 15 sccm or more, 20 sccm or more, 25 sccm or more, 30 sccm or more, 35 sccm or more, 40 sccm or more, or 45 sccm or more). In some examples, etching the fourth layered stack, the eighth layered stack, the second intermediate layered stack, the fourth intermediate layered stack, or a combination thereof can independently comprise using HBr/BCl₃ ICP-RIE at a HBr flow rate of 50 sccm or less (e.g., 45 sccm or less, 40 sccm or less, 35 sccm or less, 30 sccm or less, 25 sccm or less, 20 sccm or less, 15 sccm or less, or 10 sccm or less). The HBr flow rate at which the fourth layered stack, the eighth layered stack, the second intermediate layered stack, the fourth intermediate layered stack, or a combination thereof can independently be etched using HBr/BCl₃ ICP-RIE can range from any of the minimum values described above to any of the maximum values described above. For example, etching the fourth layered stack, the eighth layered stack, the second intermediate layered stack, the fourth intermediate layered stack, or a combination thereof can independently comprise using HBr/BCl₃ ICP-RIE at a HBr flow rate of from 5 to 50 sccm (e.g., from 5 to 25 sccm, from 25 to 50 sccm, from 5 to 10 sccm, from 10 to 20 sccm, from 20 to 30 sccm, from 30 to 40 sccm, from 40 to 50 sccm, from 5 to 40 sccm, from 5 to 30 sccm, from 5 to 20 sccm, from 10 to 50 sccm, from 20 to 50 sccm, from 30 to 50 sccm, from 5 to 45 sccm, from 10 to 40 sccm, or from 15 to 35 sccm).

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at a pressure of from 1 to 30 μmTorr and a HBr flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an RF power of from 100 to 500 W, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an ICP power of from 100 to 2000 W, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at a pressure of from 1 to 30 μmTorr, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, an ICP power of from 100 to 2000 W, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, a pressure of from 1 to 30 μmTorr, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W, a pressure of from 1 to 30 μmTorr, and a HBr flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an RF power of from 100 to 500 W, an ICP power of from 100 to 2000 W, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, at an RF power of from 100 to 500 W, a pressure of from 1 to 30 μmTorr, and a HBr flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, an ICP power of from 100 to 2000 W, at a pressure of from 1 to 30 μmTorr, and a HBr flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, at an ICP power of from 100 to 2000 W, at a pressure of from 1 to 30 μmTorr, and a HBr flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE at a BCl₃ flow rate of 5 sccm or more (e.g., 10 sccm or more, 15 sccm or more, 20 sccm or more, 25 sccm or more, 30 sccm or more, 35 sccm or more, 40 sccm or more, or 45 sccm or more). In some examples, etching the fourth layered stack, the eighth layered stack, the second intermediate layered stack, the fourth intermediate layered stack, or a combination thereof can independently comprise using HBr/BCl₃ ICP-RIE at a BCl₃ flow rate of 50 sccm or less (e.g., 45 sccm or less, 40 sccm or less, 35 sccm or less, 30 sccm or less, 25 sccm or less, 20 sccm or less, 15 sccm or less, or 10 sccm or less). The BCl₃ flow rate at which the fourth layered stack, the eighth layered stack, the second intermediate layered stack, the fourth intermediate layered stack, or a combination thereof can independently be etched using HBr/BCl₃ ICP-RIE can range from any of the minimum values described above to any of the maximum values described above. For example, etching the fourth layered stack, the eighth layered stack, the second intermediate layered stack, the fourth intermediate layered stack, or a combination thereof can independently comprise using HBr/BCl₃ ICP-RIE at a BCl₃ flow rate of from 5 to 50 sccm (e.g., from 5 to 25 sccm, from 25 to 50 sccm, from 5 to 10 sccm, from 10 to 20 sccm, from 20 to 30 sccm, from 30 to 40 sccm, from 40 to 50 sccm, from 5 to 40 sccm, from 5 to 30 sccm, from 5 to 20 sccm, from 10 to 50 sccm, from 20 to 50 sccm, from 30 to 50 sccm, from 5 to 45 sccm, from 10 to 40 sccm, or from 15 to 35 sccm).

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at a pressure of from 1 to 30 μmTorr and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at a HBr flow rate of from 5 to 50 sccm and a BCl₃ flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an ICP power of from 100 to 2000 W, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, a pressure of from 1 to 30 μmTorr, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, a HBr flow rate of from 5 to 50 sccm, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, an ICP power of from 100 to 2000 W, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, a pressure of from 1 to 30 μmTorr, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, a HBr flow rate of from 5 to 50 sccm, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W, a pressure of from 1 to 30 μmTorr, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an ICP power of from 100 to 2000 W, a HBr flow rate of from 5 to 50 sccm, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at a pressure of from 1 to 30 μmTorr, a HBr flow rate of from 5 to 50 sccm, and a BCl₃ flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, an ICP power of from 100 to 2000 W, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, a pressure of from 1 to 30 μmTorr, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, a HBr flow rate of from 5 to 50 sccm, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an ICP power of from 100 to 2000 W, a pressure from 1 to 30 μmTorr, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an ICP power of from 100 to 2000 W, a HBr flow rate of from 5 to 50 sccm, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, a pressure of from 1 to 30 μmTorr, and a HBr flow rate of from 5 to 50 sccm, and a BCl₃ flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, at an ICP power of from 100 to 2000 W, a pressure of from 1 to 30 μmTorr, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, at an ICP power of from 100 to 2000 W, a HBr flow rate of from 5 to 50 sccm, and a BCl₃ flow rate of from 5 to 50 sccm. In some examples, etching the fourth layered stack, the eighth layered stack, the second intermediate layered stack, the fourth intermediate layered stack, or a combination thereof can independently comprise using HBr/BCl₃ ICP-RIE at an RF power of from 100 to 500 W, an ICP power of from 100 to 2000 W, a pressure of from 1 to 30 μmTorr, a HBr flow rate of from 5 to 50 sccm, and a BCl₃ flow rate of from 5 to 50 sccm.

In some examples, etching the fourth layered stack, the eighth layered stack, the second intermediate layered stack, the fourth intermediate layered stack, or a combination thereof can independently comprise using HBr/BCl₃ ICP-RIE for an amount of time of from 10 minutes to 120 minutes, an RF power of from 100 to 500 W, an ICP power of from 100 to 2000 W, a pressure of from 1 to 30 μmTorr, a HBr flow rate of from 5 to 50 sccm, and

In some examples, etching the fourth layered stack, the eighth layered stack, the second intermediate layered stack, the fourth intermediate layered stack, or a combination thereof can independently comprise using HBr/BCl₃ ICP-RIE: for an amount of time of from 10 minutes to 120 minutes; at an RF power of from 100 to 500 W; at an ICP power of from 100 to 2000 W; at a pressure of from 1 to 30 μmTorr; at a HBr flow rate of from 5 to 50 sccm; at a BCl₃ flow rate of from 5 to 50 sccm; or a combination thereof. In some examples, etching the fourth layered stack, the eighth layered stack, the second intermediate layered stack, the fourth intermediate layered stack, or a combination thereof can independently comprise using HBr/BCl₃ ICP-RIE: for an amount of time of from 10 minutes to 120 minutes; at an RF power of from 100 to 500 W; at an ICP power of from 100 to 2000 W; at a pressure of from 1 to 30 μmTorr; at a HBr flow rate of from 5 to 50 sccm; and at a BCl₃ flow rate of from 5 to 50 sccm.

In some examples, the methods further comprise making the first layered stack. For example, making the first layered stack can comprise: depositing the polysilicon layer on the surface of the substrate; depositing the antireflection layer on the polysilicon layer; and depositing the photoresist layer on the antireflection layer.

In some examples, the methods further comprise making the first precursor layered stack. For example, making the first precursor layered stack can comprise: depositing the polysilicon layer on the surface of the substrate; and depositing the photoresist layer on the polysilicon layer.

In some examples, the methods further comprise making the fifth layered stack. For example, making the fifth layered stack can comprise: depositing the polysilicon layer on the second surface of the substrate; depositing the antireflection layer on the polysilicon layer; and depositing the photoresist layer on the antireflection layer. In some examples, the method further comprises protecting the patterned first surface of the substrate before making the fifth layered stack, for example by depositing a protective layer on the patterned first surface of the substrate. In some examples, the methods can further comprise removing the protective layer from the patterned first surface after the second surface is patterned.

In some examples, the methods further comprise making the second precursor layered stack. For example, making the second precursor layered stack can comprise: depositing the polysilicon layer on the second surface of the substrate; and depositing the photoresist layer on the polysilicon layer. In some examples, the method further comprises protecting the patterned first surface of the substrate before making the second precursor layered stack, for example by depositing a protective layer on the patterned first surface of the substrate. In some examples, the methods can further comprise removing the protective layer from the patterned first surface after the second surface is patterned.

The polysilicon layer can be deposited using any suitable method. In some examples, the polysilicon layer can be deposited using electron beam deposition, thermal deposition, chemical vapor deposition (CVD), atomic layer deposition (ALD), physical vapor deposition (PVD), sputtering, pulsed layer deposition, evaporation, or combinations thereof. In some examples, the polysilicon layer can be deposited using chemical vapor deposition (CVD), such as low-pressure chemical vapor deposition (LPCVD).

The antireflection layer can be deposited using any suitable method. In some examples, the antireflection layer can be deposited using spin coating, drop-casting, zone casting, dip coating, blade coating, spraying, vacuum filtration, or combinations thereof. In some examples, the antireflection layer is deposited using spin-coating.

The photoresist layer can be deposited using any suitable method. In some examples, the photoresist layer can be deposited using spin coating, drop-casting, zone casting, dip coating, blade coating, spraying, vacuum filtration, or combinations thereof. In some examples, the photoresist layer is deposited using spin-coating.

The protective layer can comprise any suitable material. In some examples, the protective layer can comprise a polymer.

The protective layer can be deposited using any suitable method. In some examples, the protective layer can be deposited using spin coating, drop-casting, zone casting, dip coating, blade coating, spraying, vacuum filtration, or combinations thereof. In some examples, the photoresist layer is deposited using spin-coating.

### Methods of Use

Also disclosed herein are methods of use of any of the patterned materials disclosed herein. For example, the methods can comprise using the patterned material in an optical device, a photonic device, an electronic device, or an optoelectronic device. In some examples, the method comprises using the patterned material in a nanophotonic device, as a metasurface, or a combination thereof. In some examples, the method comprises using the patterned material in a defense application, an extraterrestrial application, an aerospace application, or a combination thereof. In some examples, the method comprises using the patterned material in a missile dome.

### Devices

Also disclosed herein are devices and/or articles of manufacture comprising any of the patterned materials disclosed herein. For example, the article and/or device can comprise an optical device, a photonic device, an electronic device, or an optoelectronic device. In some examples, the article and/or device comprises a display, a portable electronic device, a window, a lens, a lighting device, or a combination thereof. In some examples, the article and/or device comprises a nanophotonic device, as a metasurface, or a combination thereof. In some examples, the article and/or device is for a defense application, an extraterrestrial application, an aerospace application, or a combination thereof. In some examples, the article and/or device comprises a missile dome.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the systems and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in °C or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Antireflection Sapphire Nanostructures Fabricated by Low RF Power ICP-RIE

Introduction. Bio-inspired nanostructures have drawn significant interest and attention because of their attractive electrical, optical, and mechanical properties. One of those bio-inspired nanostructures is the antireflection (AR) nanostructures that can be applied on planar surfaces to reduce the reflectance and enhance the transmittance, which can be found on the surface of moth eyes (P Vukusic et al. Nature, 2003, 424, 852). These taper structures gradually match refractive indices of two media across the interface to mitigate Fresnel reflection losses over broad wavelength bands and wide incident angles. As a result, those antireflection nanostructures have better optical performance than traditional antireflection coatings (D Poitras et al. Appl. Opt., 2004, 43, 1286; WH Southwell, J. Opt. Soc. Am. A, 1991, 8, 549).

Single crystal sapphire has many applications in photonics and optoelectronics due to its high mechanical hardness, thermal tolerance, chemical stability, and high optical transmittance in the infrared range. However, the large refractive index mismatch between air and sapphire results in high optical reflection losses. This issue can be mitigated by applying antireflection nanostructures, especially those with a high aspect ratio (HAR), on the sapphire surface. However, the fabrication of high aspect ratio sapphire structures is challenging due to the high chemical stability of single crystal sapphire.

Previous work demonstrated that sapphire nanostructures with a height of 350 nm could be achieved by using a multilayer etching mask (YA Chen et al. Micro and Nano Engineering, 2022, 14, 100115). However, its fabrication process includes multiple steps, such as depositions and etching for different materials, including SiO₂, polysilicon, and nitride, which is comparatively complex.

Presented herein is a simple technique to fabricate high aspect ratio sapphire antireflection nanostructures to enhance the transmittance of sapphire substrates. This approach utilizes inductively coupled plasma reactive ion etching (ICP-RIE) with low RF power (KC Chien et al. Journal of Vacuum Science & Technology B, 2022, 40, 062802) to form high aspect ratio polysilicon pillars as an etch mask.

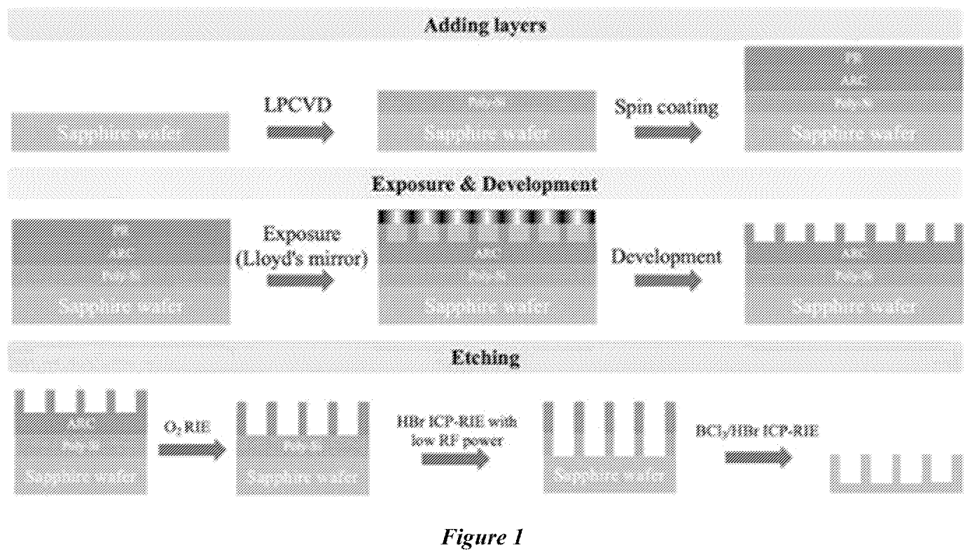

Experimental Approach. The proposed fabrication processes are illustrated in FIG. 1. First, a thick polysilicon layer is deposited on the sapphire substrate using low pressure chemical vapor deposition (LPCVD). A 200 nm photoresist (PR) PFI-88 and a 100 nm antireflection coating (ARC) ARC i-CON are spin-coated on the silicon substrate. The antireflection coating is designed to minimize the back reflection, which can lead to standing wave and photoresist waviness. Then the photoresist is exposed using Lloyd's mirror interference lithography (HI Smith, Physica E: Low-Dimensional Systems and Nanostructures, 2001, 11, 104; A Bagal et al. Optics Letters, 2013, 38, 2531) with a 325 nm HeCd laser. A pattern of 1D gratings is obtained by a single exposure, and a pattern of 2D periodic pillar arrays is obtained by two orthogonal exposures. After forming 2D pillar arrays with a 300 nm period in photoresist, the ICP-RIE etcher Oxford 100 is used in this study. Oxygen gas is used (130 second etch time, RF power 60 W, pressure 13 μmTorr, flow rate 25 sccm) to transfer the photoresist pattern into the antireflection coating, and HBr gas with a low RF power to enhance the etch selectivity (80 minute etch time, RF power 20 W, ICP power 200 W, pressure 8 μmTorr, flow rate 20 sccm) is used to further etch into the polysilicon layer to form high aspect ratio polysilicon pillars as an etch mask of the sapphire etching process. Finally, the BCl₃/HBr ICP-RIE (18 minute etch time, RF power 400 W, ICP power 1500 W, pressure 8 μmTorr, flow rate 15 sccm for each gas) further etches the pattern into the sapphire substrate.

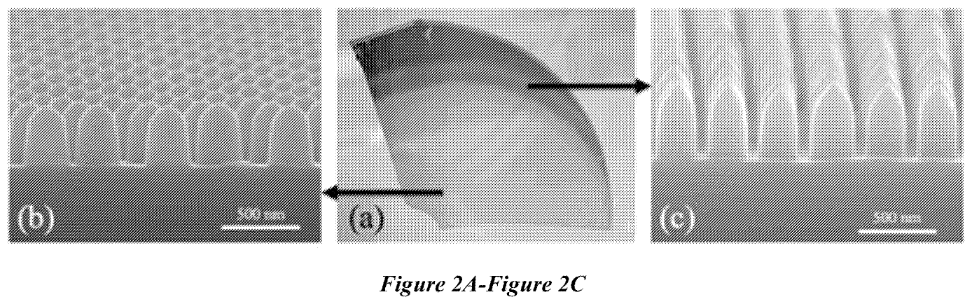

Results and Discussion. After using BCl₃/HBr ICP-RIE to etch the sapphire substrate for 18 min, the sapphire sample is shown in FIG. 2A. It can be observed that most parts of high aspect ratio polysilicon pillars, which exhibit a deep-colored appearance, are removed. The sapphire nanostructures of that area (e.g., where most of the polysilicon pillars are removed) follow a tapered profile with a width of 242 nm and a height of 385 nm, resulting in an aspect ratio of 1.59, as seen in the cross-section SEM image shown in FIG. 2B. However, some parts of high aspect ratio polysilicon pillars around the edge of the sample are not completely removed after etching for 18 min due to the non-uniform thickness of the polysilicon layer. After an additional 5 min etch time, the resulting tapered sapphire nanostructures are shown in FIG. 2C with a height of 500 nm, which lead to a higher aspect ratio of 2.07.

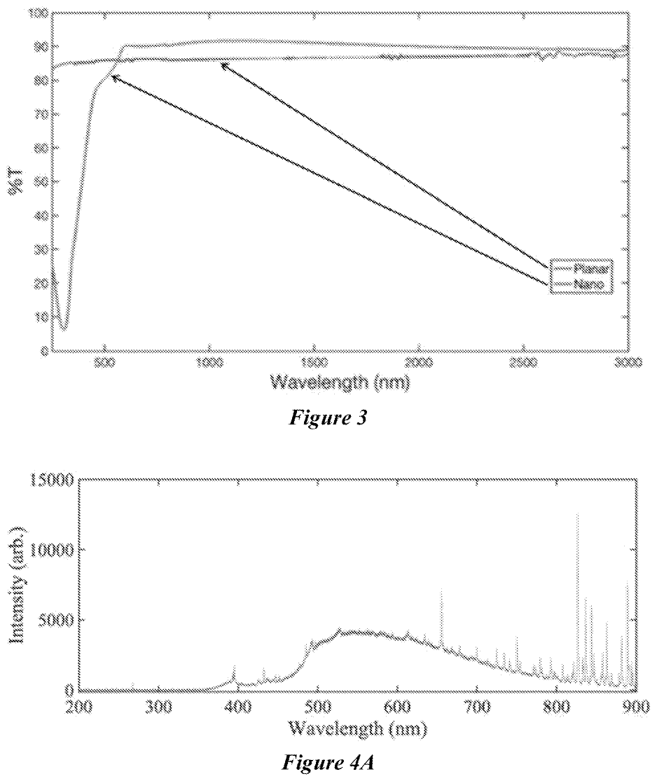

To examine the antireflection effects caused by tapered nanostructures on the sapphire substrate, the broadband transmittance from 250 nm to 3000 nm was characterized via UV-Vis-NIR spectrophotometer (Cary 5000, Agilent) (FIG. 3). It can be observed that the transmission has been enhanced to over 90% for wavelengths longer than 600 nm to NIR range. The best improvement is at 1184 nm, where the transmission increases from 86.2% to 91.6%. The transmittance of the sample for wavelength shorter than 560 nm decreases due to the diffraction effect, where diffracted orders are trapped in the substrate waveguide mode. As a result, this approach demonstrates a simple fabrication process to obtain high aspect ratio sapphire antireflection nanostructures.

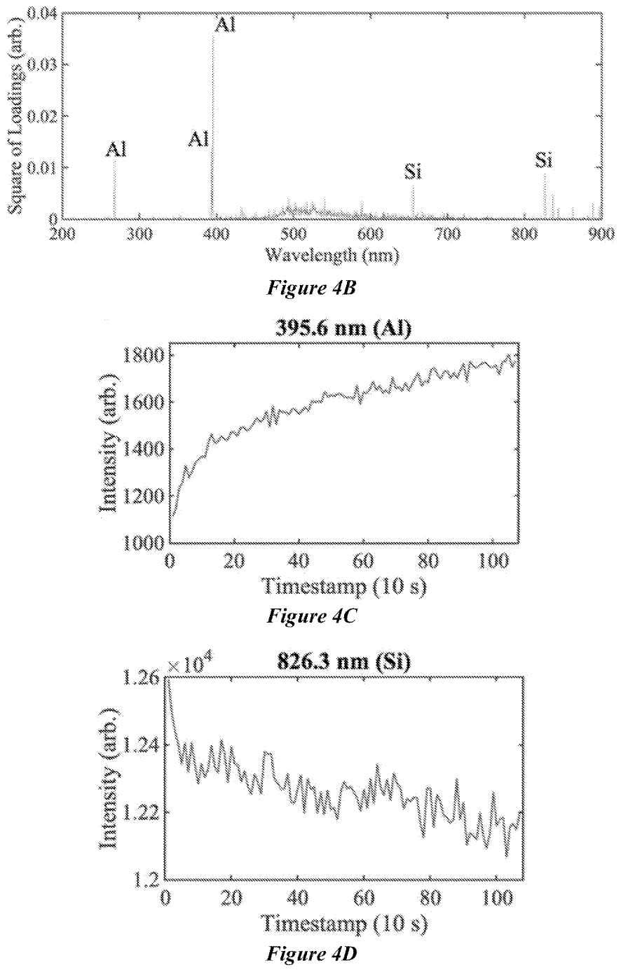

To investigate the sapphire etching mechanism, optical emission spectroscopy (OES) data is collected for each timestamp during the BCl₃/HBr ICP-RIE process shown in FIG. 4A. In FIG. 4A, multiple peaks or strong emissions across spectra can be observed, but which emissions contain important process information cannot be identified directly. Therefore, a key wavelength analysis via principal component analysis (PCA) is used to identify which emissions are critical to the etching process. Principal component analysis (JE Jackson, A User's Guide to Principal Components (John Wiley & Sons, Hoboken, NJ, 2005)) is a dimensionality reduction method that uses loadings or eigenvectors to project data points onto the first few principal components while preserving as much variation from the original dataset as possible. Since each wavelength has its own loading to project the original data to principal components, the loading infers the contribution or importance of each wavelength for principal components. Using principal component analysis to select key wavelengths in the optical emission spectroscopy data has been well demonstrated in previous studies (HH Yue et al. J. Vac. Sci. Technol. A, 2001, 19, 66; KC Chien et al. J. Vac. Sci. Technol. B, 2021, 39, 064003). FIG. 4B shows the result of the key wavelength analysis via principal component analysis. Here wavelengths having the top five squared loadings are selected, which are 267.7, 393.7, 395.6, 655.4, and 826.3 nm. These wavelength can be examined via the atomic spectra database provided by NIST to identify that 267.7, 393.7, and 395.6 nm represent emissions of Al, and 655.4 and 826.3 nm represent emissions of Si. The optical emission spectroscopy signals at 395.6 and 826.3 nm are plotted in FIG. 4C and FIG. 4D. It can be observed that the emission of Al becomes stronger over time as more sapphire is exposed during etching, and the emission of Si becomes weaker over time when less polysilicon etch mask remains on the sample. Another interesting thing that can be observed in optical emission spectroscopy data shown in FIG. 4A is that emissions of Si are much stronger than emissions of Al since an eight-inch Si wafer is used as the sample carrier in the etcher. However, via principal component analysis, less significant emissions but having important process information, such as Al emissions, can be identified, which is valuable for the process development.

Summary. The proposed approach demonstrates a simple fabrication process to obtain high aspect ratio tapered sapphire nanostructures using ICP-RIE. This technique is enabled by reducing the RF power during HBr ICP-RIE of polysilicon to enhance the etch selectivity, which results in high aspect ratio polysilicon pillars as an etch mask. The highest aspect ratio of current sapphire nanostructures is 2.07, with a width of 242 nm and a height of 500 nm. The broadband transmittance measurements show that tapered sapphire nanostructures enhance antireflection effects for wavelengths longer than 600 nm. The best improvement is at 1184 nm, where the transmission increases by 6.3%. The key wavelength analysis via principal component analysis for optical emission spectroscopy shows the ability to identify key emissions of Si and Al in the etch process, which benefits the etching process development. Antireflection effects can be enhanced by making tapered sapphire nanostructures with a finer period, increasing the aspect ratio by using a thicker polysilicon mask, and making tapered sapphire nanostructures on both sides. Tapered sapphire nanostructures with a smaller period can reduce the diffraction effect in shorter wavelengths. Higher aspect ratio sapphire nanostructures can enhance the transmittance in longer wavelengths. Fabricating nanostructures on both sides of the sapphire wafer can mitigate Fresnel reflection on both interfaces, which leads to better transmittance.

### Example 2—Fabrication of Antireflection Sapphire Nanostructures

Nanostructures in biology include moth eyes and the transparent wings of certain hawkmoths, which have tapered structures (Vukusic et al. Nature, 2003, 424, 852-855). Tapered structures gradually match refractive indices of two mediums across the interface. The reduced reflectivity enhances the photocollection efficiency. Transmission is also increased.

Sapphire has many applications in photonics and optoelectronics due to its high mechanical hardness, thermal tolerance, chemical stability, and high optical transmittance. For example, sapphire can be used in solid state lasers, as a window material, in watch faces, and camera lenses.

Because the refractive index of sapphire is much higher than other transparent materials, the large refractive index mismatch leads to high optical reflection.

Sapphire etching studies have been performed, for example where inductively coupled plasma reactive ion etching (ICP-RIE) was applied (Jeong et al. Surface and Coatings Technology, 2003, 171, 280-284; Bradley et al. Appl Phys B, 2007, 89, 311; Leem et al. Opt Express 2012, 20, 26160, Chen et al. Nanotechnology, 2015, 26, 085302). However, these studies either have large features at micrometer scale or focus on amorphous Al₂O₃ films. Generally, these structures have a low aspect ratio, random order, and/or mask removal issues.

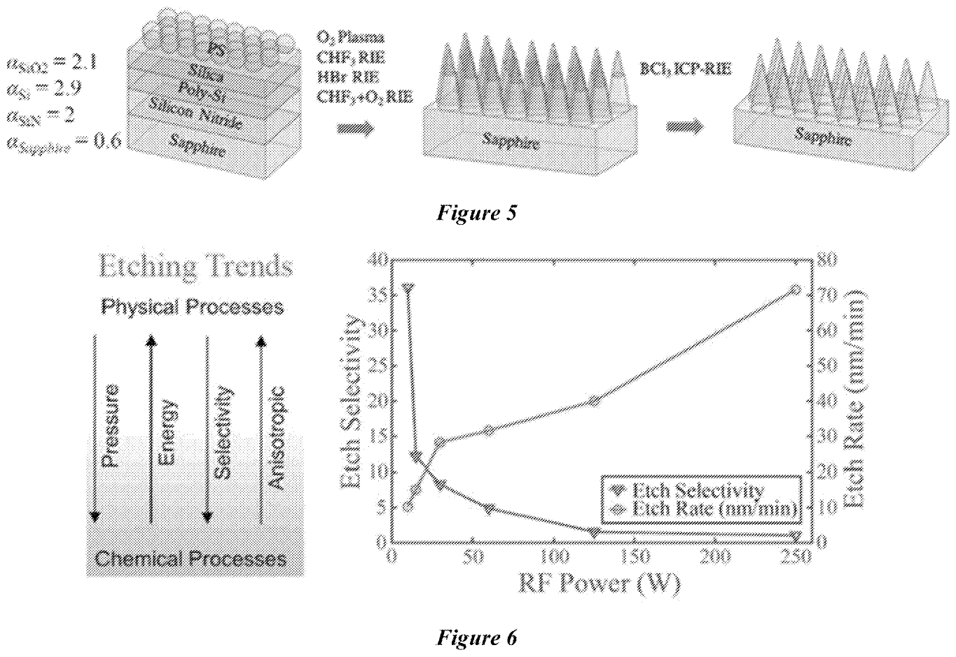

Previously, a multilayer etching mask fabrication process was described (Chen et al. Micro and nanoengineering, 2022, 14, 100115). A schematic diagram of the multilayer stack is shown in FIG. 5. The different layers of the stack were chosen in view of their etch selectivity; the etch selectivity of the layers are different relative to one another. Initially, a 430 nm thick layer of silicon nitride and a 350 nm thick layer of polysilicon were deposited on a sapphire substrate using low-pressure chemical vapor deposition (LPCVD). Then, a 100 nm thick layer of SiO₂ was deposited using electron beam evaporation. Polystyrene (PS) nanospheres with a 200 nm diameter were then assembled on the stack. The polystyrene nanospheres were then etched in oxygen plasma etching (PE) to reduce the diameters to 50 nm (pressure 700 μmTorr, RF power 300 W, and ICP power 100 W). As noted previously, the neighboring layers of the multilayer masks were selected to enhance the overall etch selectivity versus sapphire. The polystyrene pattern was used as a mask to etch into SiO₂ with etching selectivity α_{SiO2}=2.1 using CHF₃ RIE (6 min etch time, RF power 150 W, pressure 20 μmTorr, flow rate 20 sccm). The SiO₂ structure is an effective mask to etch poly-Si with etching selectivity α_{Si}=2.9 using HBr RIE (3.5 min etch time, RF power 250 W, ICP power 200 W, pressure 8 μmTorr, flow rate 30 sccm). The poly-Si structures then serve as an effective mask to etch the underlying nitride, which has an etching selectivity α_{SiN}=2.0 using CHF₃ μmixed with O₂ (24 min etch time, RF power 250 W, pressure 15 μmTorr, CHF₃ flow rate 25 sccm, O₂ flow rate 5 sccm). The final remaining multilayer etching mask includes poly-Si and nitride has a thickness of 500 nm, which can serve as a thick mask for pattern transfer into the underlying sapphire substrate. The etching selectivity of sapphire vs nitride using BCl₃ ICP-RIE (9 min 43 s etch time, RF power 300 W, ICP power 1500 W, pressure 8 μmTorr, flow rate 30 sccm) is around α_{Sapphire}=0.6. By designing the etch selectivities of the multilayer, the total etch selectivity can be calculated as αₜₒₜₐₗ=α_{SiO2}α_{Si}α_{SiN}αₛₐₚₚₕᵢᵣₑ=7.3, indicating that 50 nm thick polystyrene mask can lead to 365 nm tall sapphire nanostructures. In this mask design, 50 nm thick PS mask with 200 period is able to pattern sapphire nanostructures with around 345 nm height, an improvement by a factor of 6.9. Broadband reflectivity measurements at a 5° incident angle indicate patterning reduced the reflectivity from 9.2% to 0.3% at 350 nm and from 7.6% to 2.6% at 1000 nm. Broadband reflectivity measurements at a 450 incident angle indicate patterning reduced the reflectivity from 9.7% to 0.4% at 350 nm and from 8.2% to 3.1% at 1000 nm.

The multilayer mask method was able to fabricate high aspect ratio sapphire nanostructures. However, this method suffered from a variety of drawbacks, including lack of uniformity, low yield over large areas, mask removal issues, complications due to depositing multiple layers and multiple etch steps, etc. Further, it requires multiple steps for depositions and etching for different materials and defects caused by self-assembly of the nanoparticles as an etching mask increased the scattering which lead to a reduction of transmittance. Described herein is an alternative method which aims to address one or more of these issues.

The methods described herein are for fabricating high aspect ratio sapphire nanostructures using a simple technique to enhance transmittance. The method including using a thick poly-Si mask made by low RF power HBr ICP-RIE. The complicated multilayer mask structure is replaced by a polymer mask and a thick poly-Si layer. Lloyd's mirror is then used to form a 2D pattern instead of using polystyrene nanospheres (FIG. 1).

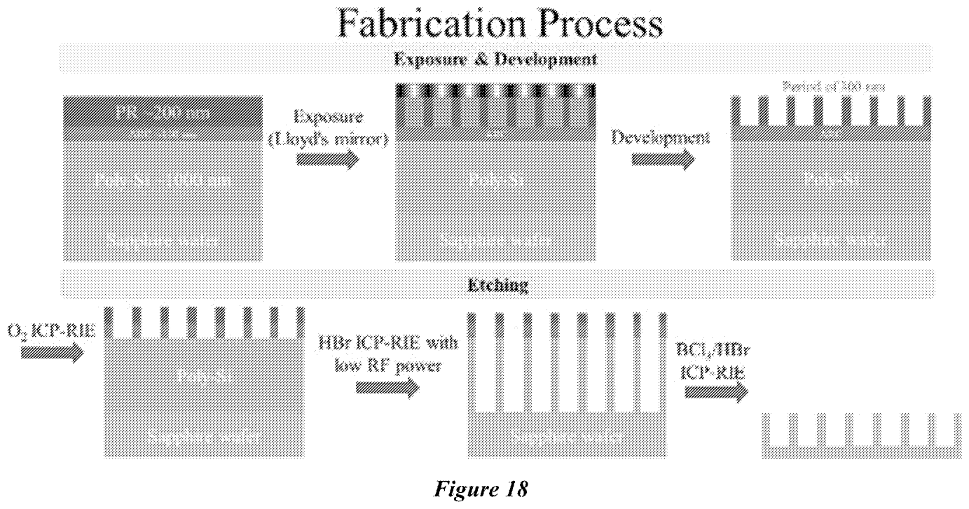

The method is shown schematically in FIG. 1 and FIG. 18. The method creates high aspect ratio polysilicon pillars as an etch mask with a low RF power. A large-area multifunctional sapphire window with enhanced optical and surface properties made using these methods has been demonstrated.

The inductively coupled plasma reaction ion etching (ICP-RIE) separates plasma density and ion energy controls by ICP and RF modules. The methods utilize ICP-RIE with the low RF power setting to enhance the etching selectivity by favoring chemical etching (FIG. 6), as described elsewhere (K.-C. Chien and C.-H. Chang, Journal of Vacuum Science & Technology B 40, 062802, 2022). The etch selectivity is further shown in Table 1.

TABLE 1
Etch selectivity.

| | Si | Sapphire | Etch |
|---|---|---|---|
| Recipe | (nm) | (nm) | selectivity |
| 400 W (HBr/BCl₃: 25/25) | 230 | 118 | 0.51 |
| 300 W (HBr/BCl₃: 25/25) | 312 | 133 | 0.43 |
| 200 W (HBr/BCl₃: 25/25) | 231 | 103 | 0.45 |
| 100 W (HBr/BCl₃: 25/25) | 209 | 89 | 0.43 |
| 400 W (HBr/BCl₃/Ar: 25/25/5) | 455 | 209 | 0.46 |
| 300 W (HBr/BCl₃: 15/15) | 227 | 123 | 0.54 |

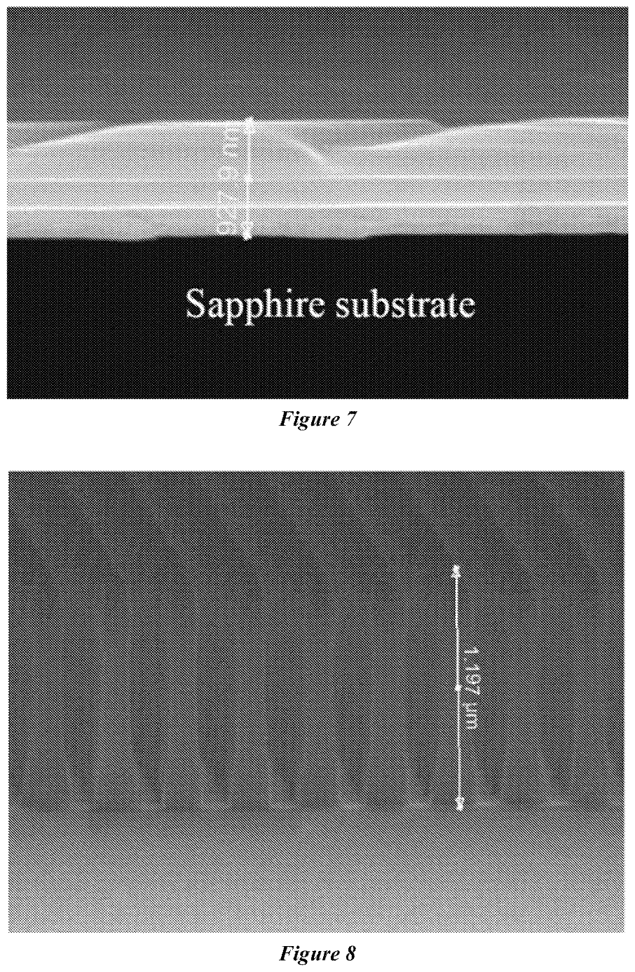

The methods described herein are shown schematically in FIG. 1 and FIG. 18. Four cycles of poly-Si LPCVD deposited a ~930 nm thick layer of poly-Si on the sapphire substrate (FIG. 7). The results of etching for 80 minutes using HBr ICP-RIE with 20 W RF power are shown in FIG. 8.

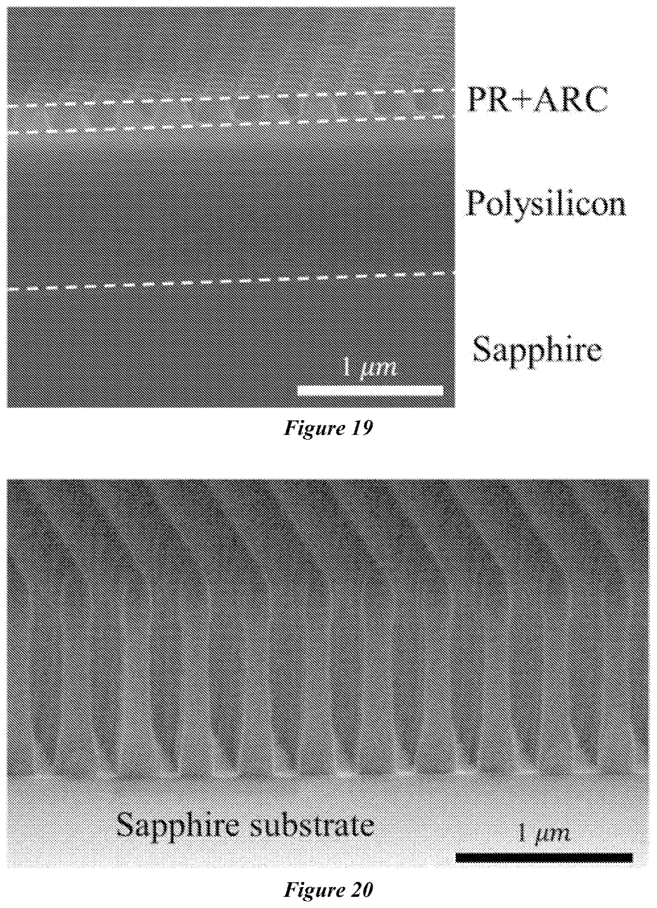

The results of pattern transferring into the antireflection layer by O₂ ICP-RIE is shown in FIG. 19. The high aspect ratio polysilicon pillars as an etching mask made by HBr ICP-RIE with 20 W RF power are shown in FIG. 20. Nano-pillars with an aspect ratio of ~10 can be obtained via HBr ICP-RIE with a low RF power.

Optical emission measurements were performed after sapphire etching. The raw data is shown in FIG. 4A. The data was further investigated using principal component analysis, the results of which are shown in FIG. 4B-FIG. 4D. The results indicate that the emission of Al becomes stronger over time as more sapphire is exposed. The emission of Si becomes weaker over time when less polysilicon etch mask remains. The emissions of Si are much stronger than emissions of Al due to the Si sample carrier. Based on squared loadings of principal component analysis, less significant emissions but having important process information, e.g., Al, can be identified.

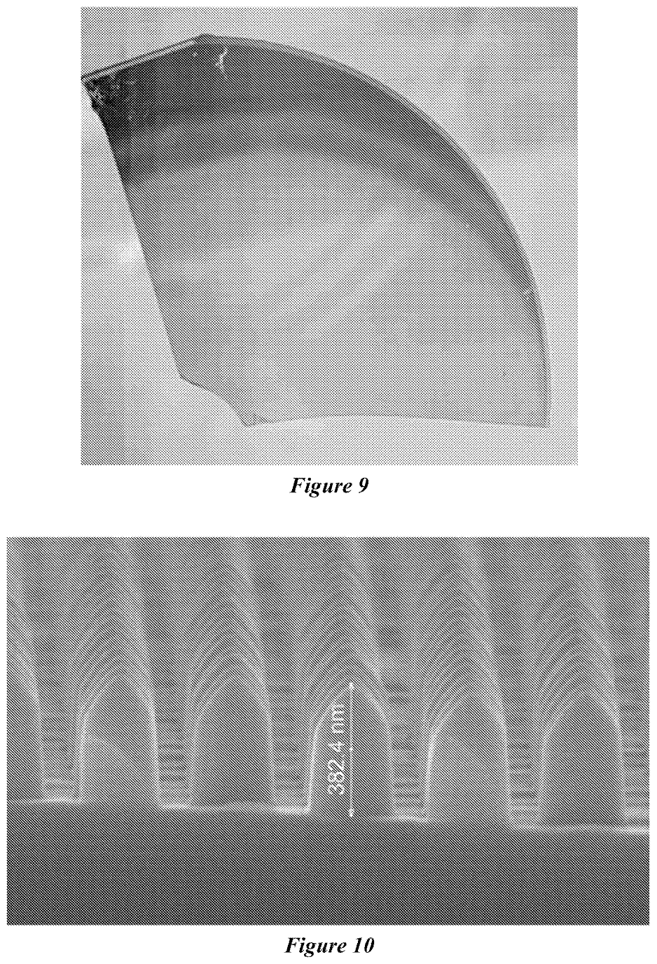

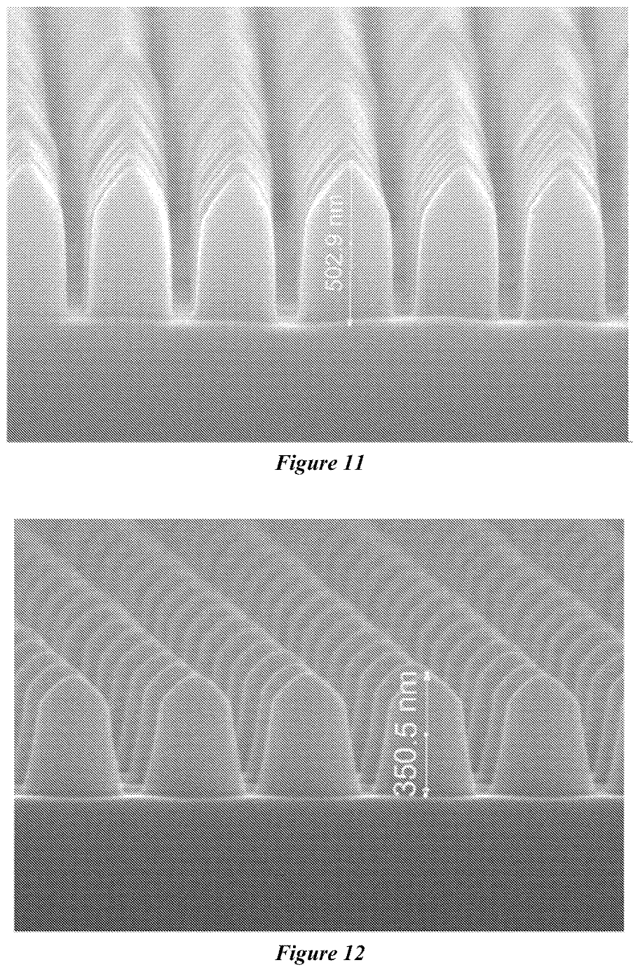

A photograph of an example substrate is shown in FIG. 9. The thickness of the poly-Si mask varied, such that not all of the polysilicon pillars were removed with a given etch time, which contributes to the variation in color in FIG. 9. After using BCl₃/HBr ICP-RIE with 400 W RF power to etch the sapphire substrate for 18 min, it can be observed that most parts of high aspect ratio polysilicon pillars, which exhibit a deep-colored appearance, are removed (FIG. 9). The sapphire nanostructures of that area (e.g., where most of the polysilicon pillars are removed) follow a tapered profile, as seen in the cross-section SEM image shown in FIG. 10. However, some parts of high aspect ratio polysilicon pillars around the edge of the sample are not completely removed after etching for 18 min due to the non-uniform thickness of the polysilicon layer (resulting the in deep colored appearance in FIG. 9). After an additional 5 min etch time (e.g., etching for 23 minutes total using HBr/BCl₃ ICP-RIE with 400 W RF power), the resulting tapered sapphire nanostructures are shown in FIG. 11.

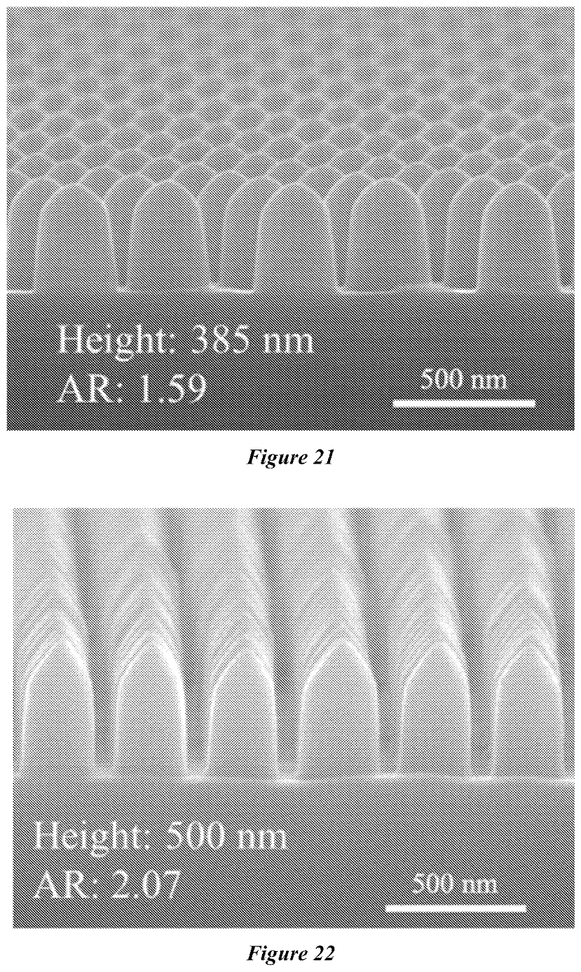

An SEM image of a sample made after etching for 18 minutes using HBr/BCl₃ ICP-RIE with 400 W RF power is shown in FIG. 21; the pillars had an average height of 385 nm and an aspect ratio of 1.59. An SEM of a sample made from a section where the polysilicon mask was thicker after etching for 23 minutes using HBr/BCl₃ ICP-RIE with 400 W RF power is shown in FIG. 22; the pillars had an average height of 500 nm and an aspect ratio of 2.07. Thus, a thicker polysilicon mask can result in taller sapphire nanostructures and/or a greater aspect ratio.

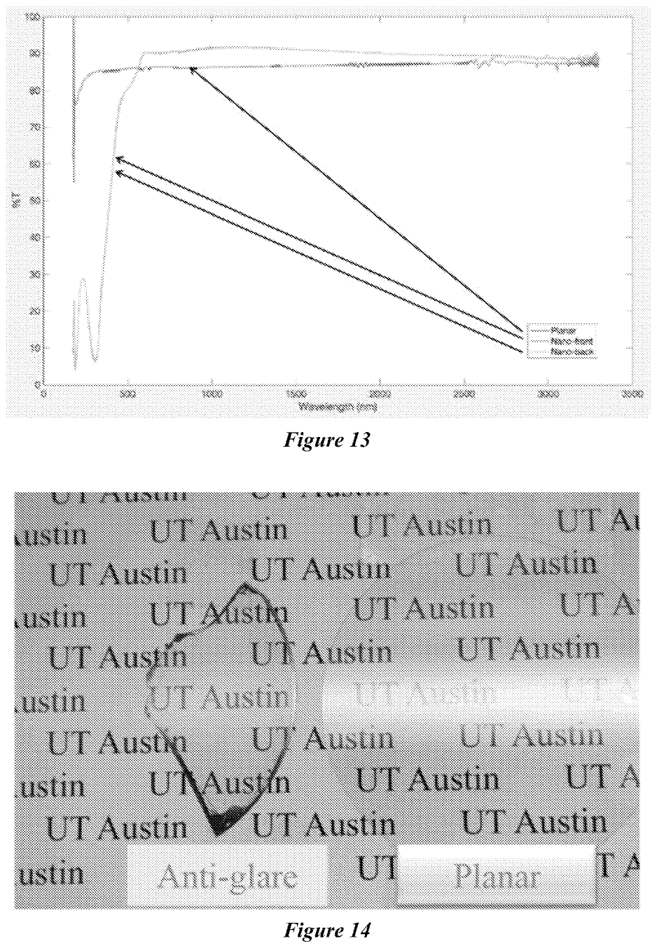

The structures in FIG. 12 were subjected to optical characterization (Cary 5000), the results of which are shown in FIG. 13.

The methods can further be used to make nanostructures on both sides of the sapphire substrate.

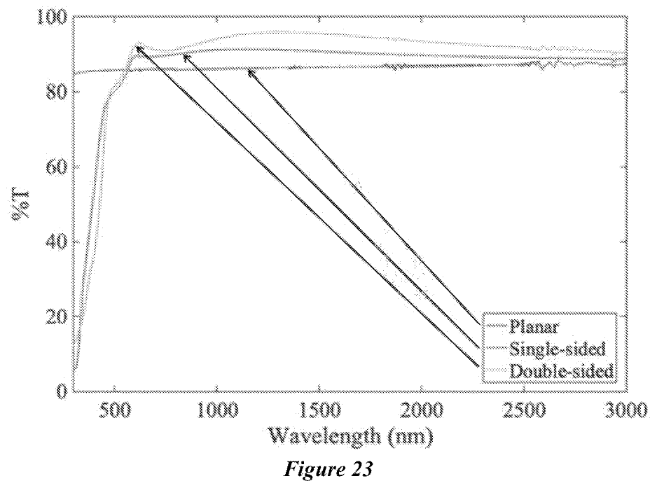

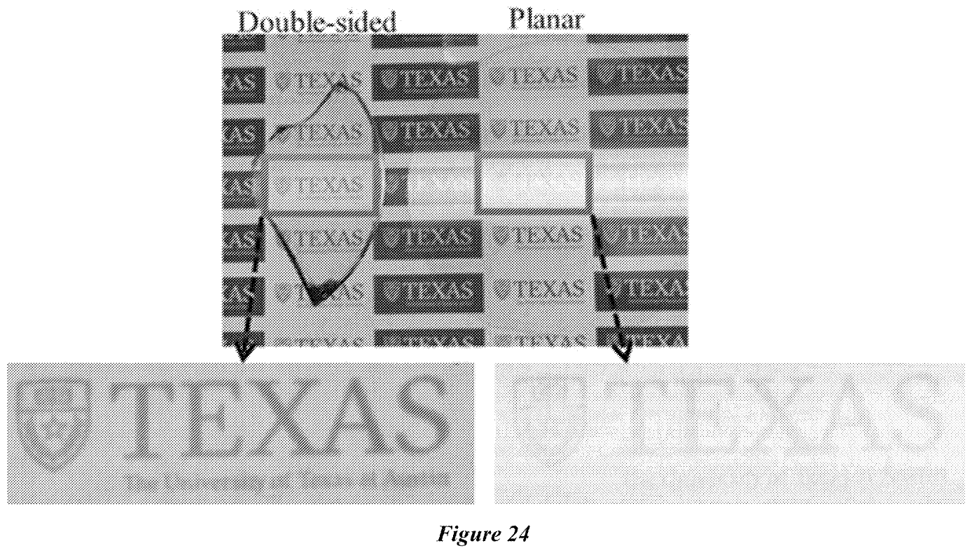

Broadband transmittance measurements were performed on a planar sapphire sample, a single-sided patterned sample (e.g., patterned on one side) made using the methods herein, and a double-sided patterned sample (e.g., patterned on two sides) made using the methods herein. The results are shown in FIG. 23. Single- and double-sided nanostructures enhance transmittance for wavelength longer than 565 nm. At 1360 nm, transmission of double-sided sample increases from 86% to 96%. Transmittance decreases significantly for wavelengths shorter than around 600 nm due to the diffraction effect.

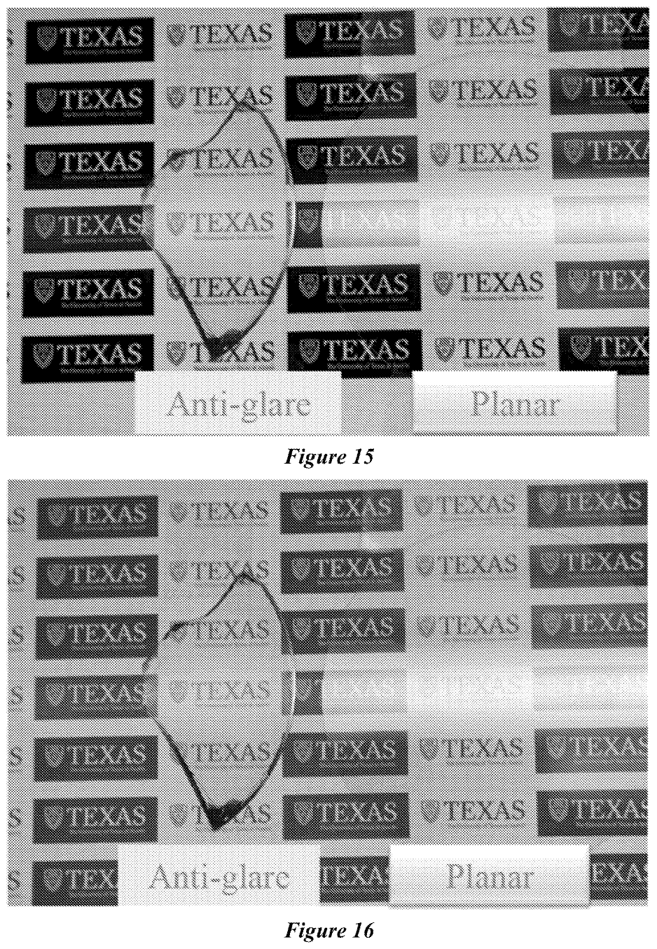

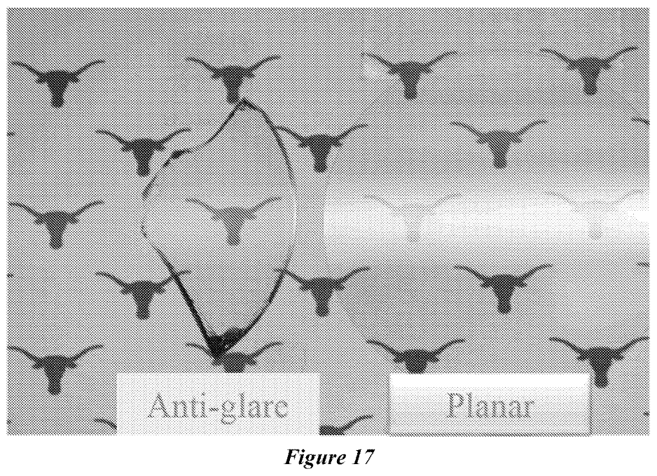

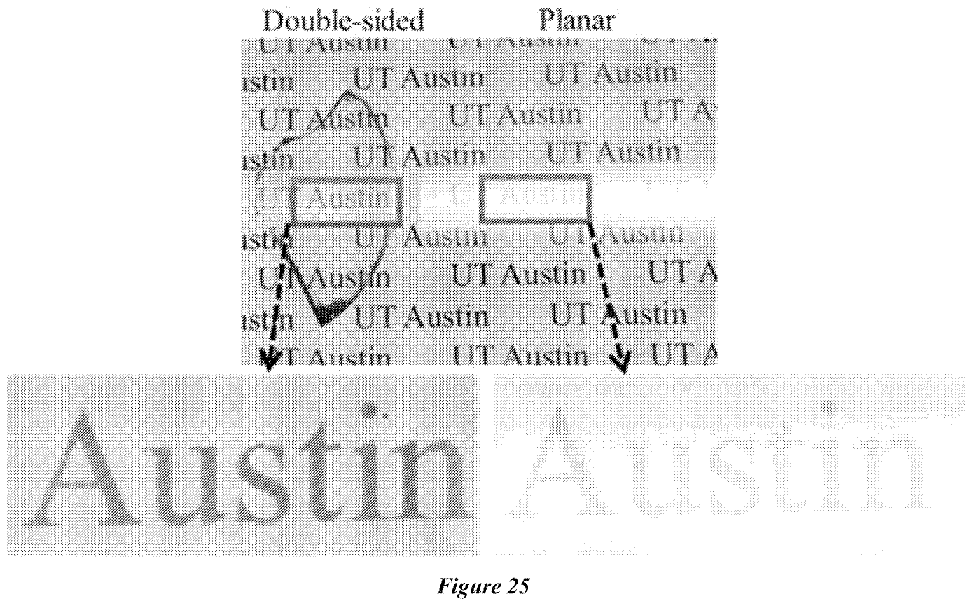

Patterning the sapphire can result in anti-glare properties. Images illustrating the anti-glare properties of patterned sapphire vs. planar sapphire are shown in FIG. 14-FIG. 17. Additional images illustrating the anti-glare/anti-reflection properties of patterned sapphire vs. planar sapphire are shown in FIG. 24 and FIG. 25.

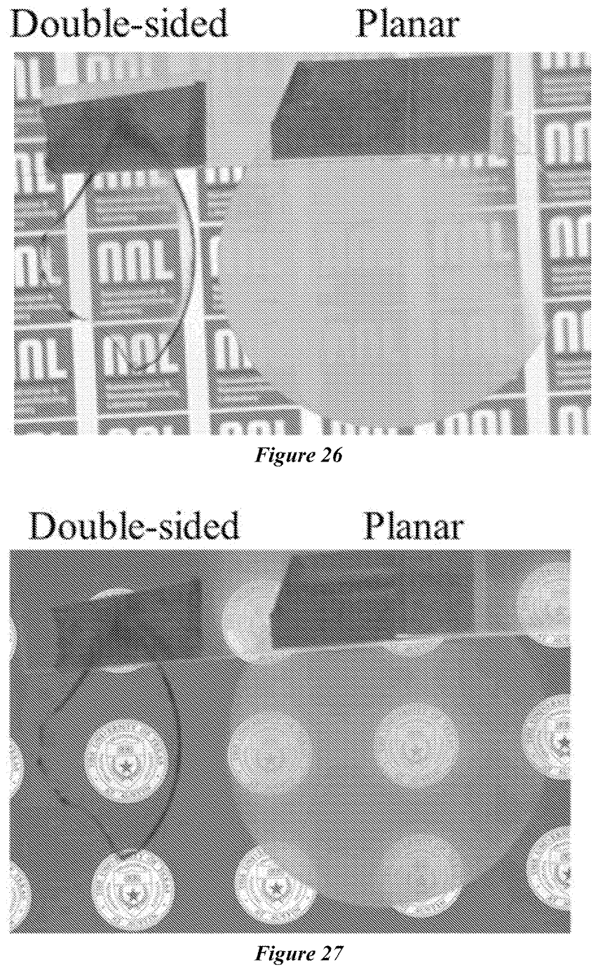

Patterning the sapphire can also result in anti-fogging properties. Images illustrating the anti-fogging properties of patterned sapphire vs. planar sapphire are shown in FIG. 26 and FIG. 27. The anti-fogging properties were tested by placing a beaker with steaming water close to the substrates and monitoring the fogging of the substrates when exposed to the steam from the beaker. As can be seen in FIG. 26 and FIG. 27, the patterned samples have anti-fogging properties relative to the planar samples.

In summary, a simple fabrication process was demonstrated that can obtain tapered sapphire nanostructures by a high aspect ratio polysilicon etch mask fabricated via ICP-RIE with a low RF power. The highest aspect ratio of current sapphire nanostructures is 2.07 with a height of 500 nm. Principal component analysis for optical emission spectroscopy was able to identify key emissions, which benefits the etching process development. Sapphire nanostructures enhanced aspect ratio effects for wavelength longer than 565 nm; the peak enhancement of 96% compared with 86% for planar surface. Nanotextured sapphire surface possesses multifunctionality such as antireflection and antifogging.

Further, the height of the nanostructures can be increased by using a thicker poly-silicon mask and transmittance in UV region can be enhanced by fabricating smaller period structures.

### Example 3—Fabrication Process for Creating Functional Nanostructures on Sapphire and Other Hard Optical Ceramics

Nanostructures on a surface can impart functionality to the surface, such as anti-glare (anti-reflective), anti-dust, anti-fog, superhydrophobic, and superhydrophilic properties. However, not every material can be patterned easily on its surface, especially hard transparent ceramics, such as sapphire and alumina-based materials. For example, in optical applications, sapphire is a material with great transparency and both chemical and physical stabilities, which can lead to broader applications in multiple fields. However, the reflection loss and decreasing light transmission due to the refractive index mismatch at the interface between two materials limits the performance of the optical device. Because the refractive index of sapphire is much higher than other transparent materials, such as silica, the refractive index mismatch leads to a problematic energy loss. As a result, fabricating nanostructures in sapphire is needed for realizing low energy loss sapphire devices, leading to much broader applications in optics, photonics, and optics-electronic area.

Described herein is a technology to create high aspect ratio nanostructures on sapphire and other hard-to-pattern materials, which are challenging to pattern via current techniques, using a high aspect ratio polysilicon mask fabricated by low radio frequency (RF) power. Via this approach, high-performance functional surfaces can be obtained. For instance, this fabrication method can be used to pattern tall sapphire nanostructures with high aspect-ratio to eliminate light reflection at different incident angles and it works for broadband wavelength.

A high aspect ratio polysilicon mask fabrication process via low RF power is demonstrated to fabricate taller, high aspect-ratio, and functional nanostructures in sapphire and other hard-to-pattern materials. This process is compatible with all patterning techniques, such as lithography and self-assembly processes. This disclosure focuses on sapphire and hard-to-pattern materials, which are traditionally challenging to pattern.

In optical applications, this fabrication process can pattern functional sapphire substrates with tall nanostructures and a high aspect-ratio. The transmittance can be enhanced at different incident angles over broadband wavelength. For example, the transmittance can be increased from 86% to 96% via patterning nanostructures on both sides of sapphire substrates.

The methods described herein can enhance or modify the surface function and performance on sapphire and other hard-to-patterned materials by creating high aspect ratio nanostructures that are traditionally difficult to make. It can lead to properties such as anti-glare, self-cleaning, anti-fogging, etc.

Improving nanostructures height and aspect-ratio on sapphire and other hard-to-pattern materials can leads to an improved performance, which cannot be achieved using existing technology.

The performance can be further enhanced by increasing the height and aspect-ratio of nanostructures on sapphire and other hard-to-pattern materials. An example described herein is around 1 in by 1 in size. The fabrication technology can be scalable.

This technology can find interests for displays, portable electronics, windows, lighting, etc. that can benefit from using a scratch-fee surface such as sapphire. Also, the anti-dust function can find interest in space programs and research.

### Example 4

Sapphire has many optical applications in nanophotonics and optoelectronic devices due to its high index, broadband transparency, and chemical and physical stability. However, sapphire is notoriously difficult to process, cut, and micromachine. As a result, patterning high density and aspect ratio nanostructures in sapphire, such as those needed for nanophotonics, are challenging. Here, an effective fabrication approach to pattern high aspect-ratio sapphire nanostructures is demonstrated. The process is used to demonstrate antireflection sapphire nanostructures. The optical properties of the sapphire nanostructures indicates that the antireflection effect operates at broadband wavelengths. This work demonstrate that sapphire nanostructures can be patterned, and can find applications in sapphire-based nanophotonics, metasurfaces, and optoelectronics devices.

Transparent substrates have many optical applications such as windows, lenses, nanophotonic structures, metasurfaces, solid-state lighting, and optoelectronic devices (YS Lin et al. Appl. Surf Sci. 2011, 258, 2; KC Park et al. ACS Nano, 2012, 6, 3789; J W Leem et al. Opt. Expr. OE, 2012, 20, 26160; X Ye et al. Sci. Rep. 2015, 5, 13023; XA Zhang et al. Opt. Lett., OL, 2017, 42, 4123; Y A et al. J. Appl. Phys. 2019, 126, 063101; P Lalanne et al. Nanotechnology, 1997, 8, 53; Y Kanamori et al. Opt. Lett., OL, 1999, 24, 1422). Most existing transparent substrates are based on silica, which has established manufacturing processes. Silicon oxide and silica-based glass are also relatively easy to micromachine and the subtractive etching processes are well understood. However, there are several limitations with silica-based glass. First, silica has relatively low index of around 1.45, which offers a limited index contrast and phase delay for nanophotonic elements and metasurfaces. Second, silica can have absorption peaks in the IR and has limited transmission for wavelength longer than 3.5 μm, limiting their application for visible to NIR range. Lastly, silica-based glass also lacks mechanical and thermal durability and is subjected to scratch damage and low operating temperature. These properties limit the application of silica-based glass in extreme environments. In contrast with silica, sapphire and other alumina-based transparent ceramics including aluminum oxynitride (AlON), yttrium aluminum garnet (YAG), and magnesium aluminate spinel (MgAl₂O₄) have a number of key advantages due to their chemical and physical stabilities (LM Goldman et al. Window and Dome Technologies and Materials XII (International Society for Optics and Photonics), 2011, 8016, 801608; CT Warner et al. Window and Dome Technologies and Materials IX (International Society for Optics and Photonics), 2005, 5786, 95-111). With Mohs hardness scale of 9, sapphire is among the hardest of all naturally occurring material only behind diamond, and is therefore useful as a protective material for wear and scratch resistance. Sapphire also has high Young's modulus of 350 GPa and compressive and tensile strengths of 2 and 0.5 GPa, respectively. In addition, sapphire has broad optical transmission from wavelength of 0.25 to 5 μm, which can be important for infrared (IR) optics. It also has high optical refractive index in the range of 1.75 in the visible and can increase light trapping and reduce losses in integrated photonics. Sapphire is also a good thermal conductor with 40 W/mK and has high melting point of 2030 °C, making it useful for high-temperature applications. Furthermore, it is chemically inert and is resistant to corrosion. These properties make sapphire attractive for long-term protection in extreme environments such as high temperature, pressure, and mechanical loading. To date, one of the most common applications for sapphire in defense is missile domes (LM Goldman et al. Window and Dome Technologies and Materials XII (International Society for Optics and Photonics), 2011, 8016, 801608), which requires the material to survive through harsh launch conditions as well as high light transmission in the IR for various optical signals. Sapphire also has broad applications in nanophotonic and optoelectronic devices due to its optical and high temperature stability (KC Park et al. ACS Nano, 2012, 6, 3789; J W Leem et al. Opt. Expr. OE, 2012, 20, 26160; XA Zhang et al. Opt. Lett., OL, 2017, 42, 4123; Y A et al. J. Appl. Phys. 2019, 126, 063101). In comparison to silica-based photonics, which has absorption peaks in the near infrared (NIR), sapphire photonics can maintain high NIR transmission up to 5 μm. Recent work using silicon-on-sapphire integrated waveguides have demonstrated operation in the NIR region up to 4.5 μm wavelength (Silicon-on-sapphire integrated waveguides for the mid-infrared. https://www.osa.publishing.org/oe/fulltext.cfm?uri=oe-18-12-12127&id=199713; Z Cheng et al. IEEE Photon. J. 2012, 4, 104). In addition, sapphire photonics can operate at much higher temperature when compared with silica. One example is sapphire fiber Bragg grating for measuring strain and temperature measurement, which can operate from room temperature to elevated temperature of 1400 °C (SJ Mihailov et al. Opt. Lett., OL, 2010, 35, 2810; S Yang et al. Opt. Lett., OL, 2018, 43, 62). Sapphire-based white-light interferometric fiber sensor have also demonstrated high operation temperature of 1600 °C (Y Zhu et al. Opt. Lett., OL, 2005, 30, 711). Sapphire substrates are also attractive for epitaxial growth of III-V semiconductors and have applications in UV LEDs and laser diodes (S Nakamura et al. Appl. Phys. Lett. 1994, 64, 1687; H Hu et al. Nano Energy, 2020, 69, 104427; M Shan et al. ACS Photon. 2019, 6, 2387; TB Tran et al. Sci. Rep. 2021, 11, 4981). The benefits of fabricating photonic devices on sapphire materials includes higher index, broader operation range in the IR, and higher operation temperature, which can lead to broader applications for photonics in extreme environments. However, one significant challenge is that creating photonic nanostructures in sapphire and other alumina-based materials is extremely difficult. This can be attributed to their chemical inertness, which results in low etch rates during plasma etching and other traditional micromachining processes where reaction chemistry plays a key role. Wet etching of sapphire in high-temperature acid solutions (such as H₂SO₄, H₃PO₄, etc.) is one method to pattern surface microstructures (YC Chen et al. J. Electrochem. Soc. 2012, 159, D362; CC Chen et al. ECS J. Solid State Sci. Technol. 2013, 2, R169; N Aota et al. ECS J. Solid State Sci. Technol. 2014, 3, N69; YC Chen et al. Mater. Lett. 2014, 118, 72; J Shen et al. ECS J. Solid State Sci. Technol. 2017, 6, R24; J. Shen et al. ECS J. Solid State Sci. Technol. 2017, 6, R122; J. Shen et al. ECS J. Solid State Sci. Technol. 2017, 6, R163). However, given the wet etching approach such structures have low feature resolution and are typically limited to the 10 μm scale. The etch depth are also difficult to precisely control and are relatively shallow, resulting in low aspect ratio less than 1. Furthermore, the etch isotropy and anisotropy in wet etching is constrained by the crystal structure of the material and cannot be well controlled. Previous work has also demonstrated reactive ion etching (RIE) of sapphire microstructures (Etch Characteristics of Al₂O₃ in ICP and MERIE Plasma Etchers—IOPscience. https://iopscience.iop.org/article/10.1149/1.1865912/pdf; SM Koo et al. Mater. Sci. Eng. B, 2005, 118, 201; H Chen et al. Nanotechnology, 2015, 26, 085302; N Heiman et al. J. Vac. Sci. Technol. 1980, 17, 731; CH Jeong et al. Surf Coat. Technol. 2033, 171, 280; CH Jeong et al. Mater. Sci. Eng. B, 2002, 93, 60; JDB Bradley et al. Appl. Phys. B Lasers Opt. 2007, 89, 311; SH Park et al. Appl. Opt. AO, 2001, 40, 3698). However, these structures generally have large features in the ~10 μm range. Finer sub-micrometer structures (YS Lin et al. Appl. Surf Sci. 2011, 258, 2; J W Leem et al. Opt. Expr. OE, 2012, 20, 26160) have also been demonstrated, but the structures have random order and high feature roughness. Recent work using nanoimprint have successfully demonstrated periodic nanostructures in sapphire (H Chen et al. Nanotechnology, 2015, 26, 085302). However, the etch depth is relatively low due to the low etch selectivity, resulting in low aspect ratio nanostructures. Therefore, fabricating high resolution sapphire nanostructures with high selectivity for high-efficiency photonic and optoelectronics is still a critical challenge. In this work, an effective method to pattern high aspect-ratio nanostructures in sapphire substrates is demonstrated. The fabricated sapphire nanostructures can effectively suppress the Fresnel losses over broadband wavelength band and wide incident angles. This work demonstrates that high-resolution, periodic sapphire nanostructures can be fabricated with high etch selectivity, which can open the door to sapphire-based nanophotonics, metasurfaces, and other optoelectronic devices.

### Example 5—Bio-Inspired Multifunctional Sapphire Window with Anti-Glare, Self-Cleaning, and Scratch-Resistant Properties

Micro/nanostructures in Nature. Micro/nanostructures can help to respond and adapt to changes in surroundings. For example, Lotus leaves have roughness due to micro/nanostructures on their surface which can lead to superhydrophobic surface properties (Nosonovsky M et al. Microsyst. Technol. 2005, 11, 535-549). Panther Chameleons can change their skin color for communication and defense by changing the structure period of micro/nanostructures on their skin (Teyssier J et al. Nat Comm, 2015, 6, 6368).

From Nature to Engineering: Bio-Inspired Structures. Inspirations from nature can leave to new mechanisms and properties enable by engineered structures. For example, in Nature Moth eyes have tapered structures that can gradually match refractive indices of two media across the interface to mitigate Fresnel reflection loss (Vukusic P et al. Nature, 2003, 424, 852-855). This inspired engineering of multifunctional silica nanostructures that can impart superhydrophobicity, anti-fogging, and/or anti-reflection properties (Park K C et al. ACS Nano, 2012, 6(5), 3789-3799).

Sapphire as a Window Material. Sapphire has many applications in photonics and optoelectronics due to its high mechanical hardness, thermal tolerance, chemical stability and high optical transmittance in IR, such as uses in missile domes, windows, watch faces, and camera lenses. Larger refractive index mismatch leads to higher optical reflection. High aspect ratio (HAR) bio-inspired sapphire nanostructures can mitigate reflection but are difficult to fabricate (Dobrovinskaya E R et al. Sapphire: Material, Manufacturing, Applications, Springer, 2009).

Sapphire Etching Studies. Inductively coupled plasma reactive ion etching (ICP-RIE) has been applied to sapphire (Jeong C H et al. Surface and Coatings Technology, 2003, 171, 280-284; Bradley J D B et al. Appl Phys B, 2007, 89, 311; Leem J W et al. Opt Express, 2012, 20, 26160; Chen Y A et al. Micro and Nano Eng. 2022, 14, 100115). However, these studies either have large features at micrometer scale, smaller features at nanometer scale, or focus on amorphous Al₂O₃ films. Generally, these structures either have low aspect ratio, or random order and mark removal issues.

Fabrication Process. Described herein is a fabrication process as shown schematically in FIG. 18. The method includes using a polymer mask and a thick poly-Si layer. Lloyd's mirror is then used to form a 2D pattern. The method creates high aspect ratio polysilicon pillars as an etch mask with a low RF power.

Etching Results. A photograph of an example substrate is shown in FIG. 9. The thickness of the poly-Si mask varied, such that not all of the polysilicon pillars were removed with a given etch time, which contributes to the variation in color in FIG. 9.

After using BCl₃/HBr ICP-RIE with 400 W RF power to etch the sapphire substrate for 18 min, it can be observed that most parts of high aspect ratio polysilicon pillars, which exhibit a deep-colored appearance, are removed FIG. 9). The sapphire nanostructures of that area (e.g., where most of the polysilicon pillars are removed) follow a tapered profile, as seen in the cross-section SEM image shown in FIG. 21. However, some parts of high aspect ratio polysilicon pillars around the edge of the sample are not completely removed after etching for 18 min due to the non-uniform thickness of the polysilicon layer (resulting the in deep colored appearance in FIG. 9). After an additional 5 min etch time (e.g., etching for 23 minutes total using HBr/BCl₃ ICP-RIE with 400 W RF power), the resulting tapered sapphire nanostructures are shown in FIG. 22.

An SEM image of a sample made after etching for 18 minutes using HBr/BCl₃ ICP-RIE with 400 W RF power is shown in FIG. 21; the pillars had an average height of 385 nm and an aspect ratio of 1.59. An SEM of a sample made from a section where the polysilicon mask was thicker after etching for 23 minutes using HBr/BCl₃ ICP-RIE with 400 W RF power is shown in FIG. 22; the pillars had an average height of 500 nm and an aspect ratio of 2.07. Thus, a thicker polysilicon mask can result in taller sapphire nanostructures and/or a greater aspect ratio.

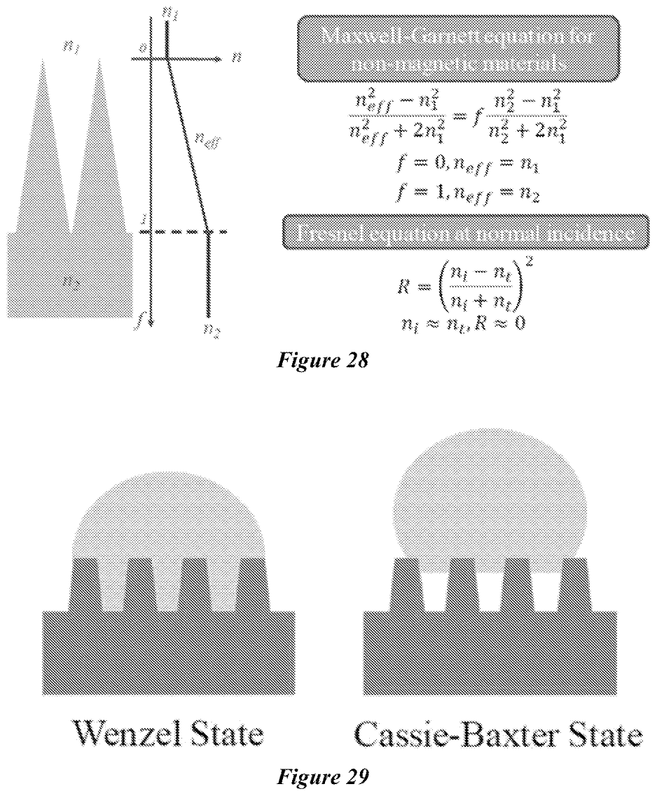

Bio-Inspired Nanostructures: Anti-Glare. Bio-inspired tapered nanostructures (e.g., inspired by Moth eyes as discussed above) can create a gradient-index (GRIN) medium to gradually match refractive indices of two media across the interface to mitigate Fresnel reflection loss (anti-glare) (FIG. 28).

Bio-Inspired Nanostructures: Surface Wetting. Surface wetting properties, hydrophobicity or hydrophilicity, can be affected by surface structure geometry and chemistry. Hydrophilic surfaces can help reduce light scattering caused by small water droplets during condensation due to the formation of a thin water film (anti-fogging). Hydrophobic surfaces can help remove particles using water droplets rolling off of the surface (self-cleaning). A Cassie-Baxter surface is important for self-cleaning because droplets can easily bounce and roll off (e.g., Lotus effect) (FIG. 29).

Transmittance Measurements. Broadband transmittance measurements were performed on a planar sapphire sample, a single-sided patterned sample (e.g., patterned on one side) made using the methods herein, and a double-sided patterned sample (e.g., patterned on two sides) made using the methods herein. The results are shown in FIG. 23. Single- and double-sided nanostructures enhance transmittance for wavelength longer than 565 nm. At 1360 nm, transmission of double-sided sample increases from 86% to 96%. Transmittance decreases significantly for wavelengths shorter than around 600 nm due to the diffraction effect.

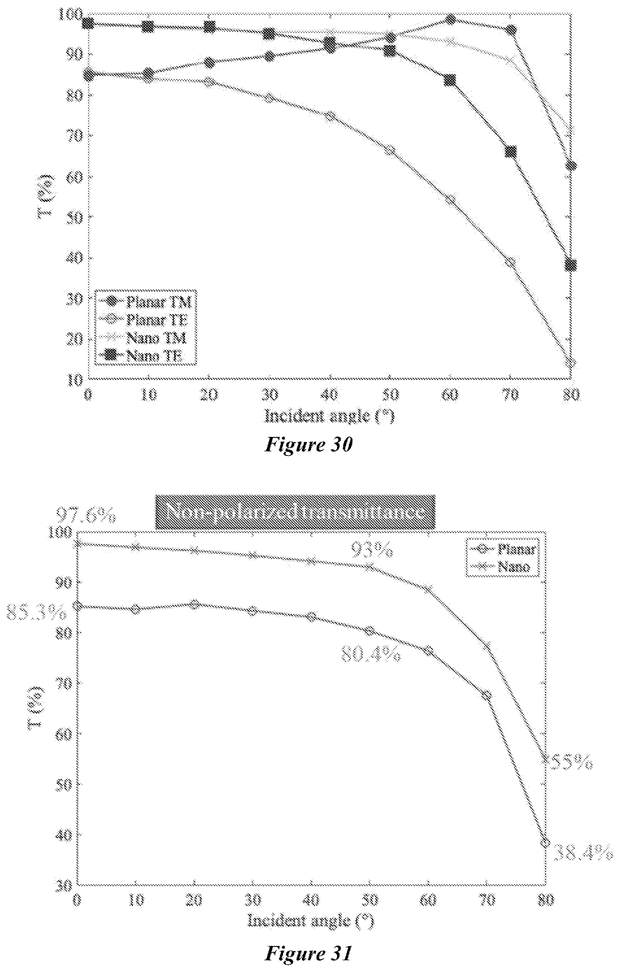

The transmittance was also measured at 1330 nm for different incidence angles. The transmittance of TE and TM are shown in FIG. 30. The non-polarized transmittance is shown in FIG. 31. These results indicate that the bio-inspired sapphire nanostructures enhance transmittance regardless of the incidence angle.

Multifunctional Surface: Anti-Glare. Patterning the sapphire can result in anti-glare properties. Images illustrating the anti-glare/anti-reflection properties of patterned sapphire vs. planar sapphire are shown in FIG. 24 and FIG. 25.

Multifunctional Surface: Anti-Fogging. Patterning the sapphire can also result in anti-fogging properties. Images illustrating the anti-fogging properties of patterned sapphire vs. planar sapphire are shown in FIG. 26 and FIG. 27. The anti-fogging properties were tested by placing a beaker with steaming water close to the substrates and monitoring the fogging of the substrates when exposed to the steam from the beaker. As can be seen in FIG. 26 and FIG. 27, the patterned samples have anti-fogging properties relative to the planar samples.

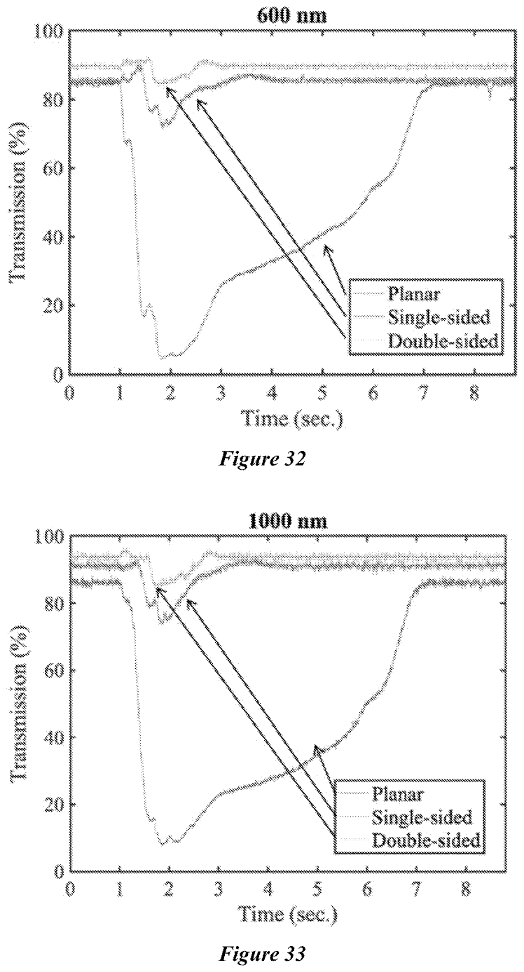

The time evolution of transmission for anti-fogging was investigated for a planar sapphire sample, a single-sided patterned sample (e.g., patterned on one side) made using the methods herein, and a double-sided patterned sample (e.g., patterned on two sides). At both 600 and 1000 nm (FIG. 32 and FIG. 33, respectively), after water condensation on samples for 1 s, the transmission of the planar sample drops to below 10% and it takes 8 s to recover. Meanwhile, the double-sided sample can maintain high transmission (over 80%) during the water condensation process, and therefore no need to recover.

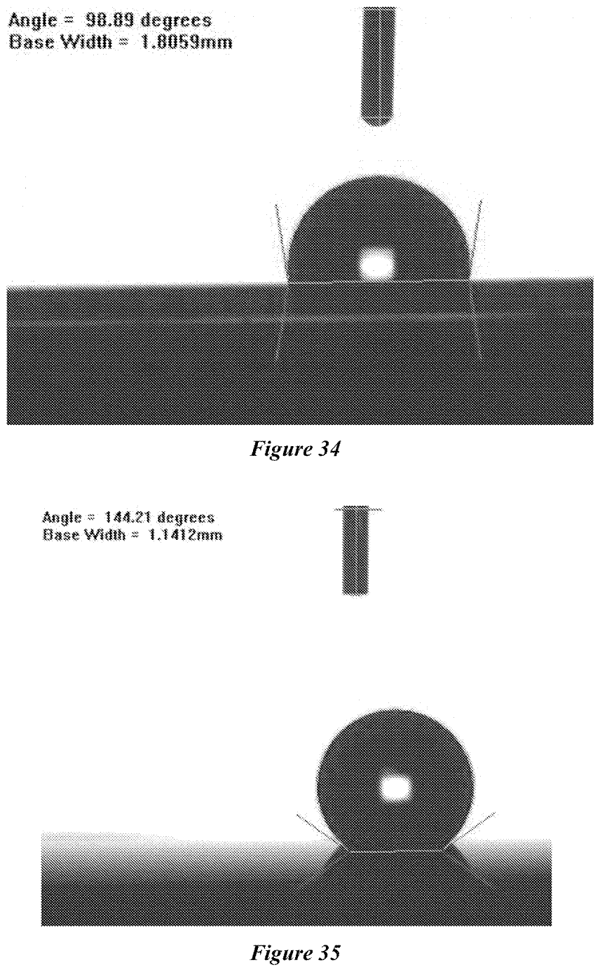

Water Contact Angle after Silane Coating. The sapphire surface chemistry was changed by O₂ plasma cleaning followed by monolayer silane coating. Both surfaces demonstrate hydrophobicity: 98.9° contact angle for planar surface and 144.2° contact angle for nanotextures surface (FIG. 34 and FIG. 35, respectively).

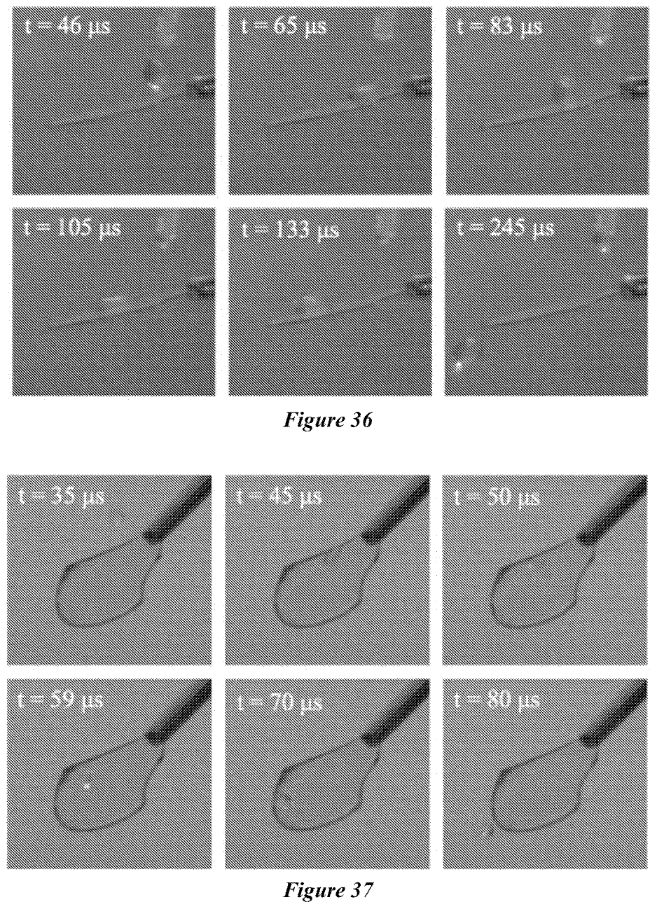

Multifunctional Surface: Self-Cleaning. The self-cleaning properties of the patterned surfaces made using the methods described herein were investigated. The behavior of a water droplet introduced onto the patterned surface with a low impact at a 20° oblique angle is shown in the photographs in FIG. 36. Further, the behavior of a water droplet introduced onto the surface with a high impact at a 50° oblique angle (V=1 μm/s) is shown in FIG. 37.

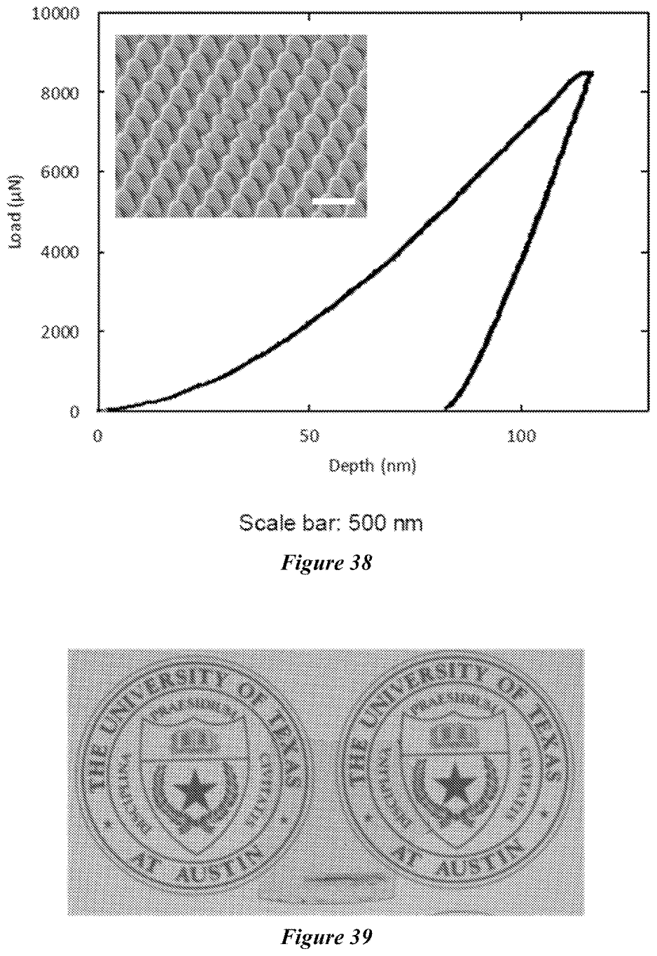

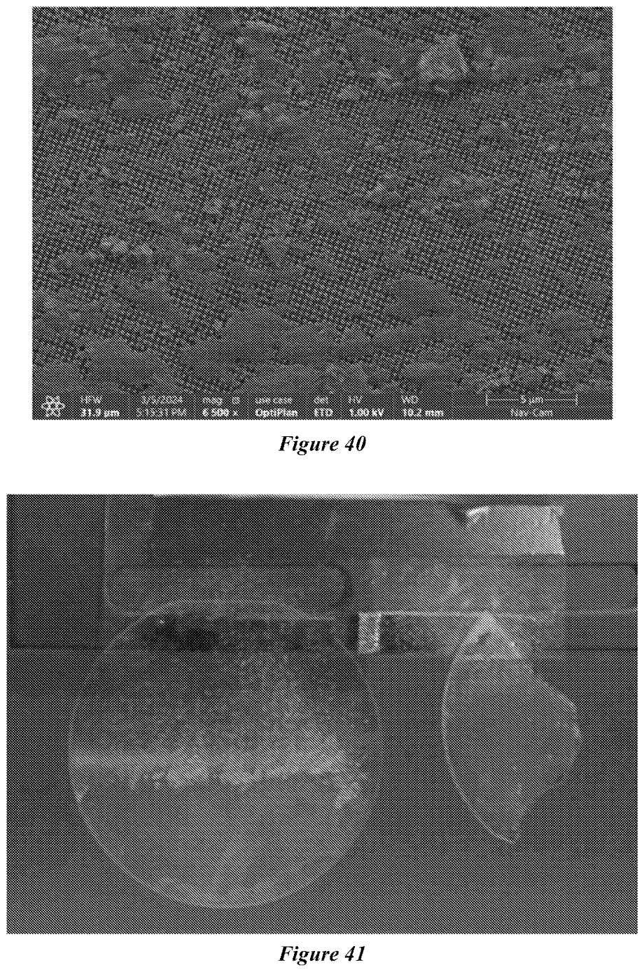

Mechanical Properties. Preliminary nanoindentation and pencil hardness tests showed that these bio-inspired sapphire nanostructures have high stiffness, hardness, and scratch resistance (FIG. 38-FIG. 40). The nanoindentation tests show that the hardness of the sapphire nanostructures at around 10% of the nanopillar height is ~1.8 GPa based on the quasi-static, load-controlled indentation test method. The reduced modulus at the same depth is calculated as ~115 GPa based on Oliver-Pharr method. These values are remarkable for nanopillar structures, especially when compared to the bulk sapphire, which has around 30 GPa of hardness and 440 GPa of indentation modulus. Hysitron TI 950 Triboindenter (Bruker, USA) performed nanoindentation tests on sapphire nanopillar structures. A conospherical indenter with 10 μm tip radius and 90° cone angle was utilized. The pencil hardness test shows that the sapphire nanostructures are undamaged after testing at 7.5N loading at 450 angle with a 2B pencil lead, showing the mechanical robustness of the structures. This test followed ASTM D3363 Standard Test Method for Film Hardness by Pencil Test.

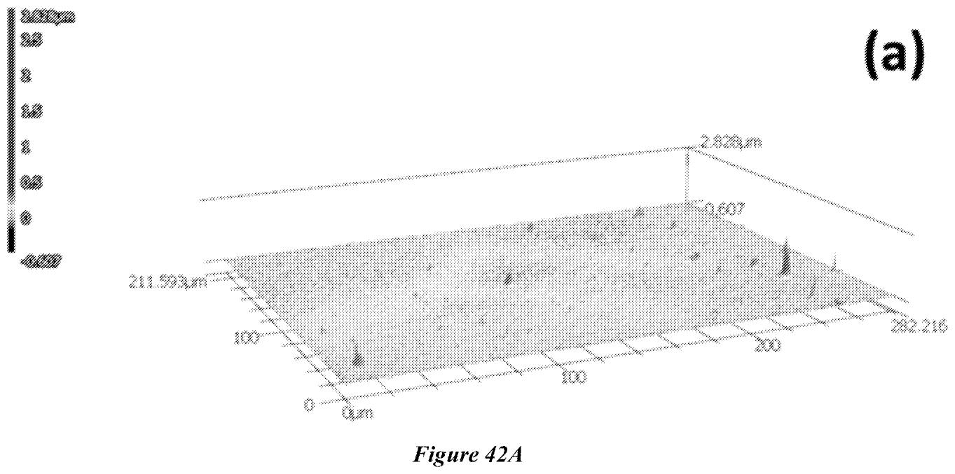

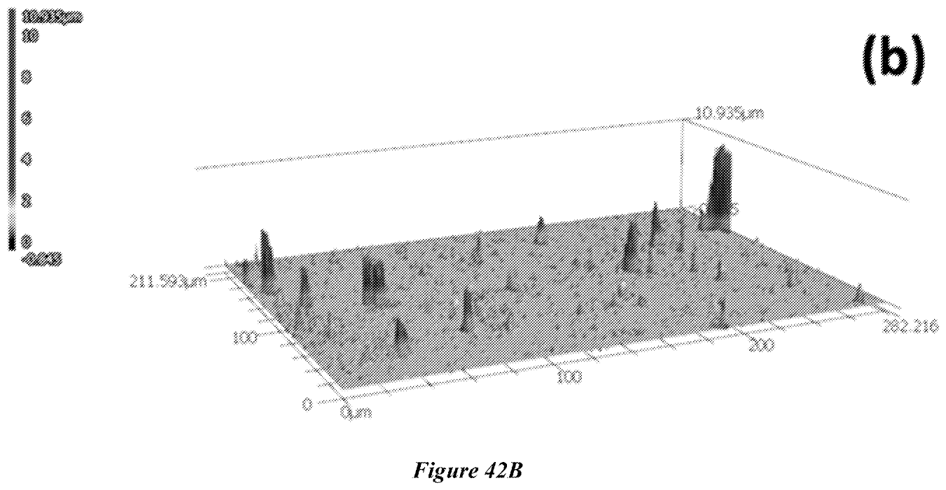

Multifunctional Surface: Anti-Dust. The anti-dust experiment using a lunar dust simulant shows that the nanostructured sapphire surface can reduce 95.9% dust coverage. FIG. 41 shows planar sapphire sample (left) and nanostructured sapphire sample (right) after the anti-dust experiment using a lunar dust simulant. FIG. 42A-FIG. 42B shows topographic maps of the nanostructured sapphire surface (FIG. 42A) and the planar sapphire surface (FIG. 42B) by the confocal microscopy after the anti-dust experiment.

Conclusion. Bio-inspired sapphire surfaces fabricated by low RF power ICP-RIE demonstrate their multifunctionality. For anti-glare, the bio-inspired sapphire surfaces showed omnidirectional broadband enhancement of transmission, which increased by 11.6% at 1360 nm (from 86% to 96%), and increased by 43.2% at 800 incident angle (from 38.4% to 55%). For anti-fogging, the bio-inspired sapphire surfaces can maintain transmission above 80% during the water condensation, so no need to recover. For self-cleaning, the bio-inspired sapphire surfaces are close to being superhydrophobic and the wetting condition is in the Cassie-Baxter state, causing water droplets to bounce and roll of the surface. For mechanical properties, the bio-inspired sapphire surfaces have high stiffness, hardness, and scratch resistance. For anti-dust, the bio-inspired sapphire surfaces shows 95.9% reduction in residual dust coverage.

### EXEMPLARY ASPECTS

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A patterned material comprising a first plurality of nanostructures patterned on a first surface of a substrate, wherein: the first plurality of nanostructures have a first average aspect ratio of 0.5 or more; the first plurality of nanostructures comprise a first plurality of pillars extending from the first surface of the substrate; the first plurality of nanostructures are arranged in a first ordered array, such that the first plurality of nanostructures are periodic; the first plurality of nanostructures and the substrate comprise a transparent ceramic material comprising alumina (aluminum oxide, Al₂O₃) (e.g., an alumina-based transparent ceramic material); and the first plurality of nanostructures are substantially uniform over a surface area of 10 square micrometers (m²) or more on the first surface of the substrate.

Example 2: The patterned material of any examples herein, particularly example 1, wherein the first plurality of nanostructures are integrally formed with the first surface of the substrate.

Example 3: The patterned material of any examples herein, particularly example 1 or example 2, wherein the first plurality of nanostructures have a first average aspect ratio of 1 or more, 1.5 or more, or 2 or more.

Example 4: The patterned material of any examples herein, particularly examples 1-3, wherein the first plurality of pillars have a first average characteristic dimension (e.g., diameter) and a first average height, and the first average characteristic dimension varies along at least a portion of the first average height (e.g., at least a portion of each of the first plurality of pillars are tapered).

Example 5: The patterned material of any examples herein, particularly example 4, wherein the first plurality of pillars have a first average height of from 200 nanometers (nm) to 2 micrometers (microns, μm).

Example 6: The patterned material of any examples herein, particularly example 4 or example 5, wherein the first average characteristic dimension of the first plurality of pillars at the first surface of the substrate (e.g., the base of the first plurality of pillars) is from 50 nm to 2 μm.

Example 7: The patterned material of any examples herein, particularly examples 1-6, wherein the first ordered array comprises a two dimensional array.

Example 8: The patterned material of any examples herein, particularly examples 1-7, wherein the first ordered array has a first periodicity of from 10 nanometers (nm) to 1 micrometer (μm).

Example 9: The patterned material of any examples herein, particularly examples 1-8, wherein the first ordered array has a first periodicity of 300 nm or less, 250 nm or less, or 200 nm or less.

Example 10: The patterned material of any examples herein, particularly examples 1-8, wherein the alumina-based transparent ceramic material comprises sapphire (single-crystal aluminum oxide), aluminum oxynitride spinel (Al₂₃O₂₇N₅, abbreviated as AlON), yttrium aluminum garnet (YAG), magnesium aluminate spinel (MgAl₂O₄), alumina-based glass, derivatives thereof, or a combination thereof.

Example 11: The patterned material of any examples herein, particularly examples 1-9, wherein the alumina-based transparent ceramic material comprises sapphire.

Example 12: The patterned material of any examples herein, particularly examples 1-10, wherein the alumina-based transparent ceramic material has a Mohs hardness of 7 or more, 7.5 or more, 8 or more, 8.5 or more, or 9 or more.

Example 13: The patterned material of any examples herein, particularly examples 1-12, wherein the substrate has a second surface, the second surface being opposite and spaced apart from the first surface (e.g., the first surface is a top surface and the second surface is a bottom surface), and the patterned material further comprises a second plurality of nanostructures patterned on the second surface of the substrate, wherein: the second plurality of nanostructures have a second average aspect ratio of 0.5 or more; the second plurality of nanostructures comprise a second plurality of pillars extending from the second surface of the substrate; the second plurality of nanostructures are arranged in a second ordered array, such that the second plurality of nanostructures are periodic; the second plurality of nanostructures comprise the alumina-based transparent ceramic material; and the second plurality of nanostructures are substantially uniform over a surface area of 10 square micrometers (m²) or more on the second surface of the substrate.

Example 14: The patterned material of any examples herein, particularly example 13, wherein the second plurality of nanostructures are integrally formed with the second surface of the substrate.

Example 15: The patterned material of any examples herein, particularly example 13 or example 14, wherein the second plurality of nanostructures have a second average aspect ratio of 1 or more, 1.5 or more, or 2 or more.

Example 16: The patterned material of any examples herein, particularly examples 13-15, wherein the second plurality of pillars have a second average characteristic dimension (e.g., diameter) and a second average height, and the second average characteristic dimension varies along at least a portion of the second average height (e.g., at least a portion of each of the second plurality of pillars are tapered).

Example 17: The patterned material of any examples herein, particularly example 16, wherein the second plurality of pillars have a second average height of from 200 nanometers (nm) to 2 micrometers (microns, μm).

Example 18: The patterned material of any examples herein, particularly example 16 or example 17, wherein the second average characteristic dimension of the second plurality of pillars at the second surface of the substrate (e.g., the base of the second plurality of pillars) is from 50 nm to 2 μm.

Example 19: The patterned material of any examples herein, particularly examples 13-18, wherein the second ordered array comprises a two dimensional array.

Example 20: The patterned material of any examples herein, particularly examples 13-19, wherein the second ordered array has a second periodicity of from 10 nanometers (nm) to 1 micrometer (μm).

Example 21: The patterned material of any examples herein, particularly examples 13-20, wherein the second ordered array has a second periodicity of 300 nm or less, 250 nm or less, or 200 nm or less.

Example 22: The patterned material of any examples herein, particularly examples 13-21, wherein the second plurality of nanostructures are the same as the first plurality of nanostructures.

Example 23: The patterned material of any examples herein, particularly examples 1-22, wherein the patterned material exhibits improved anti-glare (anti-reflection) properties, anti-dust properties, anti-fog properties, anti-scratch properties, self-cleaning properties, or a combination thereof, for example relative to the substrate in the absence of the patterning.

Example 24: The patterned material of any examples herein, particularly examples 1-23, wherein the patterned material exhibits improved anti-reflection properties.

Example 25: The patterned material of any examples herein, particularly examples 1-24, wherein the patterned material exhibits reduced reflectance and/or enhanced transmittance at one or more wavelengths, for example relative to the substrate in the absence of the patterning.

Example 26: The patterned material of any examples herein, particularly examples 1-25, wherein the patterned material exhibits a transmittance of 90% or more at one or more wavelengths from 300 nm to 5000 nm.

Example 27: The patterned material of any examples herein, particularly example 26, wherein the transmittance is at incidence angle of from 0° to 90°.

Example 28: The patterned material of any examples herein, particularly examples 1-27, wherein the patterned material exhibits improved anti-fog properties.

Example 29: The patterned material of any examples herein, particularly example 28, wherein the patterned material reduces fogging/water condensation by 90% or more (e.g., 91% or more, 92% or more, 93% or more, 94% or more, 95% or more, 96% or more, 97% or more, 98% or more, or 99% or more) relative to the substrate in the absence of the patterning (e.g., a substantially flat/planar substrate).

Example 30: The patterned material of any examples herein, particularly examples 1-29, wherein the patterned material exhibits improved anti-dust properties.

Example 31: The patterned material of any examples herein, particularly example 30, wherein the patterned material reduces dust adhesion by 90% or more (e.g., 91% or more, 92% or more, 93% or more, 94% or more, 95% or more, 96% or more, 97% or more, 98% or more, or 99% or more) relative to the substrate in the absence of the patterning (e.g., a substantially flat/planar substrate).

Example 32: The patterned material of any examples herein, particularly examples 1-31, wherein the patterned material exhibits mechanical robustness.

Example 33: The patterned material of any examples herein, particularly examples 1-32, wherein the patterned material exhibits enhanced toughness while maintaining high stiffness, hardness, and/or scratch resistance, for example relative to the substrate in the absence of the patterning.

Example 34: The patterned material of any examples herein, particularly examples 1-33, wherein the patterned material has a hardness of 1.8 GPa or more (e.g., 5 GPa or more, 10 GPa or more, 15 GPa or more, 20 GPa or more, 25 GPa or more, or 30 GPa or more) relative to the substrate in the absence of the patterning (e.g., a substantially flat/planar substrate) based on the quasi-static, load-controlled indentation test method.

Example 35: The patterned material of any examples herein, particularly examples 1-34, wherein the patterned material has an indentation modulus of 115 GPa or more (e.g., 150 GPa or more, 200 GPa or more, 250 GPa or more, 300 GPa or more, 350 GPa or more, 400 GPa or more, or 440 GPa or more) relative to the substrate in the absence of the patterning (e.g., a substantially flat/planar substrate) based on Oliver-Pharr method.

Example 36: A method of making the patterned material of any examples herein, particularly examples 1-35.

Example 37: The method of any examples herein, particularly example 36, wherein the method comprises: patterning a photoresist layer of a first layered stack, thereby making a second layered stack where the photoresist layer is patterned; wherein the first layered stack comprises the photoresist layer, an antireflection layer, a polysilicon layer, and a substrate having a first surface, the polysilicon layer being disposed on the first surface of the substrate, the antireflection layer being disposed on the polysilicon layer such that the polysilicon layer is sandwiched between the antireflection layer and the first surface of the substrate, and the photoresist layer being disposed on the antireflection layer such that the antireflection layer is sandwiched between the photoresist layer and the polysilicon layer; patterning the antireflection layer of the second layered stack to transfer the pattern of the photoresist layer to the antireflection layer, thereby making a third layered stack where the photoresist layer and the antireflection layer are patterned; patterning the polysilicon layer of the third layered stack to transfer the pattern of the antireflection layer to the polysilicon layer, thereby making a fourth layered stack where the photoresist layer, the antireflection layer, and the polysilicon layer are patterned; and etching the fourth layered stack to transfer the pattern of the polysilicon layer to the substrate and remove the photoresist layer, the antireflection layer, and the polysilicon layer, thereby making the patterned material.

Example 38: The method of any examples herein, particularly example 36, wherein the method comprises: patterning a photoresist layer of a first precursor layered stack, thereby making a first intermediate layered stack where the photoresist layer is patterned; wherein the first precursor layered stack comprises the photoresist layer, a polysilicon layer, and a substrate having a first surface, the polysilicon layer being disposed on the first surface of the substrate, the photoresist layer being disposed on the polysilicon layer such that the polysilicon layer is sandwiched between the photoresist layer and the first surface of the substrate; patterning the polysilicon layer of the first intermediate layered stack to transfer the pattern of the photoresist layer to the polysilicon layer, thereby making a second intermediate layered stack where the photoresist layer and the polysilicon layer are patterned; and etching the second intermediate layered stack to transfer the pattern of the polysilicon layer to the substrate and remove the photoresist layer and the polysilicon layer, thereby making the patterned material.

Example 39: The method of any examples herein, particularly examples 36-38, wherein the substrate has a second surface, the second surface being opposite and spaced apart from the first surface (e.g., the first surface is a top surface and the second surface is a bottom surface), and the method further comprises patterning the second surface.

Example 40: The method of any examples herein, particularly example 39, wherein the method comprises: patterning a photoresist layer of a fifth layered stack thereby making a sixth layered stack where the photoresist layer is patterned; wherein the fifth layered stack comprises the photoresist layer, an antireflection layer, a polysilicon layer, and the substrate having the second surface, the polysilicon layer being disposed on the second surface of the substrate, the antireflection layer being disposed on the polysilicon layer such that the polysilicon layer is sandwiched between the antireflection layer and the second surface of the substrate, and the photoresist layer being disposed on the antireflection layer such that the antireflection layer is sandwiched between the photoresist layer and the polysilicon layer; patterning the antireflection layer of the sixth layered stack, to transfer the pattern of the photoresist layer to the antireflection layer, thereby making a seventh layered stack where the photoresist layer and the antireflection layer are patterned; patterning the polysilicon layer of the seventh layered stack to transfer the pattern of the antireflection layer to the polysilicon layer, thereby making an eighth layered stack where the photoresist layer, the antireflection layer, and the polysilicon layer are patterned; and etching the eighth layered stack to transfer the pattern of the polysilicon layer to the substrate and remove the photoresist layer, the antireflection layer, and the polysilicon layer, thereby making the patterned material (e.g., wherein the first surface and the second surface are patterned).

Example 41: The method of any examples herein, particularly example 39, wherein the method comprises: patterning a photoresist layer of a second precursor layered stack thereby making a third intermediate layered stack where the photoresist layer is patterned; wherein the second precursor layered stack comprises the photoresist layer, a polysilicon layer, and the substrate having the second surface, the polysilicon layer being disposed on the second surface of the substrate, the photoresist layer being disposed on the polysilicon layer such that the polysilicon layer is sandwiched between the photoresist layer and the second surface of the substrate; patterning the polysilicon layer of the third intermediate layered stack, to transfer the pattern of the photoresist layer to the polysilicon layer, thereby making a fourth intermediate layered stack where the photoresist layer and the polysilicon layer are patterned; and etching the fourth intermediate layered stack to transfer the pattern of the polysilicon layer to the substrate and remove the photoresist layer and the polysilicon layer, thereby making the patterned material.

Example 42: The method of any examples herein, particularly examples 37-41, wherein patterning the photoresist layer comprises using interference lithography.

Example 43: The method of any examples herein, particularly examples 37-42, wherein patterning the photoresist comprises Llyod's mirror interference lithography with two orthogonal exposures.

Example 44: The method of any examples herein, particularly examples 37-43, wherein patterning the photoresist further comprises developing the photoresist by exposing the patterned photoresist to a solvent.

Example 45: The method of any examples herein, particularly examples 37-44, wherein patterning the antireflection layer comprises using inductively coupled plasma reactive ion etching (ICP-RIE), such as O₂ inductively coupled plasma reactive ion etching (ICP-RIE).

Example 46: The method of any examples herein, particularly examples 37-45, wherein patterning the antireflection layer comprises using O₂ inductively coupled plasma reactive ion etching (ICP-RIE): for an amount of time of from 1 minute to 5 minutes; at a RF power of from 10 to 300 W; at a pressure of from 1 to 30 μmTorr; with a O₂ flow rate of from 5 to 50 sccm; or a combination thereof.

Example 47: The method of any examples herein, particularly examples 37-46, wherein patterning the polysilicon layer comprises using ICP-RIE with low RF power, such as HBr ICP-RIE with low RF power.

Example 48: The method of any examples herein, particularly examples 37-47, wherein the low RF power used to pattern the polysilicon layer enhances etch selectivity.

Example 49: The method of any examples herein, particularly examples 37-48, wherein patterning the polysilicon layer comprises using HBr ICP-RIE with low RF power: for an amount of time of 30 minutes to 200 minutes; at a RF power of from 1 to 50 W; at an ICP power of from 100 to 600 W; at a pressure of from 1 to 30 μmTorr; with a HBr flow rate of from 5 to 50 sccm; or a combination thereof.

Example 50: The method of any examples herein, particularly examples 37-49, wherein etching the fourth layered stack, the eighth layered stack, the second intermediate layered stack, the fourth intermediate layered stack, or a combination thereof independently comprises using ICP-RIE, such as HBr/BCl₃ ICP-RIE.

Example 51: The method of any examples herein, particularly examples 37-50, wherein etching the fourth layered stack, the eighth layered stack, the second intermediate layered stack, the fourth intermediate layered stack, or a combination thereof independently comprises using HBr/BCl₃ ICP-RIE: for an amount of time of from 10 minutes to 120 minutes; at an RF power of from 100 to 500 W; at an ICP power of from 100 to 2000 W; at a pressure of from 1 to 30 mTorr; at a HBr flow rate of from 5 to 50 sccm; at a BCl₃ flow rate of from 5 to 50 sccm; or a combination thereof.

Example 52: The method of any examples herein, particularly examples 37-51, wherein the method further comprises making the first layered stack.

Example 53: The method of any examples herein, particularly example 52, wherein making the first layered stack comprises: depositing the polysilicon layer on the surface of the substrate; depositing the antireflection layer on the polysilicon layer; and depositing the photoresist layer on the antireflection layer.

Example 54: The method of any examples herein, particularly examples 38-51, wherein the method further comprises making the first precursor layered stack.

Example 55: The method of any examples herein, particularly example 54, wherein making the first precursor layered stack comprises: depositing the polysilicon layer on the surface of the substrate; and depositing the photoresist layer on the polysilicon layer.

Example 56: The method of any examples herein, particularly examples 40-55, wherein the method further comprises making the fifth layered stack.

Example 57: The method of any examples herein, particularly example 56, wherein making the fifth layered stack comprises: depositing the polysilicon layer on the second surface of the substrate; depositing the antireflection layer on the polysilicon layer; and depositing the photoresist layer on the antireflection layer.

Example 58: The method of any examples herein, particularly example 56 or example 57, wherein the method further comprises protecting the patterned first surface of the substrate before making the fifth layered stack.

Example 59: The method of any examples herein, particularly example 58, wherein the method comprises depositing a protective layer on the patterned first surface of the substrate.

Example 60: The method of any examples herein, particularly examples 41-55, wherein the method further comprises making the second precursor layered stack.

Example 61: The method of any examples herein, particularly example 60, wherein making the second precursor layered stack comprises: depositing the polysilicon layer on the second surface of the substrate; and depositing the photoresist layer on the polysilicon layer.

Example 62: The method of any examples herein, particularly example 60 or example 61, wherein the method further comprises protecting the patterned first surface of the substrate before making the second precursor layered stack.

Example 63: The method of any examples herein, particularly example 62, wherein the method comprises depositing a protective layer on the patterned first surface of the substrate.

Example 64: The method of any examples herein, particularly examples 52-63, wherein the polysilicon layer is deposited using low-pressure chemical vapor deposition (LPCVD).

Example 65: The method of any examples herein, particularly examples 52-64, wherein the antireflection layer is deposited using spin-coating.

Example 66: The method of any examples herein, particularly examples 52-65, wherein the photoresist layer is deposited using spin-coating.

Example 67: The method of any examples herein, particularly examples 37-66, wherein the polysilicon layer in the first layered stack, the fifth layered stack, the first precursor layered stack, the second precursor layered stack, or a combination thereof independently has an average thickness of from 500 nm to 10 μmicrons.

Example 68: The method of any examples herein, particularly examples 37-67, wherein the antireflection layer in the first layered stack, the fifth layered stack, the first precursor layered stack, the second precursor layered stack, or a combination thereof independently has an average thickness of from 50 to 200 nm.

Example 69: The method of any examples herein, particularly examples 37-68, wherein the photoresist layer in the first layered stack, the fifth layered stack, the first precursor layered stack, the second precursor layered stack, or a combination thereof independently has an average thickness of from 100 nm to 1000 nm.

Example 70: A method of use of the patterned material of any examples herein, particularly examples 1-35 or the patterned material made by the method of any examples herein, particularly examples 36-69.

Example 71: The method of any examples herein, particularly example 70, wherein the method comprises using the patterned material in an optical device, a photonic device, an electronic device, or an optoelectronic device.

Example 72: The method of any examples herein, particularly example 70 or example 71, wherein the method comprises using the patterned material in a nanophotonic device, as a metasurface, or a combination thereof.

Example 73: The method of any examples herein, particularly examples 70-72, wherein the method comprises using the patterned material in a defense application, an extraterrestrial application, an aerospace application, or a combination thereof, such as a missile dome.

Example 74: An article of manufacture and/or a device comprising the patterned material of any examples herein, particularly examples 1-35 or the patterned material made by the method of any examples herein, particularly examples 36-69.

Example 75: The article and/or device of any examples herein, particularly example 74, wherein the article and/or device comprises an optical device, a photonic device, an electronic device, or an optoelectronic device.

Example 76: The article and/or device of any examples herein, particularly example 74 or example 75, wherein the article and/or device comprises a display, a portable electronic device, a window, a lens, a lighting device, or a combination thereof.

Example 77: The article and/or device of any examples herein, particularly examples 74-76, wherein the article and/or device comprises a nanophotonic device, as a metasurface, or a combination thereof.

Example 78: The article and/or device of any examples herein, particularly examples 74-77, wherein the article and/or device is for a defense application, an extraterrestrial application, an aerospace application, or a combination thereof, such as a missile dome.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A patterned material comprising a first plurality of nanostructures patterned on a first surface of a substrate, wherein:
the first plurality of nanostructures have a first average aspect ratio of 0.5 or more;
the first plurality of nanostructures comprise a first plurality of pillars extending from the first surface of the substrate;
the first plurality of nanostructures are arranged in a first ordered array, such that the first plurality of nanostructures are periodic;
the first plurality of nanostructures and the substrate comprise a transparent ceramic material comprising alumina (aluminum oxide, Al₂O₃); and
the first plurality of nanostructures are substantially uniform over a surface area of 10 square micrometers (μm²) or more on the first surface of the substrate.

2. The patterned material of claim 1, wherein the first plurality of nanostructures are integrally formed with the first surface of the substrate.

3. The patterned material of claim 1, wherein the first plurality of pillars have a first average characteristic dimension and a first average height, and the first average characteristic dimension varies along at least a portion of the first average height.

4. The patterned material of claim 1, wherein the first ordered array comprises a two dimensional array.

5. The patterned material of claim 1, wherein the alumina-based transparent ceramic material comprises sapphire (single-crystal aluminum oxide), aluminum oxynitride spinel (Al₂₃O₂₇N₅, abbreviated as AlON), yttrium aluminum garnet (YAG), magnesium aluminate spinel (MgAl₂O₄), alumina-based glass, derivatives thereof, or a combination thereof.

6. The patterned material of claim 1, wherein the alumina-based transparent ceramic material comprises sapphire.

7. The patterned material of claim 1, wherein the alumina-based transparent ceramic material has a Mohs hardness of 7 or more.

8. The patterned material of claim 1, wherein the substrate has a second surface, the second surface being opposite and spaced apart from the first surface, and the patterned material further comprises a second plurality of nanostructures patterned on the second surface of the substrate, wherein:
the second plurality of nanostructures have a second average aspect ratio of 0.5 or more;
the second plurality of nanostructures comprise a second plurality of pillars extending from the second surface of the substrate;
the second plurality of nanostructures are arranged in a second ordered array, such that the second plurality of nanostructures are periodic;
the second plurality of nanostructures comprise the alumina-based transparent ceramic material; and
the second plurality of nanostructures are substantially uniform over a surface area of 10 square micrometers (μm²) or more on the second surface of the substrate.

9. The patterned material of claim 8, wherein the second plurality of nanostructures are integrally formed with the second surface of the substrate.

10. The patterned material of claim 8, wherein the second plurality of pillars have a second average characteristic dimension and a second average height, and the second average characteristic dimension varies along at least a portion of the second average height.

11. The patterned material of claim 8, wherein the second ordered array comprises a two dimensional array.

12. The patterned material of claim 8, wherein the second plurality of nanostructures are the same as the first plurality of nanostructures.

13. The patterned material of claim 1, wherein the patterned material exhibits improved anti-glare (anti-reflection) properties, anti-dust properties, anti-fog properties, anti-scratch properties, self-cleaning properties, or a combination thereof, for example relative to the substrate in the absence of the patterning.

14. A method of making the patterned material of claim 1.

15. The method of claim 14, wherein the method comprises:
patterning a photoresist layer of a first layered stack, thereby making a second layered stack where the photoresist layer is patterned;
wherein the first layered stack comprises the photoresist layer, an antireflection layer, a polysilicon layer, and a substrate having a first surface, the polysilicon layer being disposed on the first surface of the substrate, the antireflection layer being disposed on the polysilicon layer such that the polysilicon layer is sandwiched between the antireflection layer and the first surface of the substrate, and the photoresist layer being disposed on the antireflection layer such that the antireflection layer is sandwiched between the photoresist layer and the polysilicon layer;
patterning the antireflection layer of the second layered stack to transfer the pattern of the photoresist layer to the antireflection layer, thereby making a third layered stack where the photoresist layer and the antireflection layer are patterned;
patterning the polysilicon layer of the third layered stack to transfer the pattern of the antireflection layer to the polysilicon layer, thereby making a fourth layered stack where the photoresist layer, the antireflection layer, and the polysilicon layer are patterned; and
etching the fourth layered stack to transfer the pattern of the polysilicon layer to the substrate and remove the photoresist layer, the antireflection layer, and the polysilicon layer, thereby making the patterned material.

16. The method of claim 14, wherein the method comprises:
patterning a photoresist layer of a first precursor layered stack, thereby making a first intermediate layered stack where the photoresist layer is patterned;
wherein the first precursor layered stack comprises the photoresist layer, a polysilicon layer, and a substrate having a first surface, the polysilicon layer being disposed on the first surface of the substrate, the photoresist layer being disposed on the polysilicon layer such that the polysilicon layer is sandwiched between the photoresist layer and the first surface of the substrate;
patterning the polysilicon layer of the first intermediate layered stack to transfer the pattern of the photoresist layer to the polysilicon layer, thereby making a second intermediate layered stack where the photoresist layer and the polysilicon layer are patterned; and
etching the second intermediate layered stack to transfer the pattern of the polysilicon layer to the substrate and remove the photoresist layer and the polysilicon layer, thereby making the patterned material.

17. The method of claim 14, wherein the substrate has a second surface, the second surface being opposite and spaced apart from the first surface, and the method further comprises patterning the second surface.

18. The method of claim 17, wherein the method comprises:
patterning a photoresist layer of a fifth layered stack thereby making a sixth layered stack where the photoresist layer is patterned;
wherein the fifth layered stack comprises the photoresist layer, an antireflection layer, a polysilicon layer, and the substrate having the second surface, the polysilicon layer being disposed on the second surface of the substrate, the antireflection layer being disposed on the polysilicon layer such that the polysilicon layer is sandwiched between the antireflection layer and the second surface of the substrate, and the photoresist layer being disposed on the antireflection layer such that the antireflection layer is sandwiched between the photoresist layer and the polysilicon layer;
patterning the antireflection layer of the sixth layered stack, to transfer the pattern of the photoresist layer to the antireflection layer, thereby making a seventh layered stack where the photoresist layer and the antireflection layer are patterned;
patterning the polysilicon layer of the seventh layered stack to transfer the pattern of the antireflection layer to the polysilicon layer, thereby making an eighth layered stack where the photoresist layer, the antireflection layer, and the polysilicon layer are patterned; and
etching the eighth layered stack to transfer the pattern of the polysilicon layer to the substrate and remove the photoresist layer, the antireflection layer, and the polysilicon layer, thereby making the patterned material.

19. The method of claim 17, wherein the method comprises:
patterning a photoresist layer of a second precursor layered stack thereby making a third intermediate layered stack where the photoresist layer is patterned;
wherein the second precursor layered stack comprises the photoresist layer, a polysilicon layer, and the substrate having the second surface, the polysilicon layer being disposed on the second surface of the substrate, the photoresist layer being disposed on the polysilicon layer such that the polysilicon layer is sandwiched between the photoresist layer and the second surface of the substrate;
patterning the polysilicon layer of the third intermediate layered stack, to transfer the pattern of the photoresist layer to the polysilicon layer, thereby making a fourth intermediate layered stack where the photoresist layer and the polysilicon layer are patterned; and
etching the fourth intermediate layered stack to transfer the pattern of the polysilicon layer to the substrate and remove the photoresist layer and the polysilicon layer, thereby making the patterned material.

20. The method of claim 15, wherein patterning the photoresist layer comprises using interference lithography.

21.-28. (canceled)
